(19) United States
(12) Patent Application Publication
(10) Pub. No.: US 2012/0202141 A1
(43) Pub. Date: Aug. 9, 2012

(54) CHEMICAL AMPLIFICATION TYPE POSITIVE RESIST COMPOSITION, AND RESIST FILM, RESIST COATED MASK BLANKS AND RESIST PATTERN FORMING METHOD USING THE COMPOSITION

(75) Inventors: Takeshi INASAKI, Haibara-gun (JP); Tomotaka TSUCHIMURA, Haibara-gun (JP); Hiroo TAKIZAWA, Haibara-gun (JP)

(73) Assignee: FUJIFILM CORPORATION, Tokyo (JP)

(21) Appl. No.: 13/362,569

(22) Filed: Jan. 31, 2012

(30) Foreign Application Priority Data
Feb. 4, 2011 (JP) 2011-023412

(51) Int. Cl. G03F 1/78; G03F 1/76; G03F 1/50; C08F 228/02

(52) U.S. Cl. 430/5; 526/287

(57) ABSTRACT

The object of the present invention is to solve the technical problems in the microfabrication of photomasks or semiconductors and is, in particular, to provide a chemical amplification type positive resist film, and a resist film, resist coated mask blanks and a method of forming a resist pattern using the composition, which satisfy at the same time all of high sensitivity, high resolution (for example, high resolving power), good exposure latitude (EL), and good line edge roughness (LER).

A chemical amplification type positive resist composition comprising: a high molecular compound (A) having a repeating unit represented by the following general formula (1), a repeating unit represented by the following general formula (2), and a repeating unit represented by the following general formula (3).

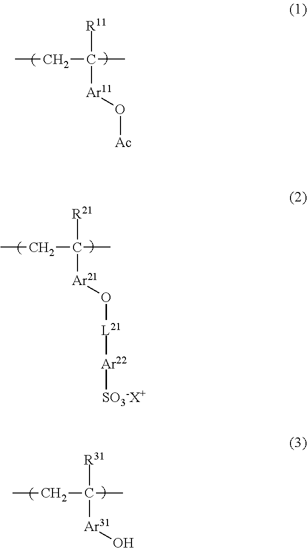

### BACKGROUND OF THE INVENTION

1. Field of the Invention

The present invention relates to a chemical amplification type positive resist composition which is capable of forming a high precision pattern using an electron beam, a resist film, resist coated mask blanks and a method of forming a resist pattern using the composition. The chemical amplification type positive resist composition of the present invention is suitably used in ultramicrolithography which is applicable to a production process such as the production of VLSI or high capacity microchips, a manufacturing process of a nanoimprinting mold and a production process of a high density information recording medium, and the like, and other photofabrication processes. In particular, the present invention relates to a chemical amplification type positive resist composition used in a process using a substrate having a particular undercoating layer, and a resist film, resist coated mask blanks and a resist pattern forming method using the composition.

2. Description of the Related Art

In the conventional production processes of semiconductor devices such as IC or LSI, a microfabrication by the lithography using a photoresist composition has been performed. In recent years, due to increasing integration of integrated circuits, the formation of ultrafine patterns in sub-micron region or quarter-micron region has been required. Due to this requirement, the exposure wavelength also tends to become shorter, for example, from g-rays to i-rays or further to excimer laser light, and the development of the lithography technology using an electron beam or X-rays is currently also proceeding.

Electron beam lithography has in particular been positioned as a pattern forming technique of a next-generation or the generation after that, and additionally, because of its high resolution, has been widely used for making a photomask which is used for semiconductor exposure. In a process for making a photomask, a resist layer is formed on a shielding substrate wherein a shielding layer containing, as a main component, chromium, and the like has been provided on a transparent substrate, and electron beam exposure is selectively performed and thereafter alkali development is performed to form a resist pattern. Then, through etching the shielding layer using this resist pattern as a mask to form a pattern to the shielding layer, a photomask equipped with a shielding layer having a predetermined pattern on the transparent substrate is produced.

However, since an electron beam cannot used for a one-shot exposure such as with ultraviolet rays, a resist having a high sensitivity has been desired to shorten the processing time. As a resist which is suitable for electron beam lithography, a so-called positive chemical amplification resist composition wherein an acid decomposable high molecular compound is combined with a photoacid generator, are effectively used. However, in the case the sensitivity of such a resist composition is intended to be further increased, the decrease of resolution or the decrease of exposure latitude (EL) tends to occur. Furthermore, the worsening of line edge roughness (a phenomenon wherein the edge of the interface between a resist pattern and a substrate varies irregularly in a direction perpendicular to the line, the edge becomes uneven, and the unevenness is transcribed by etching process, thereby lowering a dimensional accuracy) also tends to occur. The improvement of line edge roughness has become a particularly important issue in ultrafine regions with a line width of not more than 0.25 μm.

As one way to solve these problems, for example, JP2007-197718A discloses a resin having a group which decomposes by the action of an acid to increase the solubility into an alkaline developer and a photoacid generating group in the same molecule. However, a resist composition which satisfies at the same time all of high sensitivity, high resolution, good exposure latitude (EL), and good line edge roughness (LER), in an ultrafine region such as an electron beam lithography has not been obtained.

### SUMMARY OF THE INVENTION

The object of the present invention is to solve the technical problems in the microfabrication of photomasks or semiconductor devices and is, in particular, to provide a chemical amplification type positive resist composition, and a resist film, resist coated mask blanks and a method of forming a resist pattern using the composition, which satisfy at the same time all of high sensitivity, high resolution (for example, high resolving power), good exposure latitude (EL), and good line edge roughness (LER).

The present invention is, in particular to provide a chemical amplification type positive resist composition, which exhibits good exposure latitude (EL), and good line edge roughness (LER) in the formation of fine patterns by exposure using an electron beam.

As a result of intensive studies to solve those problems, the present inventors have found out that the above-described object can be attained by a chemical amplification type positive resist composition which uses a high molecular compound having a specific structure.

That is, the chemical amplification type positive resist composition of the present invention is characterized by containing a high molecular compound (A) having a repeating unit represented by the following general formula (1), a repeating unit represented by the following general formula (2), and a repeating unit represented by the following general formula (3).

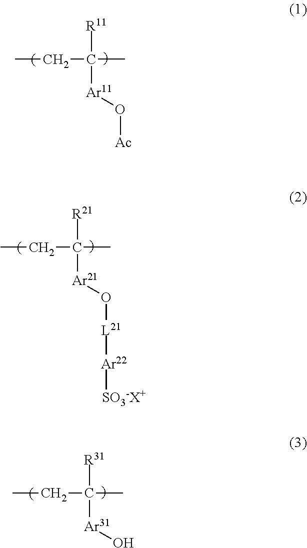

In the general formulae (1) to (3), each of R¹¹, R²¹, and R³¹ represents independently a hydrogen atom or a methyl group,

each of Ar¹¹, Ar²¹, and Ar³¹ represents independently an arylene group,
Ac is a group leaving by the action of an acid, and —OAc is an acetal group which decomposes by the action of an acid to generate an alkali-soluble group,
L²¹ represents a divalent organic group,
Ar²² represents an unsubstituted aromatic ring, or an aromatic ring which is substituted with an alkyl group or an alkoxy group, and
X⁺ represents an onium cation.

The preferred embodiments in the present invention are that the Ar¹¹, Ar²¹, and Ar³¹ represent a phenylene group, and that the L²¹ represents a carbonyl group, a methylene group, —CO—(CH₂)ₙ—O—, —CO—(CH₂)ₙ—O—CO—, —(CH₂)ₙ—COO—, —(CH₂)ₙ—CONR¹—, or —CO—(CH₂)ₙ—NR¹— (wherein, the R¹ represents a hydrogen atom, an alkyl group, an aryl group or an aralkyl group, and the n is an integer of 1 to 10), and particularly that the L²¹ represents a carbonyl group, —CH₂—COO—, —CO—CH₂—O—, —CO—CH₂—O—CO—, —CH₂—CONR¹—, or —CO—CH₂—NR¹— (wherein the R¹ represents a hydrogen atom, an alkyl group, an aryl group or an aralkyl group).

In addition, the preferred embodiments in the present invention are also that the X⁺ represents a sulfonium cation, and that the dispersity of the high molecular compound (A) is from 1.0 to 1.3.

The present invention includes a resist film formed by a chemical amplification type positive resist composition described above, and resist coated mask blanks having the resist film.

In addition, the present invention includes a method of forming a resist pattern, including: exposing the resist film and developing the exposed film, and a method of forming a resist pattern, including: exposing the resist coated mask blanks and developing the exposed mask blanks.

The preferred embodiment in the present invention is that the exposing is performed by using an electron beam.

The present invention can provide a chemical amplification type positive resist composition, and a resist film, resist coated mask blanks and a method of forming a resist pattern using the composition, which satisfy at the same time all of high sensitivity, high resolution (for example, high resolving power), good exposure latitude (EL), and good line edge roughness (LER), in an ultrafine region.

In particular, the chemical amplification type positive resist composition of the present invention can provide good exposure latitude (EL) and good line edge roughness (LER) in the formation of fine patterns by exposure using an electron beam.

### DESCRIPTION OF THE PREFERRED EMBODIMENTS

Hereinafter, the embodiments of the present invention will be further described in detail.

Furthermore, in the present specification, when a group (atomic group) is denoted without specifying whether substituted or unsubstituted, the group includes not only a group having no substituent but also a group having a substituent. For example, the term “an alkyl group” includes not only an alkyl group having no substituent (an unsubstituted alkyl group) but also an alkyl group having a substituent (a substituted alkyl group).

In the present invention, the term “actinic rays” or “radiation” means, for example, a bright line spectrum of a mercury lamp, far ultraviolet rays typified by an excimer laser, extreme ultraviolet rays (EUV light), X-rays or an electron beam, and the like. Also, in the present invention, the term “light” means actinic rays or radiation. Furthermore, in the present specification, unless otherwise specified, the term “exposure” includes not only exposure to a mercury lamp, far ultraviolet rays typified by an excimer laser, X-rays, EUV light, and the like but also lithography with a particle beam such as an electron beam and an ion beam. In the following specification, “(from) xx to yy” means that it includes numerical values designated by “xx” and “yy” as a lower limit and an upper limit, respectively.

The chemical amplification type positive resist composition according to the present invention contains a high molecular compound (A) having the repeating units represented by the following general formulae (1) to (3).

It is preferable that the chemical amplification type positive resist composition according to the present invention be used for the exposure to an electron beam.

Hereinafter, the chemical amplification type positive resist composition of the present invention will be described in detail.

[1] (A) A High Molecular Compound (A) having a repeating unit represented by the general formula (1), a repeating unit represented by the general formula (2), and a repeating unit represented by the general formula (3)

The chemical amplification type positive resist composition according to the present invention contains a high molecular compound (A) having a repeating unit represented by the following general formula (1), a repeating unit represented by the following general formula (2), and a repeating unit represented by the following general formula (3). The high molecular compound (A) is used as a main component in the chemical amplification type positive resist composition according to the present invention.

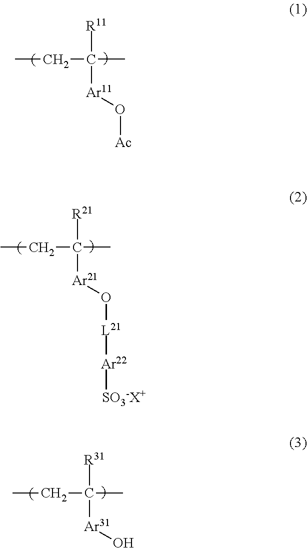

In the general formulae (1) to (3), each of R¹¹, R²¹, and R³¹ represents independently a hydrogen atom or a methyl group,

each of Ar¹¹, Ar²¹, and Ar³¹ represents independently an arylene group,
Ac is a group leaving by the action of an acid, and —OAc is an acetal group which decomposes by the action of an acid to generate an alkali-soluble group,
L²¹ represents a divalent organic group,
Ar²² represents an unsubstituted aromatic ring, or an aromatic ring which is substituted with an alkyl group or an alkoxy group, and
X⁺ represents an onium cation.

It is preferable that in the general formulae (1) to (3), Ar¹¹, Ar²¹, and Ar³¹ represent a phenylene group.

The general formula (1) is, in a positive resist composition, a repeating unit having an acetal group on the side chain thereof, and the general formula (3) is a repeating unit which has a function of controlling an alkali developing property. The acetal group is a group (hereinafter, sometimes referred to as “an acid decomposable group”) which decomposes by the action of an acid to form an alkali-soluble group. In addition, the general formula (2) is a repeating unit which generates a sulfonic acid group (which is an acid group) upon irradiation with the actinic rays or radiation such as an electron beam, and which induces the decomposition reaction of the acetal group of the general formula (1).

In the present invention, in the case the acid decomposable group is an acetal group, not a strong acid, but an aryl sulfonic acid such as in the present invention has the most appropriate acid strength as the acid which induces the decomposition reaction thereof. In addition, in the formula (2), the presence of the site L²¹ and the site Ar²² in the side chain thereof enables the optimal design of the linking length between the acid generating moeity (SO₃⁻X⁺) and the main chain of the high molecular compound (A). In the present invention, it is considered that these combinations lead to the attainment of the object of the present invention. In particular, according to the high molecular compound (A) of the present invention, it is presumed that the presence of the acid generating moiety in the high molecular compound enables the suppression of the diffusion of the acid, and at the same time the presence of the spacer of the site L²¹ and the site Ar²² described above enables the maintenance of the minimum diffusion which is required for the reaction, and the optimal maintenance of the diffusion distance of the acid, thereby rendering, in particular, EL and LER better.

Next, the repeating unit represented by the general formula (1) will be described.

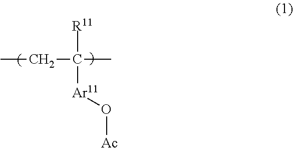

In the general formula (1), R¹¹ represents a hydrogen atom or a methyl group, Ar¹¹ represents an arylene group,

Ac is a group leaving by the action of an acid, and —OAc is an acetal group which decomposes by the action of an acid to generate an alkali-soluble group.

The repeating unit represented by the general formula (1) is a repeating unit which decomposes by the action of an acid to generate an alkali-soluble group, and is a group where a hydrogen atom of the alkali-soluble group is replaced by a group leaving by the action of the acid (hereinafter, sometimes referred to as an “acid decomposable group”).

The alkali-soluble group which decomposes by the action of an acid and is generated from the repeating unit represented by the general formula (1) is a phenolic hydroxyl group.

R¹¹ in the repeating unit represented by the general formula (1) represents a hydrogen atom or a methyl group, but is particularly preferably a hydrogen atom.

Ar¹¹ in the repeating unit represented by the general formula (1) represents an arylene group, and may have a substituent. The arylene group of Ar¹¹ is preferably an arylene group having a carbon number of 6 to 18, which may have a substituent, more preferably a phenylene group or a naphthylene group which may have a substituent, and most preferably a phenylene group which may have a substituent. In addition, the examples of the substituent which Ar¹¹ may have include an alkyl group, a halogen atom, a hydroxyl group, an alkoxy group, a carboxyl group, and an alkoxycarbonyl group.

In the repeating unit represented by the general formula (1), when Ar¹¹ is a phenylene group, the binding position of —OAc to the benzene ring of Ar¹¹ may be any of para, meta and ortho positions, relative to the binding position of the benzene ring with the polymer main chain, but the para or meta position is preferable.

In the general formula (1), Ac is a group leaving by the action of an acid, and —OAc represents an acetal group which decomposes by the action of an acid to generate an alkali-soluble group (a phenolic hydroxyl group). It is preferable that Ac be, specifically, a group represented by the following general formula (4).

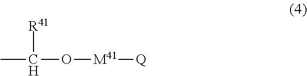

In the general formula (4), R⁴¹ represent a hydrogen atom, an alkyl group, a cycloalkyl group, an aryl group or an aralkyl group,

M⁴¹ represents a single bond or a divalent linking group, and
Q represents an alkyl group, an alicyclic group which may contain a heteroatom, or an aromatic ring group which may contain a heteroatom.

In addition, at least two of R⁴¹, M⁴¹ and Q may bind together to form a ring. It is preferable that this ring be a 5- or 6-membered ring.

The examples of alkyl group as R⁴¹ include an alkyl group having a carbon number of 1 to 8. The preferred examples thereof include a methyl group, an ethyl group, a propyl group, an isopropyl group, n-butyl group, sec-butyl group, tert-butyl group, a hexyl group and an octyl group.

The alkyl group as R⁴¹ may have a substituent, and the examples thereof include a cyano group, a halogen atom, a hydroxyl group, an alkoxy group, a carboxyl group and an alkoxycarbonyl group.

The examples of the cycloalkyl group as R⁴¹ include a cycloalkyl group having a carbon number of 3 to 15. The preferred examples thereof include a cyclohexyl group, a norbornyl group and an adamantyl group.

The examples of the aryl group of R⁴¹ include an aryl group having a carbon number of 6 to 15. The preferred examples thereof include a phenyl group, a tolyl group, naphthyl group and anthryl group.

The examples of the aralkyl group of R⁴¹ include an aralkyl group having a carbon number of 6 to 20. Preferably, the examples thereof include a benzyl group and a phenethyl group.

As R⁴¹, particularly preferred are a hydrogen atom, a methyl group, a phenyl group and a benzyl group.

The divalent linking group as M⁴¹ is, for example an alkylene group (preferably an alkylene group having a carbon number of 1 to 8, for example a methylene group, an ethylene group, a propylene group, a butylene group, a hexylene group or an octylene group), a cycloalkylene group (preferably a cycloalkylene group having a carbon number of 3 to 15, for example a cyclopentylene group or a cyclohexylene group), —S—, —O—, —CO—, —CS—, —SO₂—, —N(R₀)—, or a combination of two or more thereof, and those having the total carbon number of 20 or less are preferred. Herein, Rₒ is a hydrogen atom or an alkyl group (for example, an alkyl group having carbon number of 1 to 8, specifically, a methyl group, an ethyl group, a propyl group, n-butyl group, sec-butyl group, a hexyl group and an octyl group, and the like).

M⁴¹ is 1 preferably a single bond, an alkylene group, or a divalent linking group consisting of a combination of an alkylene group with at least one of —O—, —CO—, —CS— and —N(R₀)—, and is more preferably a single bond, an alkylene group, or a divalent linking group consisting of a combination of an alkylene group with —O—. Herein, the definition of R₀ is the same as the aforementioned R₀.

The alkyl group as Q is, for example the same as the alkyl group as R⁴¹ described above.

The examples of the alicyclic group and the aromatic ring group as Q include the cycloalkyl group and the aryl group as R⁴¹ described above. The carbon number thereof is preferably 3 to 18. In addition, in the present invention, a group in which plural aromatic rings are linked via a single bond (for example, a biphenyl group, or a terphenyl group) is also included in the aromatic group as Q.

The examples of the alicyclic group containing a heteroatom and the aromatic ring group containing a heteroatom include thiirane, cyclothiorane, thiophene, furan, pyrrole, benzothiophen, benzofuran, benzopyrrole, triazine, imidazole, benzoimidazole, triazole, thiadiazole, thiazole and pyrrolidone. In addition, in the present invention, a group in which plural “aromatic rings containing a hetero atom” are linked via a single bond (for example, a viologen group) is also included in the aromatic group as Q.

The alicyclic group and the aromatic ring group as Q may have a substituent, and the examples thereof include an alkyl group, a cycloalkyl group, a cyano group, a halogen atom, a hydroxyl group, an alkoxy group, a carboxyl group and an alkoxycarbonyl group.

As (-M⁴¹-Q), particularly preferred are a methyl group, an aryloxyethyl group, a cyclohexylethyl group or an arylethyl group.

The examples of the case where at least two of R⁴¹, M⁴¹ and Q bind together to form a ring include a case where any of M⁴¹ and Q binds to R⁴¹ to form a propylene group or a butylene group and then to form a 5- or 6-membered ring containing an oxygen atom.

When the sum of the carbon numbers of R⁴¹, M⁴¹ and Q are referred to as N_{c}, in a case where N_{C} is large, since the change of the alkali dissolution rate of the high molecular compound (A) before and after the leaving of the group represented by the general formula (4) increases and the contrast of the dissolution improves, and thus this case is preferable. The range of N_{C} is preferably 4 to 30, further preferably 7 to 25, and particularly preferably 7 to 20. When N_{c} is 30 or less, the decrease of the glass transition temperature of the high molecular compound (A) is suppressed, and the decrease of the exposure latitude (EL) of the resist is suppressed, or the remaining defects on the resist pattern due to the residue after the leaving of the group represented by the general formula (4) is suppressed, and therefore this case is preferable.

In addition, it is preferable that at least one of R⁴¹, M⁴¹ and Q have an alicyclic or aromatic ring in view of dry etching resistance. The alicyclic group and the aromatic ring group herein are, for example the same as the alicyclic group and the aromatic ring group as Q described above.

The specific examples of the repeating unit represented by the general formula (1) are illustrated below, but the present invention is not limited thereto.

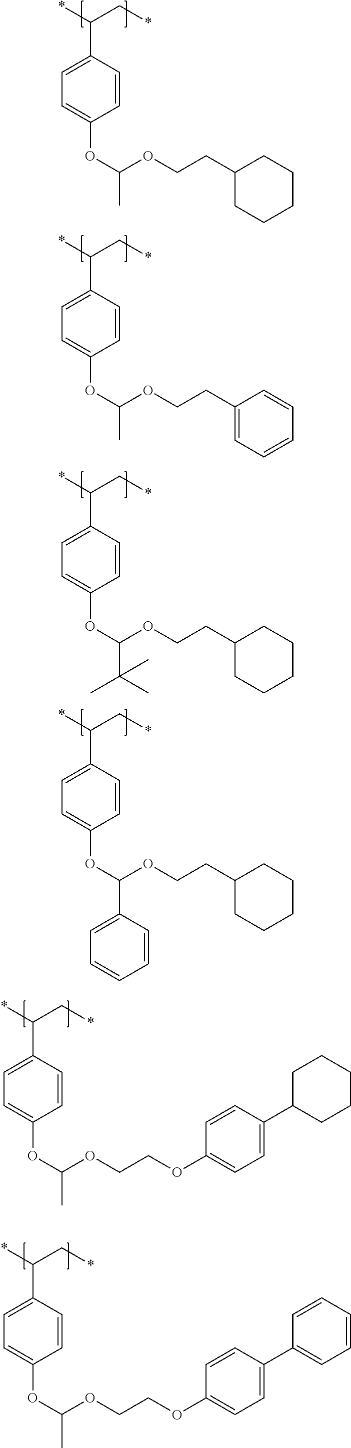

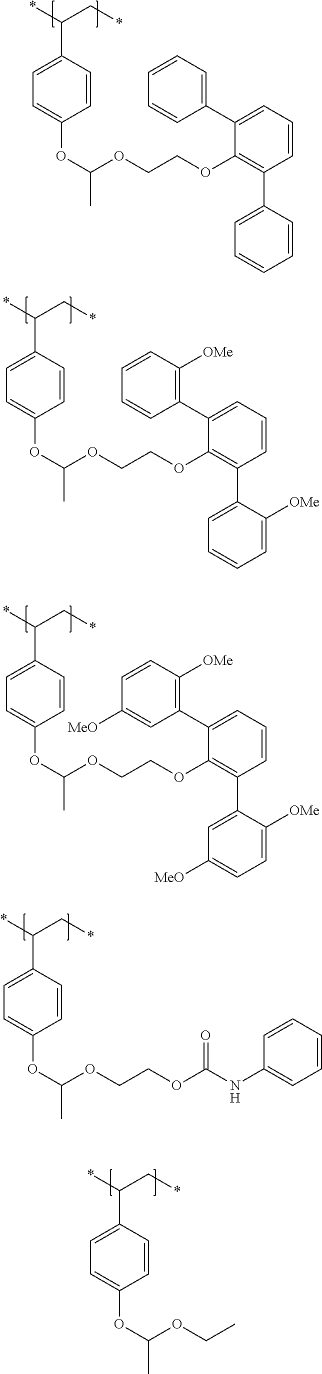

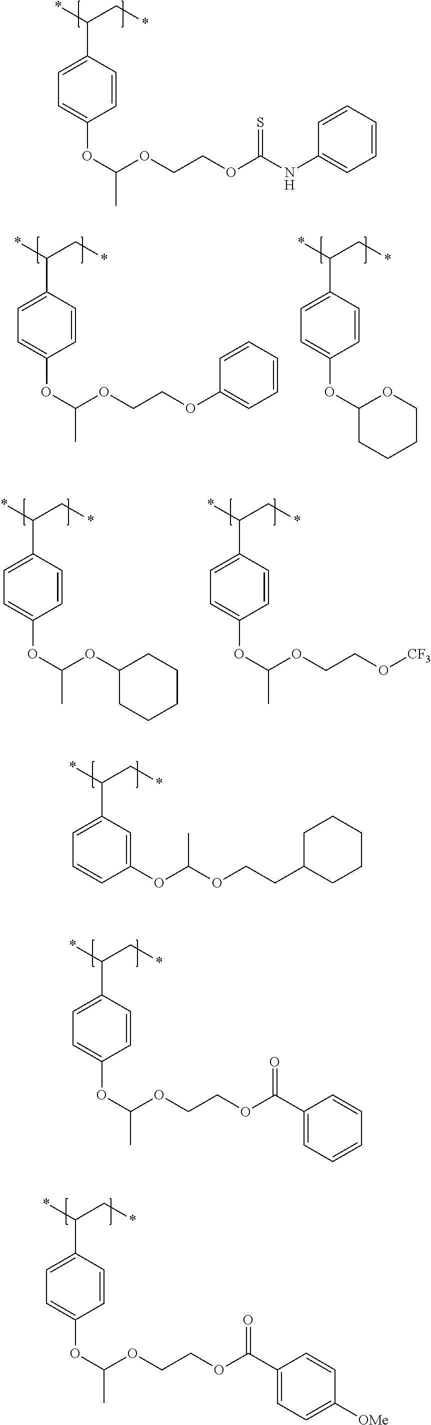

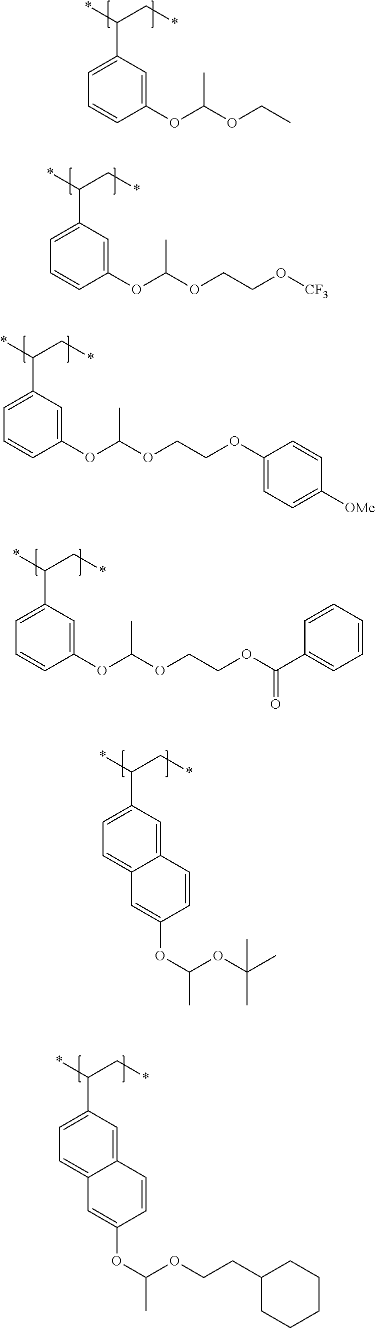

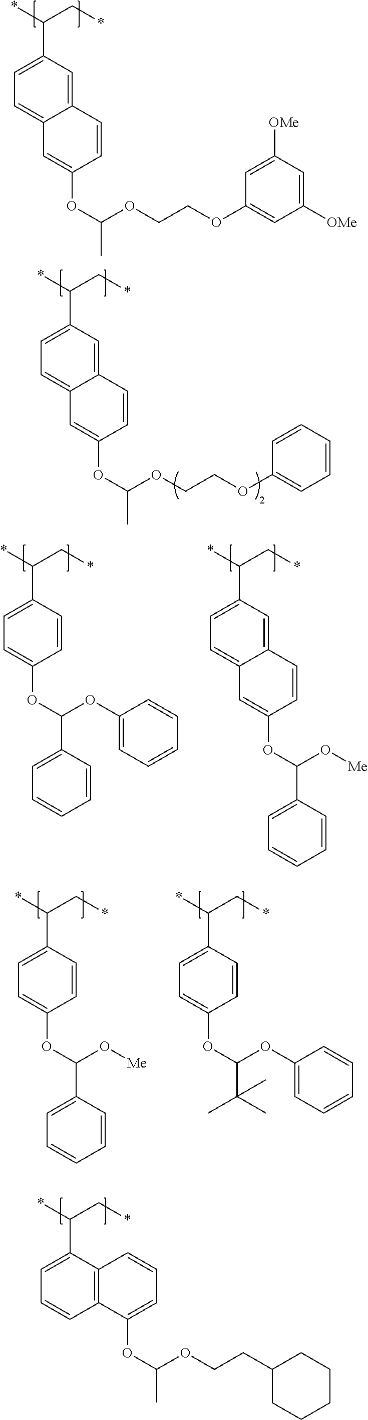

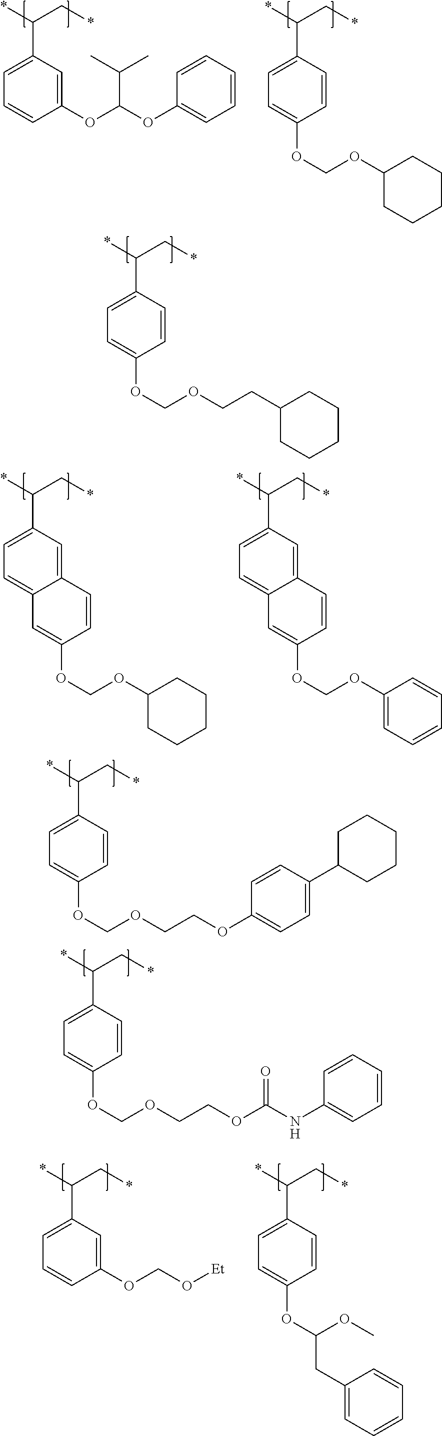

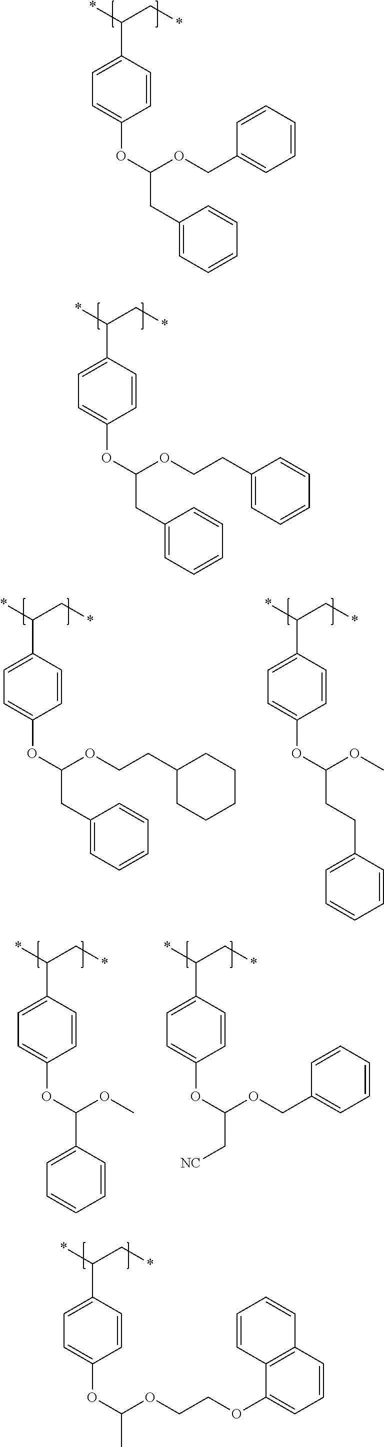

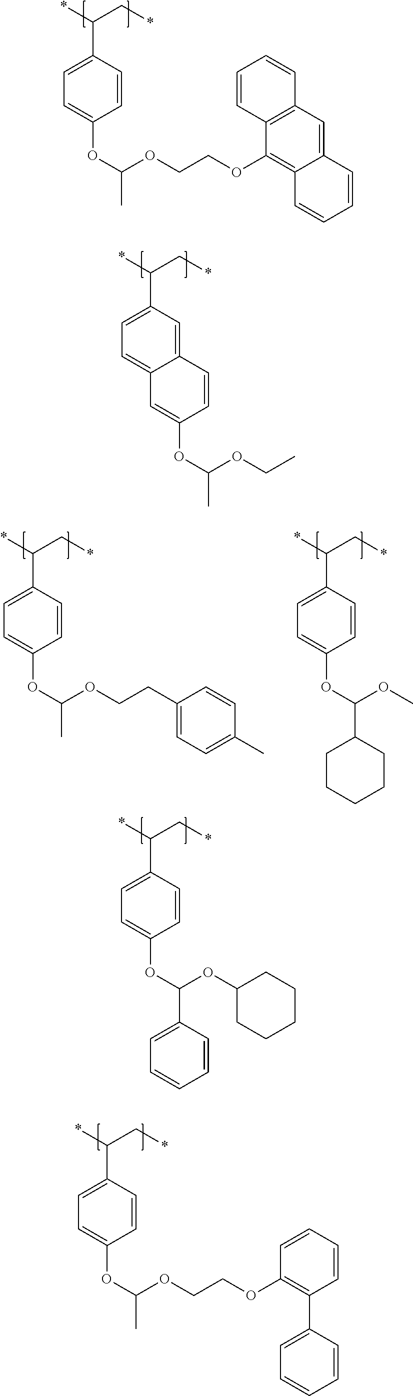

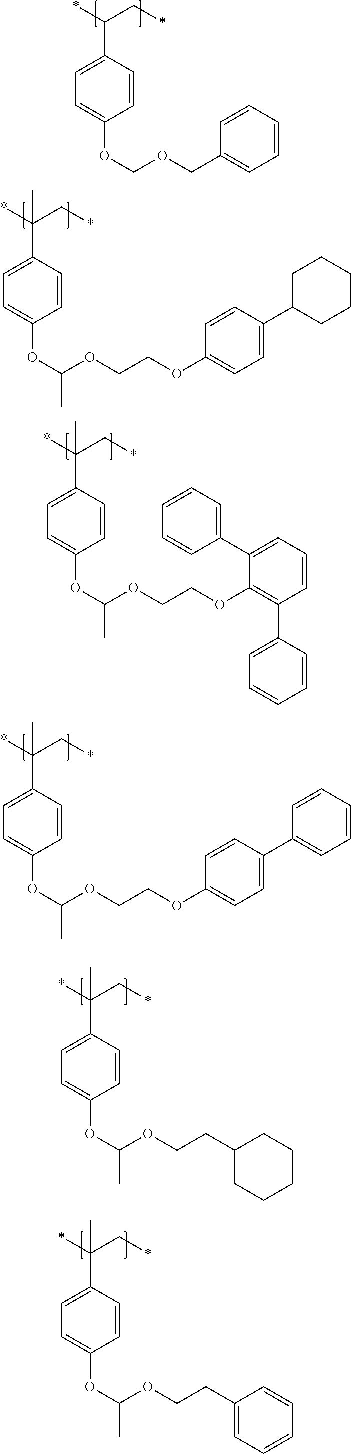

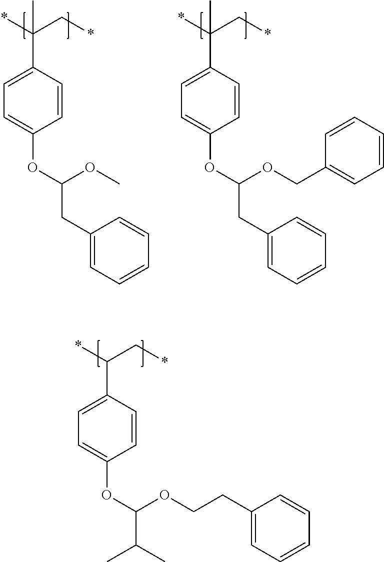

The content of the repeating unit represented by the general formula (1) in the high molecular compound (A) of the present invention is preferably the range of from 1 to 60 mol %, more preferably the range of from 3 to 50 mol %, and particularly preferably the range of from to 40 mol %, based on all the repeating units in the high molecular compound (A).

Next, the repeating unit represented by the general formula (2) will be described.

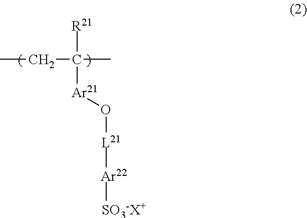

In the general formula (2), R²¹ represents a hydrogen atom or a methyl group,

Ar²¹ represents an arylene group,
L²¹ represents a divalent organic group,
Ar²² represents an unsubstituted aromatic ring, or an aromatic ring which is substituted with an alkyl group or an alkoxy group, and
X⁺ represents an onium cation.

In the repeating unit represented by the general formula (2), the preferable compounds which are used in the present invention will be described below.

R²¹ in the repeating unit represented by the general formula (2) represents a hydrogen atom or a methyl group, but is particularly preferably a hydrogen atom.

Ar²¹ in the repeating unit represented by the general formula (2) represents an arylene group, and may have a substituent. The arylene group of Ar²¹ is preferably an arylene group having a carbon number of 6 to 18, which may have a substituent, more preferably a phenylene group or a naphthylene group which may have a substituent, and most preferably a phenylene group which may have a substituent. In addition, the examples of the substituent which Ar²¹ may have include an alkyl group, a halogen atom, a hydroxyl group, an alkoxy group, a carboxyl group, and an alkoxycarbonyl group.

In the repeating unit represented by the general formula (2), when Ar²¹ is a phenylene group, the binding position of —O-L²¹-Ar²²—SO₃⁻X⁺ to the benzene ring of Ar²¹ may be any of para, meta and ortho positions, relative to the binding position of the benzene ring with the polymer main chain, but the meta and para positions are preferable, and the para position is particularly preferable.

The examples of the divalent organic group of L²¹ in the general formula (2) include, for example an alkylene group, an alkenylene group, —O—, —CO—, —NR¹⁴—, —S—, —CS—. Herein, R¹⁴ is a hydrogen atom, an alkyl group, a cycloalkyl group, an aryl group, and an aralkyl group. The total carbon number of the divalent organic group of L²¹ is preferably from 1 to 15, and is more preferably from 1 to 10.

The examples of the alkylene group include preferably an alkylene group having a carbon number of 1 to 8, more preferably an alkylene group having a carbon number of 1 to 4, for example a methylene group, an ethylene group, a propylene group, a butylene group, a hexylene group or an octylene group.

The alkenylene group is preferably an alkenylene group having a carbon number of 2 to 8, more preferably an alkenylene group having a carbon number of 2 to 4.

The specific examples and the preferred ranges of an alkyl group, a cycloalkyl group, an aryl group, and an aralkyl group represented by R¹⁴ are the same as those of an alkyl group, a cycloalkyl group, an aryl group, and an aralkyl group represented by R⁴¹ in the general formula (4).

The preferred groups as L²¹ are a carbonyl group, a methylene group, —CO—(CH₂)ₙ—O—, —CO—(CH₂)ₙ—O—CO—, —(CH₂)ₙ—COO—, —(CH₂)ₙ—CONR¹—, or —CO—(CH₂)ₙ—NR¹—, and particularly preferred groups are a carbonyl group, —CH₂—COO—, —CO—CH₂—O—, —CO—CH₂—O—CO—, —CH₂—CONR¹—, or —CO—CH₂—NR¹—. Herein, the R¹ represents a hydrogen atom, an alkyl group, an aryl group or aralkyl group, and the n is an integer of 1 to 10.

The specific examples and the preferred ranges of an alkyl group, an aryl group and aralkyl group represented by R¹ are the same as those of an alkyl group, an aryl group and aralkyl group represented by R⁴¹ in the general formula (4).

n is preferably an integer of 1 to 6, more preferably an integer of 1 to 3, and 1 is the most preferable.

Ar²² represents an unsubstituted aromatic ring, or an aromatic ring which is substituted with an alkyl group or an alkoxy group. The term of Ar²² being an unsubstituted aromatic ring means that Ar²² does not have a substituent other than -L²¹- and —SO₃⁻X⁺ to which Ar²² is linked. In addition, the term of Ar²² being an aromatic ring which is substituted with an alkyl group or an alkoxy group means that Ar²² has an alkyl group or an alkoxy group as a substituent other than -L²¹- and —SO₃⁻X⁺ to which Ar²² is linked. Thus, it is preferable that Ar²² be an aromatic ring which does not have an electron-withdrawing group such as a fluorine atom as a substituent. Due to this, the excessive increase of the strength of the generating acid is suppressed and the generating acid is allowed to have an appropriate strength.

The alkyl group in a case of Ar²² having an alkyl group has preferably a carbon number of 1 to 8, and more preferably a carbon number of 1 to 4. The alkoxy group in a case of Ar²² having an alkoxy group has preferably a carbon number of 1 to 8, and more preferably a carbon number of 1 to 4. The aromatic ring of Ar²² may be an aromatic hydrocarbon ring (for example, a benzene ring or a naphthalene ring) or may be an aromatic heterocycle (for example, a quinoline ring), and has preferably a carbon number of 6 to 18, and more preferably a carbon number of 6 to 12.

Ar²² is an unsubstituted aromatic ring, or an aromatic ring where an alkyl group or an alkoxy group is substituted, and it is more preferable that the aromatic ring be an aromatic hydrocarbon ring, and it is still more preferable that the aromatic hydrocarbon ring be a benzene ring or a naphthalene ring. In addition, it is more preferable that the aromatic ring be an unsubstituted aromatic ring.

X⁺ represents an onium cation, preferably a sulfonium cation or iodonium cation, and more preferably sulfonium cation.

As described above, in the formula (2), the presence of the site L²¹ and the site Ar²¹ in the side chain thereof makes the linking length between the acid generating moeity (SO₃⁻X⁺) and the main chain of the high molecular compound (A) long, and allows the acid generated by exposure to more easily react a leaving group Ac in the general formula (1). However, when the linking length is excessively long, since the generated acid more easily diffuses, the roughness property and the resolution decrease. The minimum linking atom number of (L²¹-Ar²²), as an indicator showing the linking length, is preferably from 3 to 20, more preferably from 3 to 15, and particularly preferably from 3 to 10.

In addition, the minimum linking atom number is the number which is determined as below. That is to say, first, among the atoms which constitute L²¹-Ar²², the rows of the atoms which connect an atom which is bound to an oxygen atom which binds to Ar²¹ with an atom which is bound to —SO₃⁻X⁺ are considered. Next, the number of the atoms which are included in each of these rows are counted. In addition, the smallest number among the number of these atoms is defined as the minimum linking atom number.

For example, in the case of the following general formula (N_{L}-1), the number is 3, and in the case of the following general formula (N_{L}-2), the number is 7.

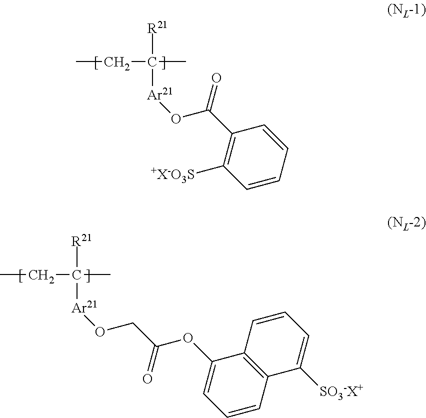

The onium cation represented by X⁺ in the repeating unit represented by the general formula (2) is preferably an onium cation represented by the following general formula (5) or (6).

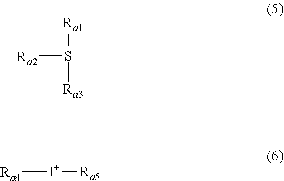

In the general formulae (5) and (6), each of Rₐ₁, Rₐ₂, Rₐ₃, Rₐ₄ and Rₐ₅ represents independently an organic group.

Next, the sulfonium cation represented by the general formula (5) will be further described in detail.

While each of Rₐ₁ to Rₐ₃ in the general formula (5) represents independently an organic group, it is preferable that at least one of Rₐ₁ to Rₐ₃ be an aryl group and more preferably be an arylsulfonium cation. As an aryl group, a phenyl group and a naphthyl group are preferable, and phenyl group is more preferable.

As the arylsulfonium cation, all of the Rₐ₁ to Rₐ₃ may be an aryl group and a part of the Rₐ₁ to Rₐ₃ may be an aryl group and the remainder may be an alkyl group, and the examples thereof can include triarylsulfonium cation, diarylalkylsulfonium cation, aryldialkylsulfonium cation, diarylcycloalkylsulfonium cation and aryldicycloalkylsulfonium cation.

As an aryl group of the arylsulfonium cation, an aryl group such as a phenyl group or a naphthyl group, and a heteroaryl group such as an indole moiety or a pyrrole moiety are preferable, and more preferred are a phenyl group and an indole moiety. In a case of having at least two aryl groups, the aryl groups may be the same or different from each other.

As for a group other than an aryl group of the arylsulfonium cation, in a case of alkyl group, a linear or branched alkyl group having a carbon number of 1 to 15 and a cycloalkyl group having a carbon number of 3 to 15 are preferable, and the examples thereof can include a methyl group, an ethyl group, a propyl group, n-butyl group, sec-butyl group, t-butyl group, and a cyclohexyl group, and the like.

The aryl group and the alkyl group of Rₐ₁ to Rₐ₃ may have a substituent, and the preferable substituents are an alkyl group having a carbon number of 1 to 4, and an alkoxy group having a carbon number of 1 to 4. In a case of Rₐ₁ to Rₐ₃ being an aryl group, it is preferable that the substituent be substituted in a p-position of the aryl group.

As for Rₐ₁ to Rₐ₃ in the general formula (5), the two of them may bind together to form a ring structure and may contain an oxygen atom, a sulfur atom, an ester bond, an amide bond, and a carbonyl group in the ring.

Next, the iodonium cation represented by the general formula (6) will be described in detail.

While each of Rₐ₄ and Rₐ₅ in the general formula (6) represents independently an organic group, it is preferable that each of them represent an aryl group and an alkyl group, and it is more preferable that the iodonium cation represented by the general formula (6) be an aryliodonium cation in which at least one of Rₐ₄ and Rₐ₅ are an aryl group.

As an aryl group of the Rₐ₄ and Rₐ₅, a phenyl group and a naphthyl group are preferable, and a phenyl group is more preferable.

The alkyl group as Rₐ₄ and Rₐ₅ may be any of a linear or a branched one, and the preferred examples thereof can include a linear or a branched alkyl group having a carbon number of 1 to 10 and a cycloalkyl group having a carbon number of 3 to 10 (for example, a methyl group, an ethyl group, a propyl group, a butyl group, a pentyl group and a cyclohexyl group).

The examples of the substituent which Rₐ₄ and Rₐ₅ may have, can include an alkyl group, an aryl group, an alkoxy group, a halogen atom, a hydroxyl group, and phenylthio group, and the like.

The specific examples of the repeating unit represented by the general formula (2) are illustrated below, but the present invention is not limited thereto.

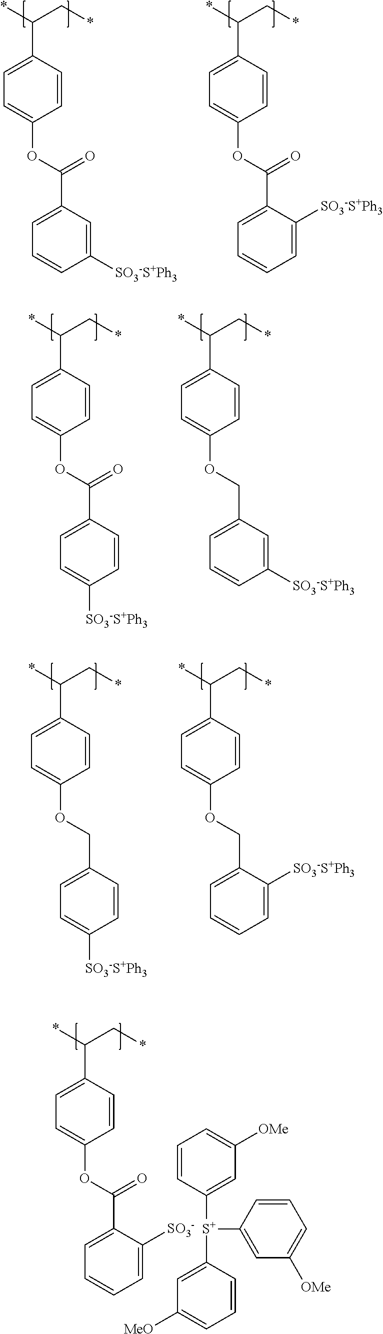

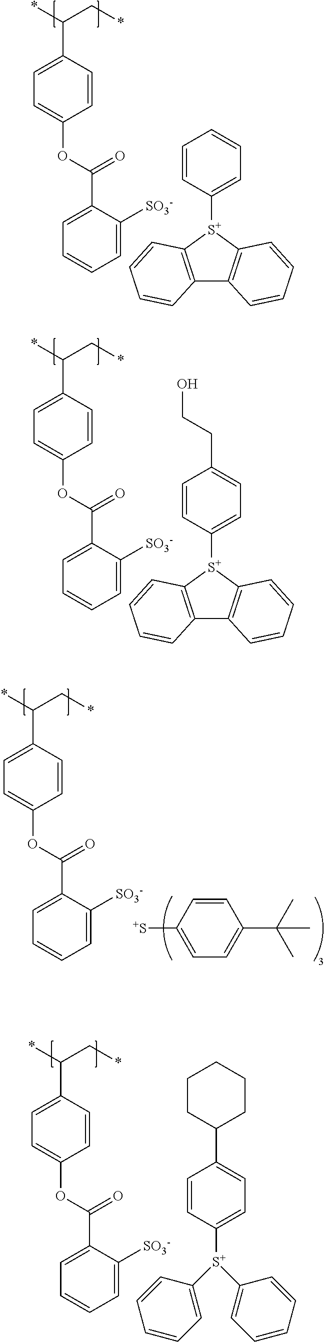

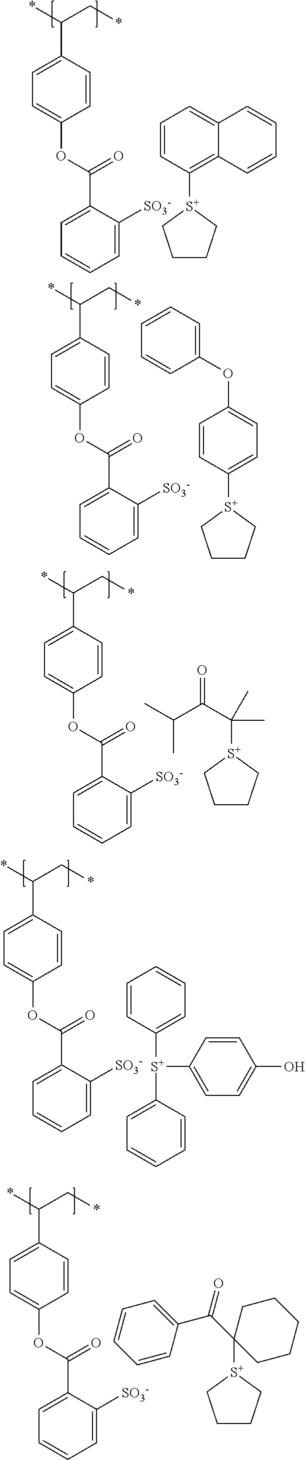

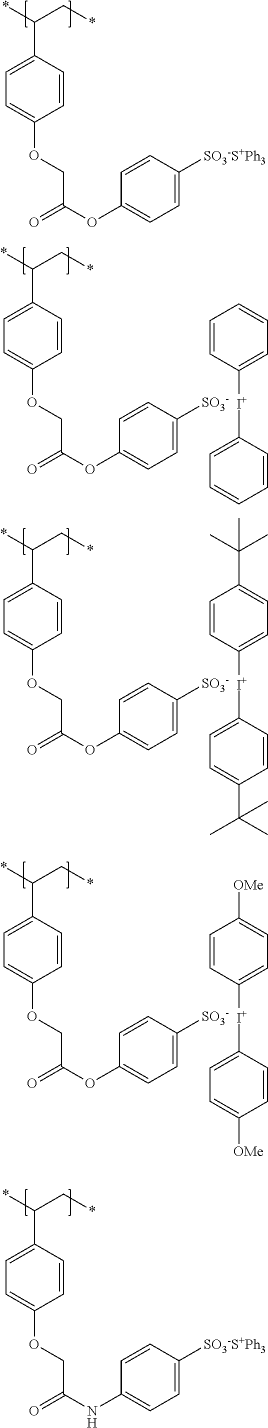

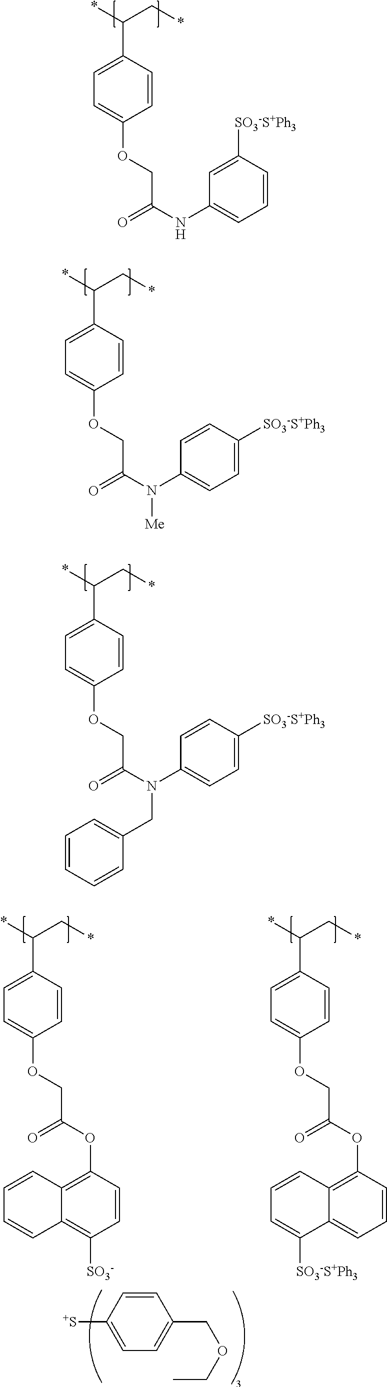

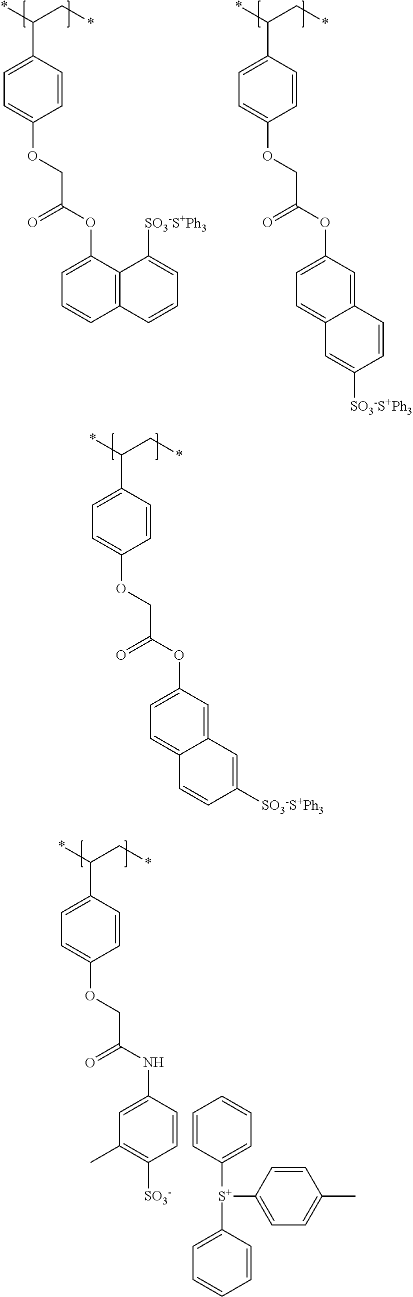

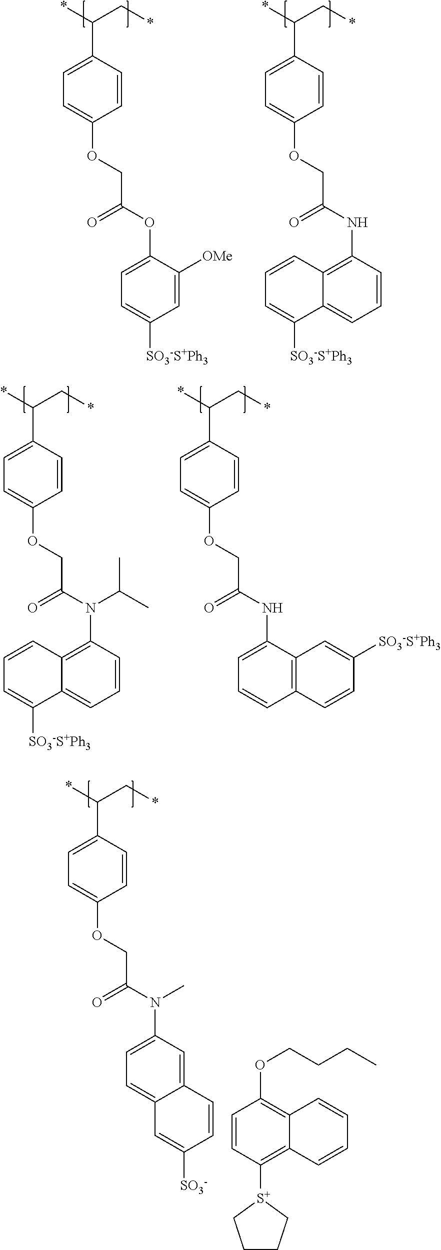

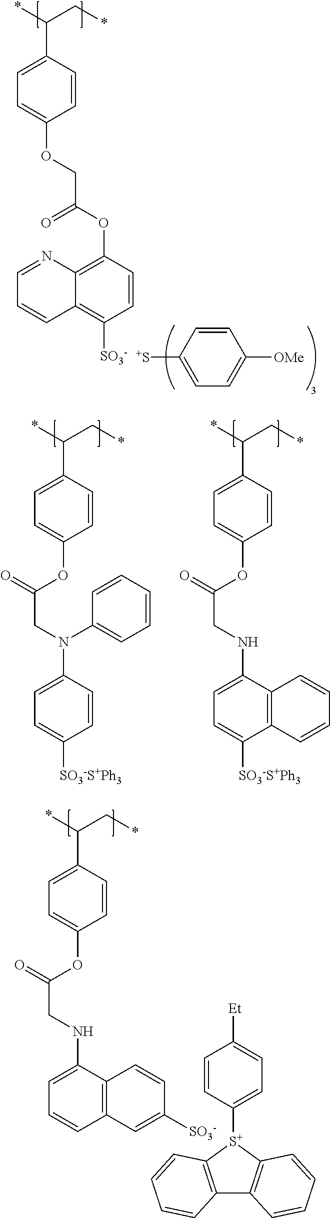

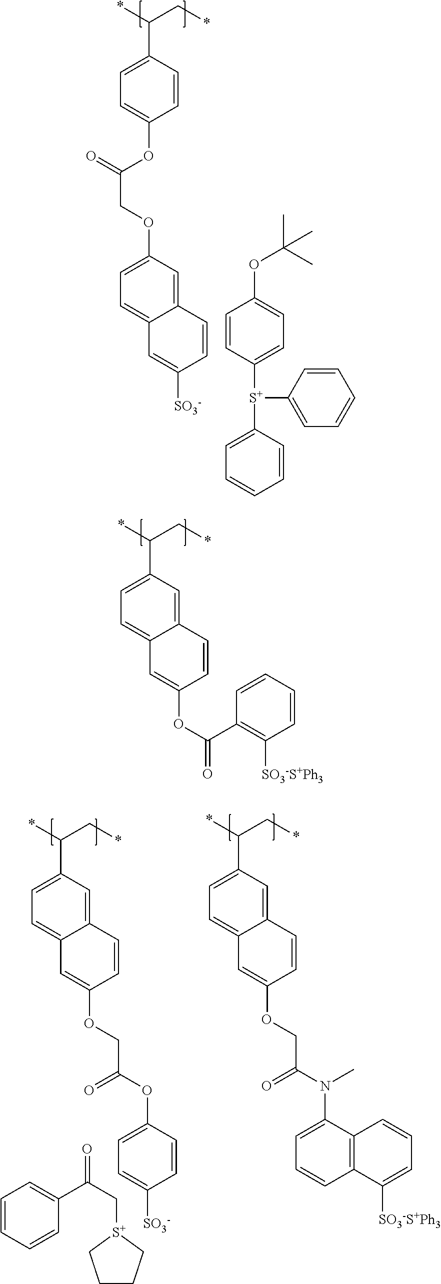

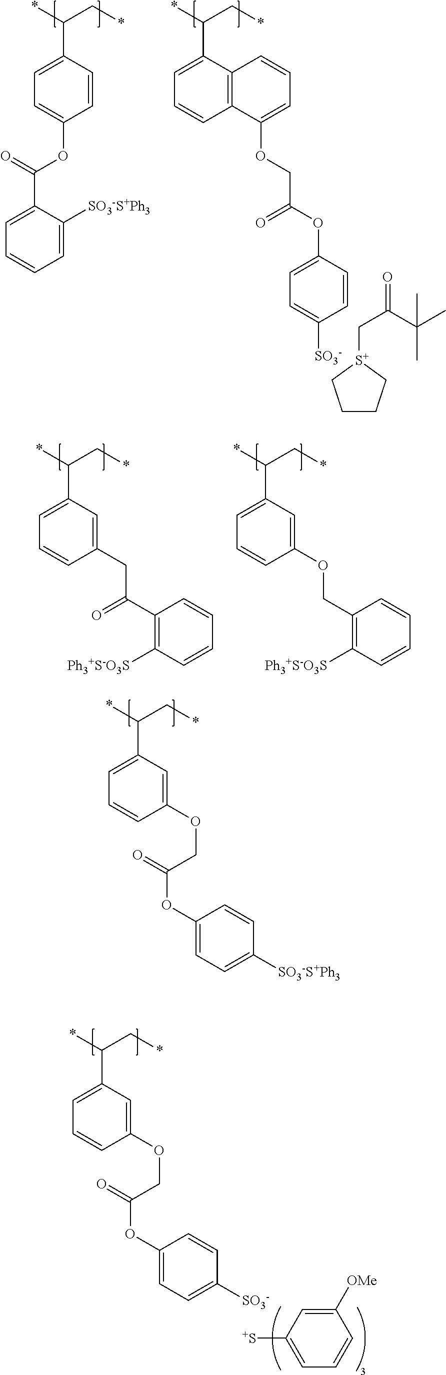

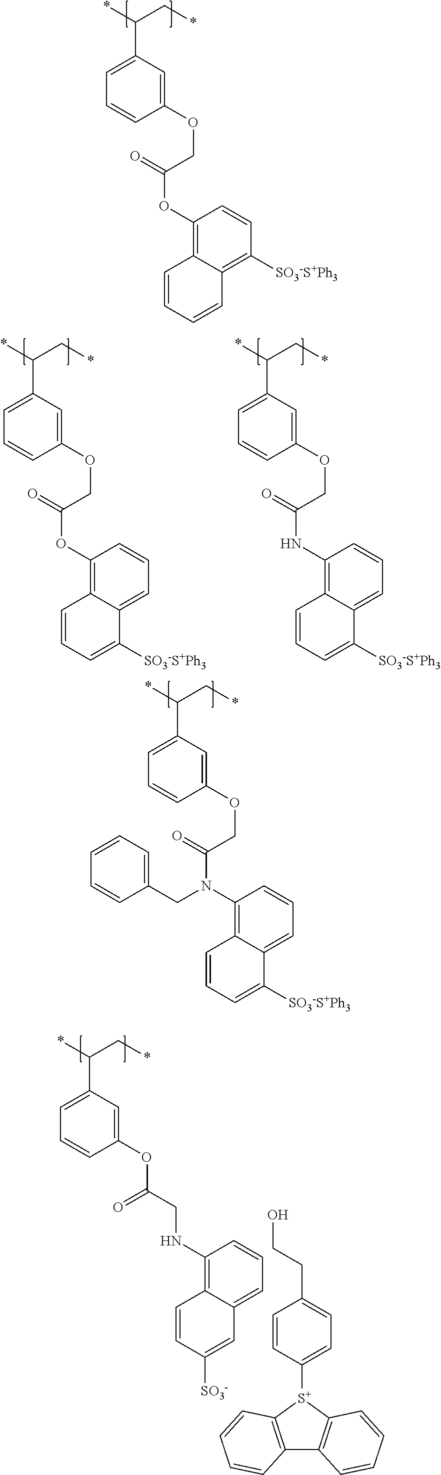

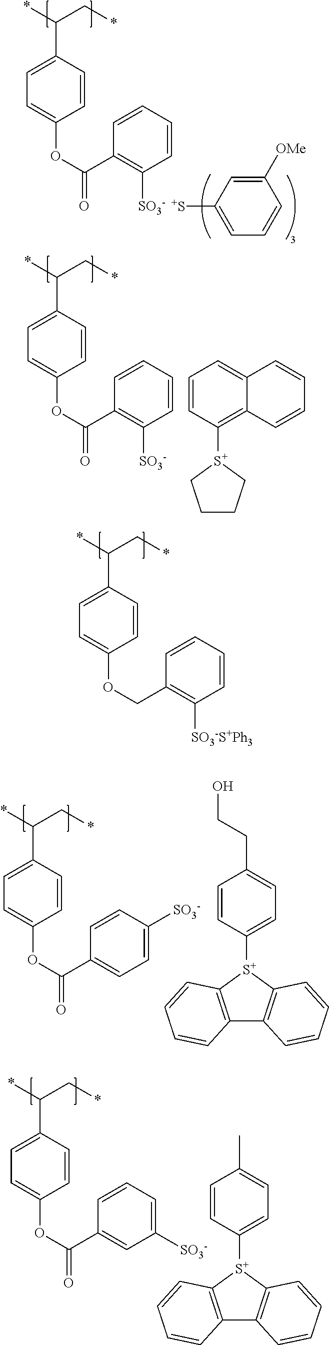

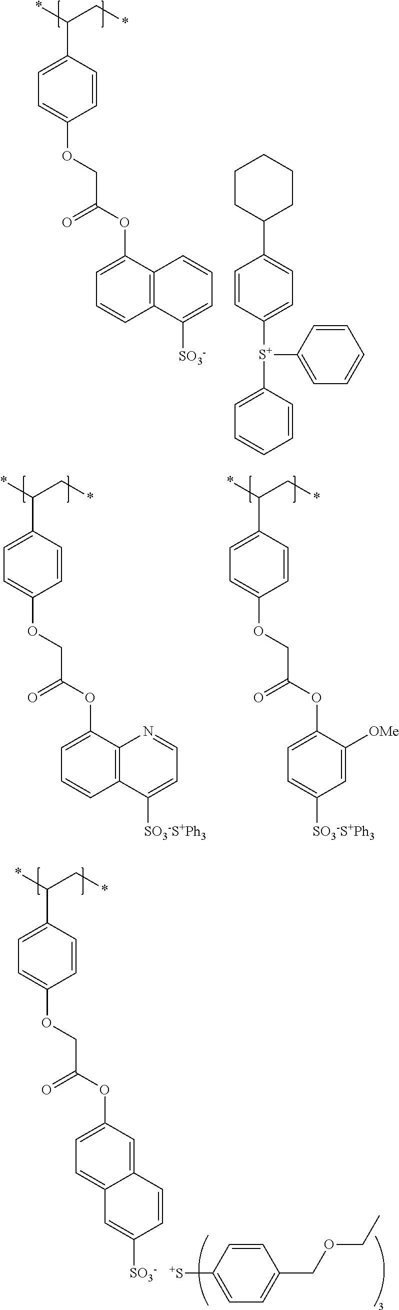

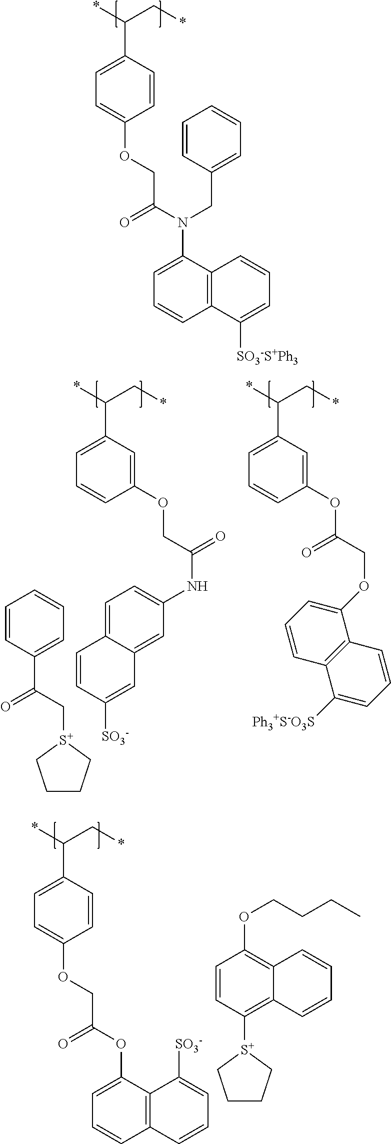

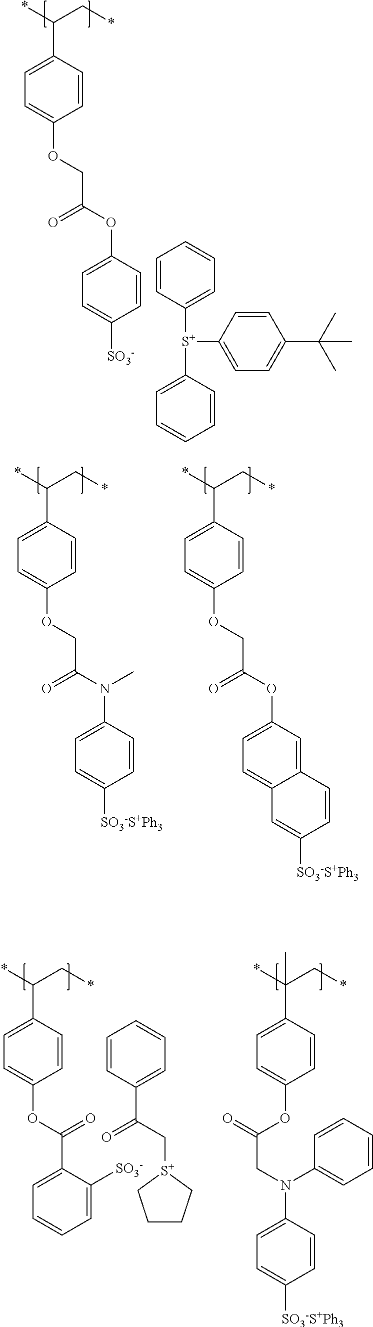

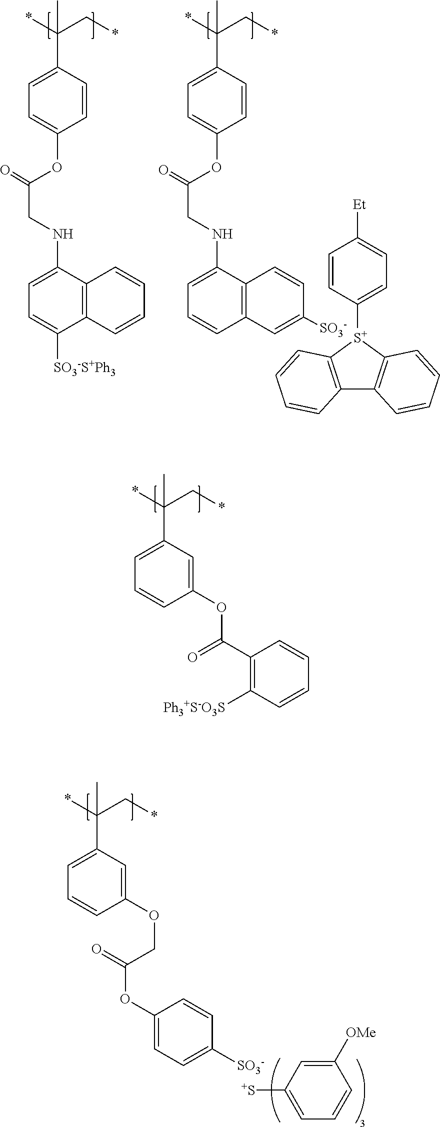

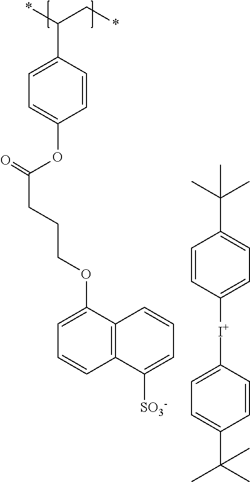

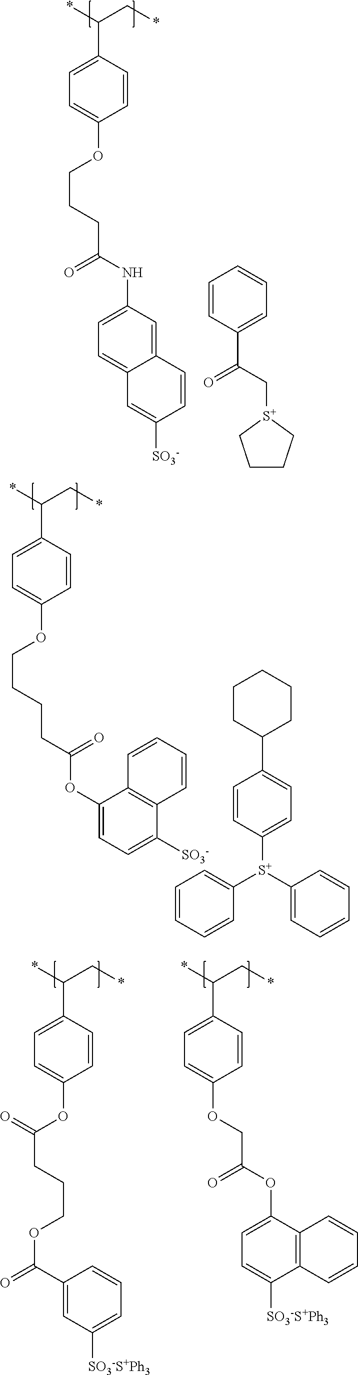

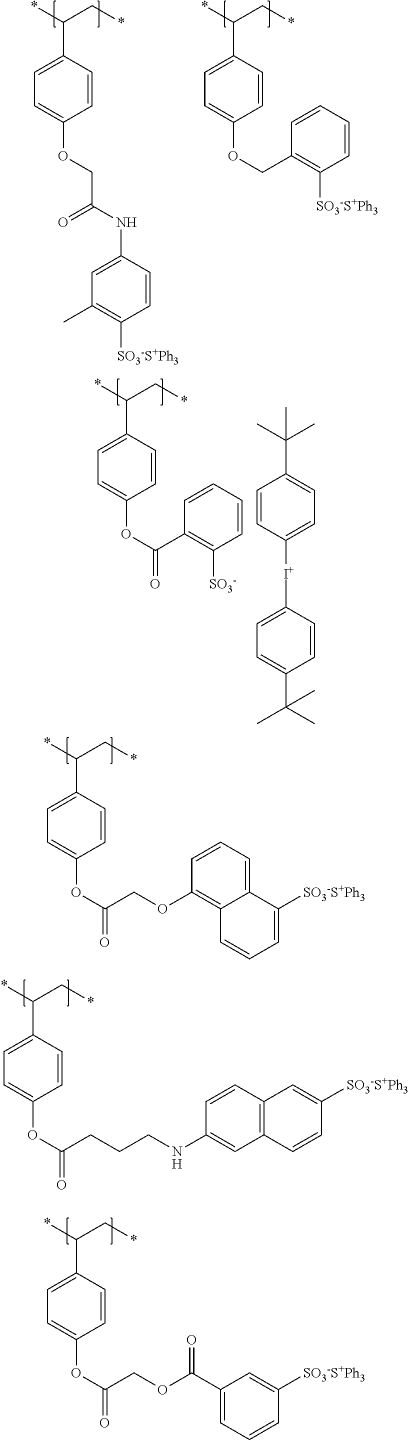

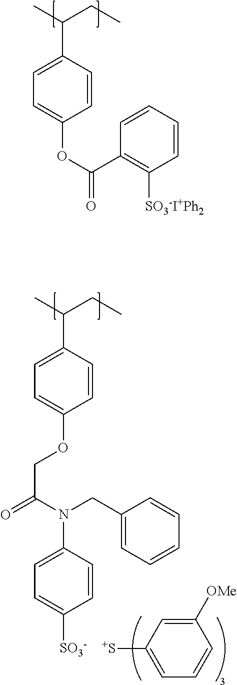

The content of the repeating unit represented by the general formula (2) in the high molecular compound (A) of the present invention is preferably the range of from 1 to 40 mol %, more preferably the range from 2 to 20 mol %, and particularly preferably the range from 2 to 15 mol %, based on all the repeating units in the high molecular compound (A).

Next, the repeating unit represented by the general formula (3) will be described.

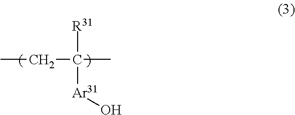

In the general formula (3), R³¹ represents a hydrogen atom or a hydrocarbon group, and Ar³¹ represents an arylene group.

R³¹ in the repeating unit represented by the general formula (3) represents a hydrogen atom or a methyl group, but is particularly preferably a hydrogen atom.

Ar³¹ in the repeating unit represented by the general formula (3) represents an arylene group, and may have a substituent other than —OH. The arylene group of Ar³¹ is preferably an arylene group having a carbon number of 6 to 18, which may have a substituent, more preferably a phenylene group or a naphthylene group which may have a substituent, and still more preferably a phenylene group which may have a substituent. In addition, the examples of the substituent which Ar³¹ may have, an alkyl group, a halogen atom, a hydroxyl group, an alkoxy group, a carboxyl group, an alkylcarbonyl group, and an alkoxycarbonyloxy group. It is preferable that the arylene group represented by Ar³¹ do not have a substituent other than —OH.

In the repeating unit represented by the general formula (3), when Ar³¹ is a phenylene group, the binding position of —OH to the benzene ring of Ar³¹ may be any of para, meta and ortho positions, relative to the binding position of the benzene ring with the polymer main chain, but the para or meta position is preferable.

The repeating unit represented by the general formula (3) has a function of controlling the alkali developing property of the resist with a repeating unit having an alkali-soluble group.

The specific examples of the repeating unit represented by the general formula (3) will be illustrated below.

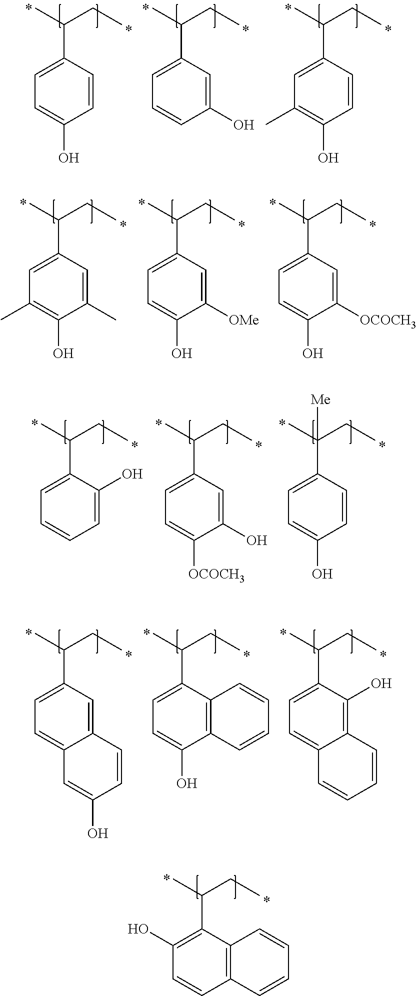

Among these, the preferred examples of the repeating unit represented by the general formula (3) is a repeating unit wherein Ar³¹ is an unsubstituted phenylene group, and include those illustrated below.

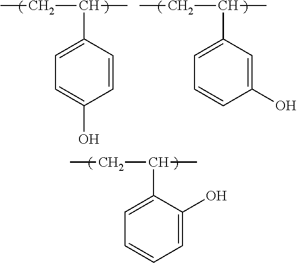

The content of the repeating unit represented by the general formula (3) in the high molecular compound (A) in the present invention is preferably 3 to 98 mol %, more preferably 40 to 90 mol %, and still more preferably 50 to 85 mol %, based on all the repeating units in the high molecular compound (A).

It is also preferable that the high molecular compound (A) used in the present invention further have, as a repeating unit other than the repeating unit represented by the general formulae (1), (2) and (3), the repeating unit as described below. In addition, needless to say, the sum of the contents of the repeating units represented by the general formulae (1) to (3), and the optional components (the repeating unit described below), contained in the high molecular compound (A), does not exceed 100 mol %.

For example, further, a repeating unit having a group which decomposes by the action of an alkaline developer to increase the dissolution rate into the alkaline developer can be mentioned. The examples of this group include a group having a lactone structure and a group having a phenyl ester structure, and the like, and as the repeating unit having a group which decomposes by the action of an alkaline developer to increase the dissolution rate into the alkaline developer, the repeating unit represented by the following general formula (AII) is more preferable.

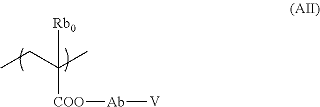

In the general formula (AII), V represents a group which decomposes by the action of an alkaline developer to increase the dissolution rate into the alkaline developer, Rb₀ represents a hydrogen atom or a methyl group, and Ab represents a single bond or a divalent organic group.

V, as a group which decomposes by the action of an alkaline developer, is a group having an ester bond, and among them, the group having a lactone structure is more preferable. While any group which has a lactone structure can be used as the group having the lactone structure, a 5- to 7-membered lactone structure is preferable, and a structure wherein other ring structure is fused with a 5- to 7-membered lactone structure in a form of forming a bicyclo structure, or spiro structure, is preferable.

Preferable Ab represents a single bond or a divalent linking group represented by -AZ—CO₂— (AZ is an alkylene group or an aliphatic ring group). Preferable AZ is a methylene group, an ethylene group, a cyclohexylene group, an adamantylene group and a norbornylene group.

Next, the specific examples are illustrated below. In the formulae, Rx represents H or CH₃.

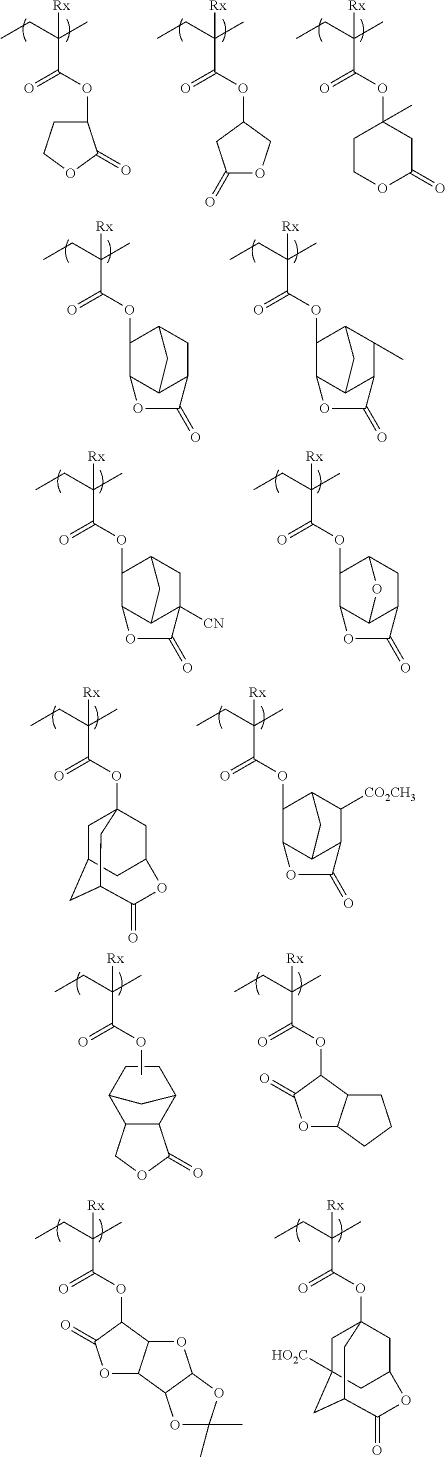

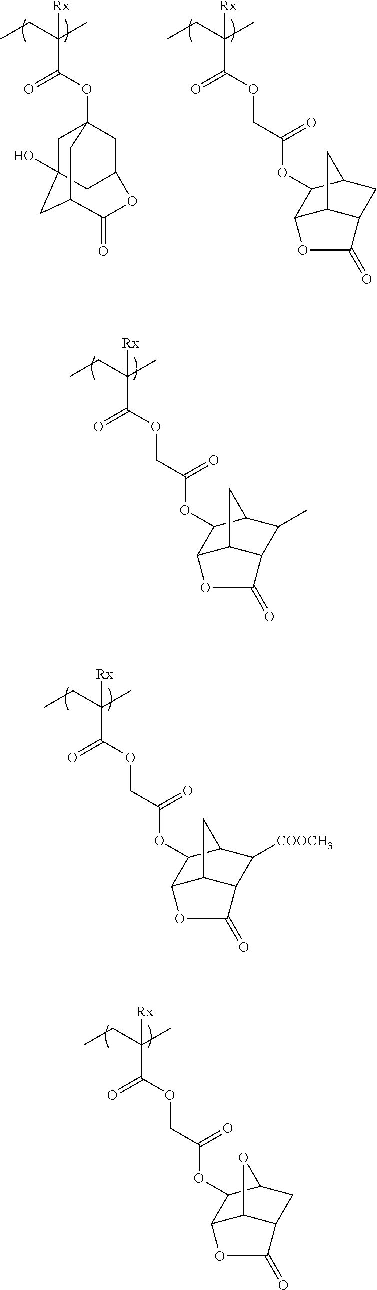

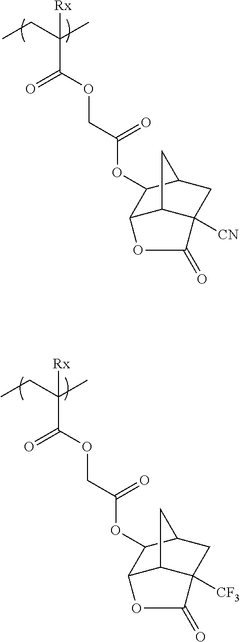

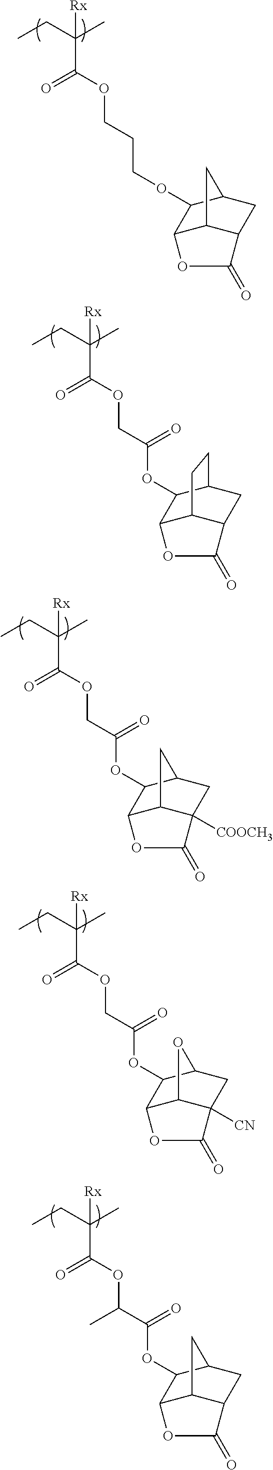

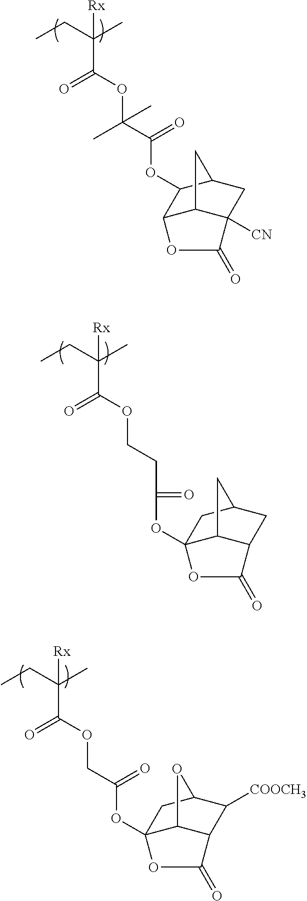

While the high molecular compound (A) may contain or may not contain a repeating unit having a group which decomposes by the action of an alkaline developer to increase the dissolution rate into the alkaline developer, in a case of having the group, the content of the repeating unit having the above group is preferably 10 to 60 mol %, more preferably 15 to 50 mol %, and still more preferably 15 to 40 mol %, based on all the repeating units in the high molecular compound (A).

The examples of the polymerizable monomer for forming a repeating unit other than the repeating units described above in the high molecular compound (A) of the present invention include styrene, alkyl substituted styrene, alkoxy substituted styrene, O-alkylated styrene, O-acylated styrene, hydrogenated hydroxystyrene, maleic anhydride, acrylic acid derivatives (acrylic acid, acrylic acid ester, and the like), methacrylic acid derivatives (methacrylic acid, methacrylic acid ester, and the like), N-substituted maleimide, acrylonitrile, methacrylonitrile, vinyl naphthalene, vinyl anthracene, indene which may have a substitutent, and the like. As the substituted styrene, 4-(1-naphthylmethoxy)styrene, 4-benzyloxy styrene, 4-(4-cholorobenzyloxy)styrene, 3-(1-naphthylmethoxy)styrene, 3-benzyloxy styrene, 3-(4-cholorobenzyloxy)styrene, and the like are preferable.

While the high molecular compound (A) may contain or may not contain the repeating units derived from these polymerizable monomers, in a case of containing the repeating units, the content of the repeating units in the high molecular compound (A) is generally 1 to 20 mol % and preferably 2 to 10 mol %, based on all the repeating units constituting the high molecular compound (A).

The high molecular compound (A) used in the present invention can be synthesized, for example by subjecting an unsaturated monomer corresponding to each repeating unit to a radical, cationic or anionic polymerization. In addition, it can be also synthesized by using an unsaturated monomer corresponding to the precursor of each repeating unit to polymerize a polymer and thereafter, modifying the synthesized polymer with a low molecular compound to convert to a desired repeating unit. In either case, by using a living polymerization such as a living anionic polymerization, the molecular weight distribution of the obtained high molecular compound becomes uniform and thus both cases are preferable.

The weight-average molecular weight of the high molecular compound (A) used in the present invention is preferably 1000 to 200000, more preferably 2000 to 50000, and still more preferably 2000 to 15000. The preferable dispersity of the high molecular compound (A) (molecular weight distribution) (Mw/Mn) is from 1.0 to 1.7, more preferably 1.0 to 1.3. The weight-average molecular weight (Mw), number-average molecular weight (Mn), and dispersity (Mw/Mn) of the high molecular compound (A) are defined by GPC measurements (solvent: THF, column: available from TOSOH CORPORATION TSK gel Multipore HXL-M, column temperature: 40° C., flow rate: 1.0 mL/min, detector: RI) in terms of standard polystyrene.

Next, while specific examples of the high molecular compound (A) used in the present invention will be illustrated, the present invention is not limited thereto.

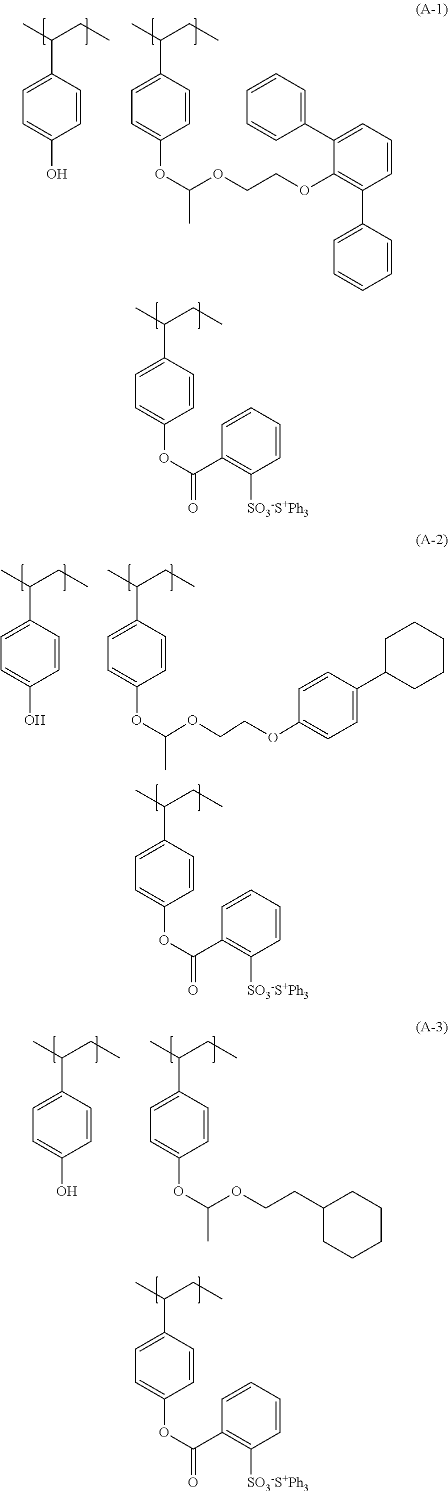

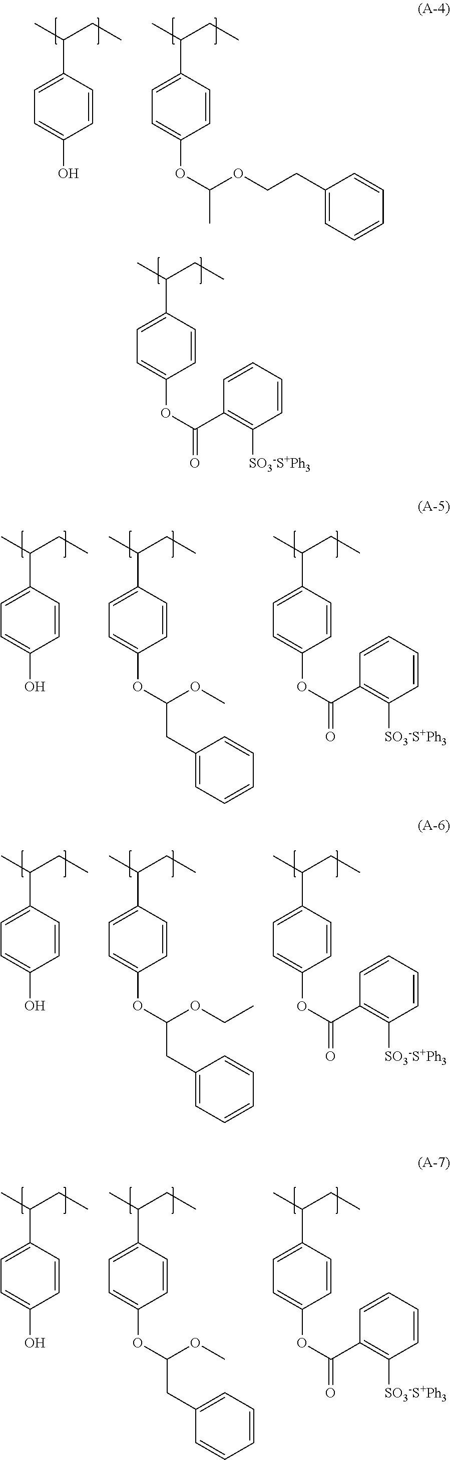

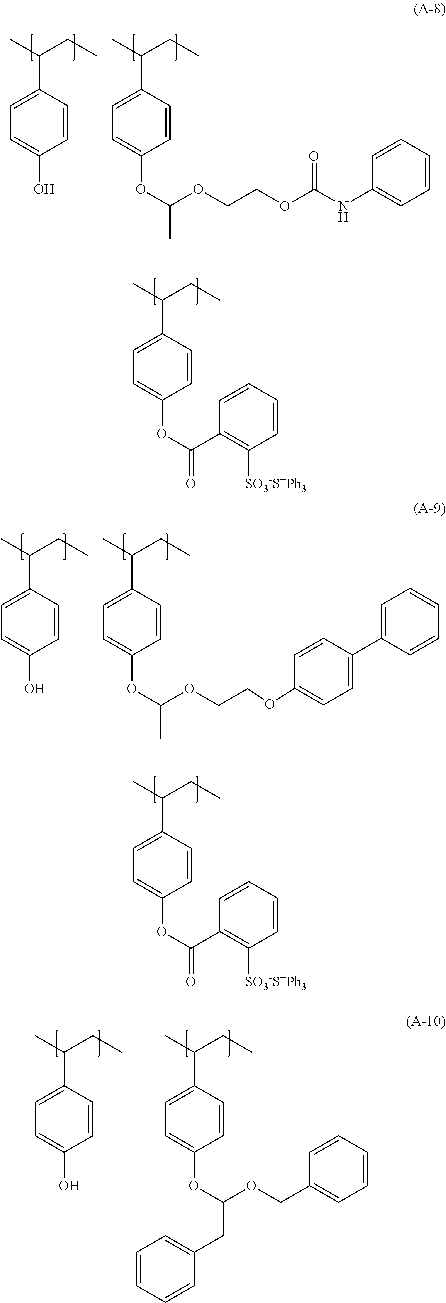

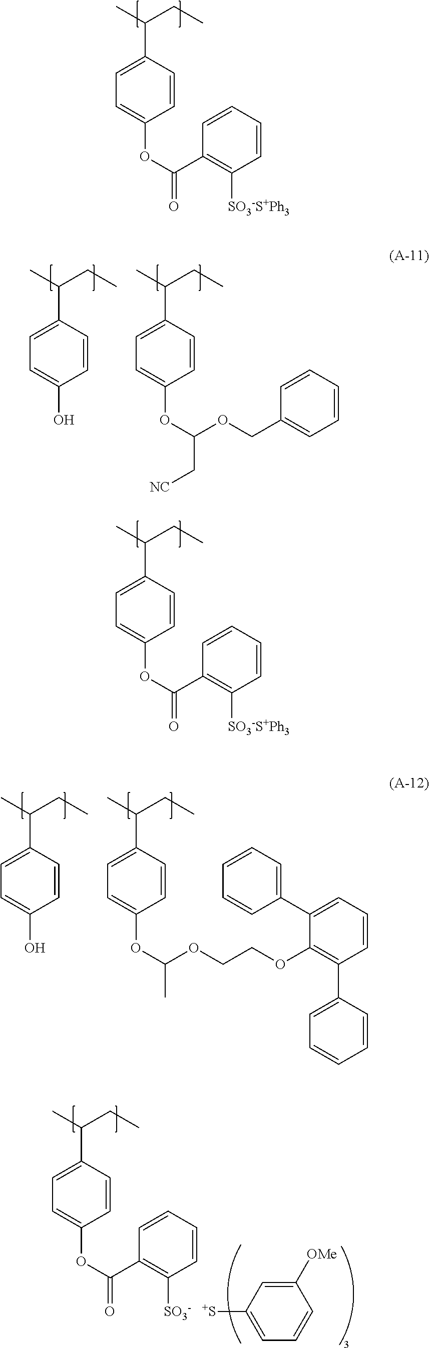

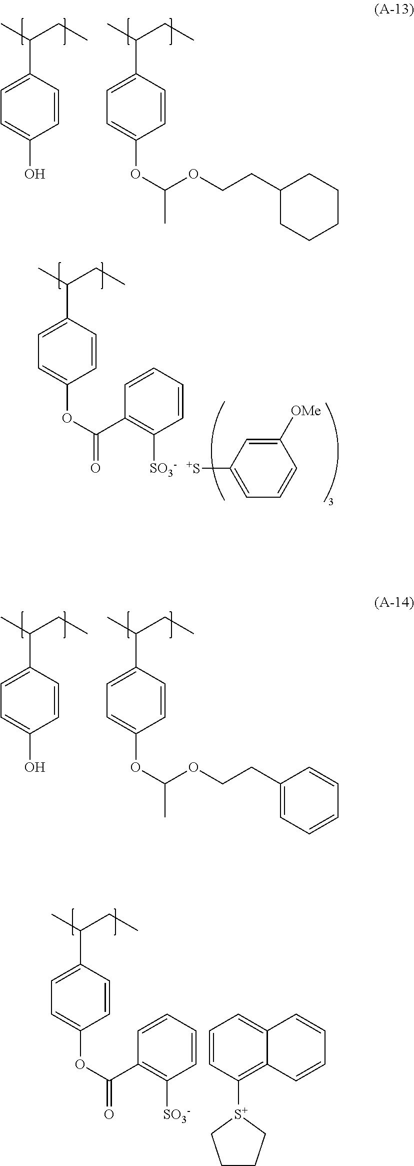

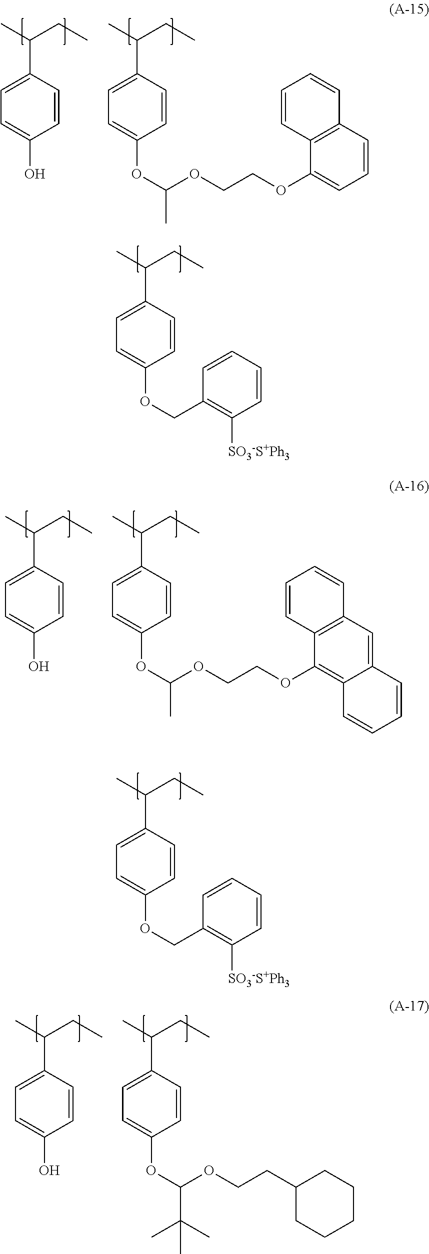

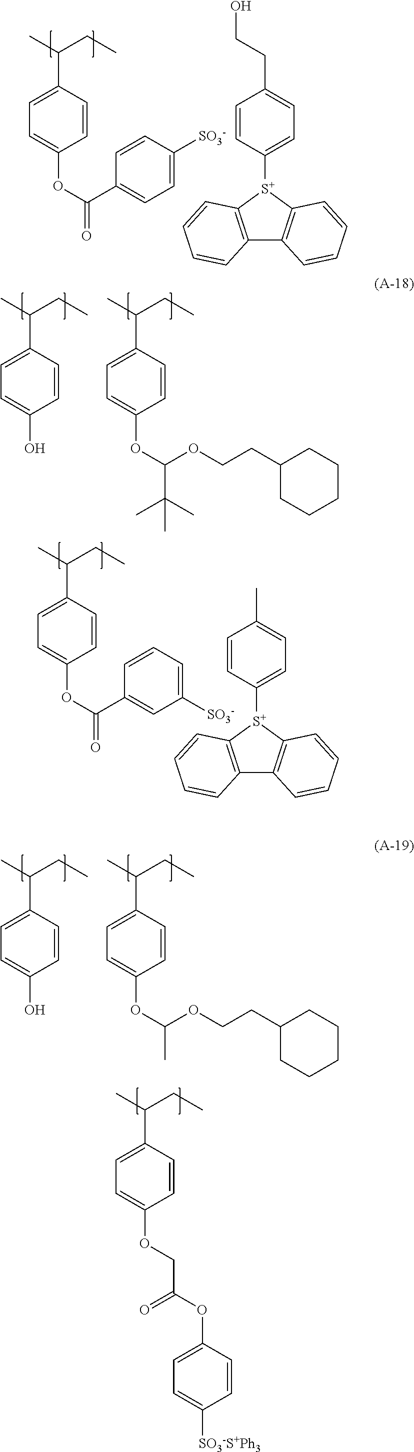

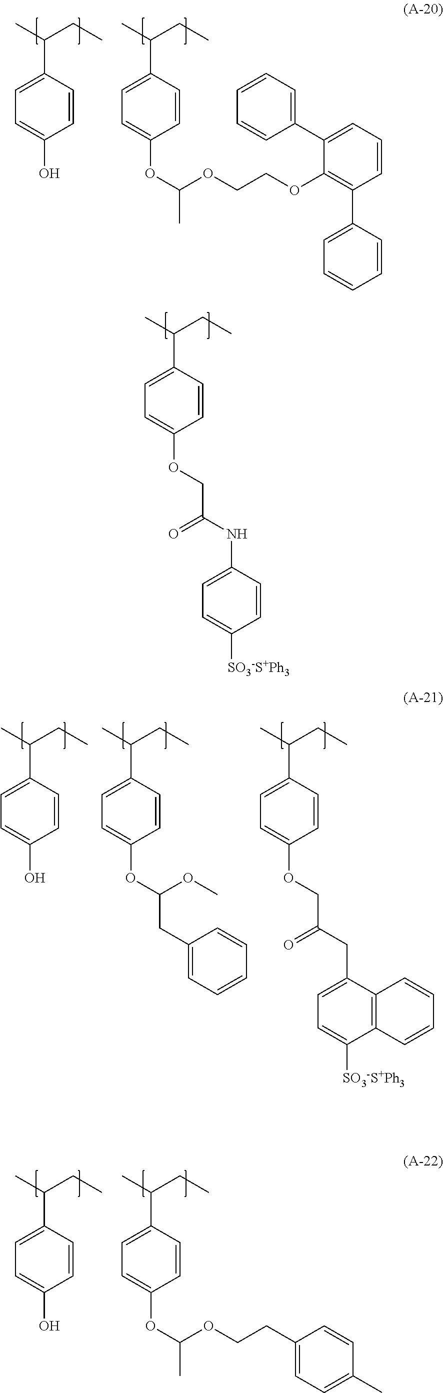

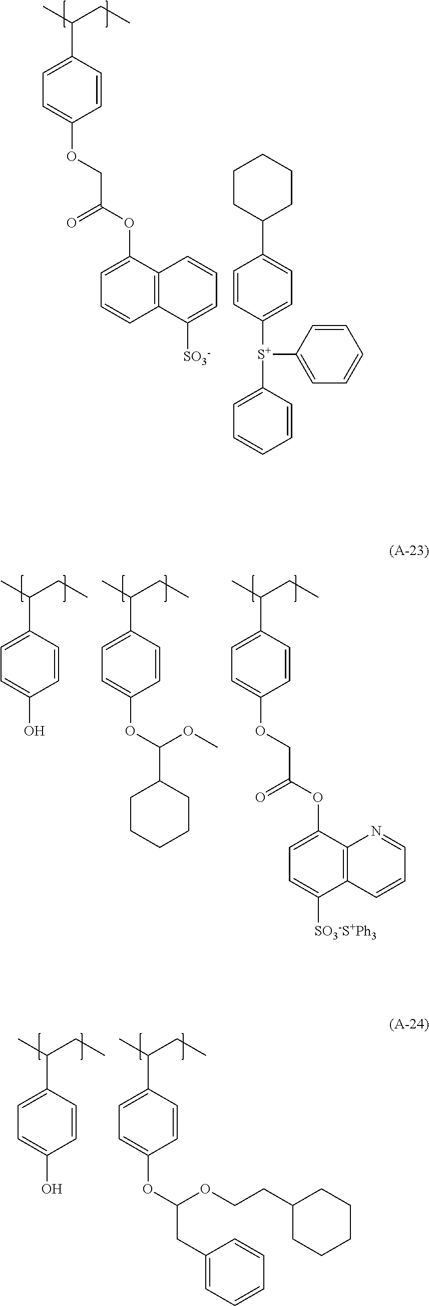

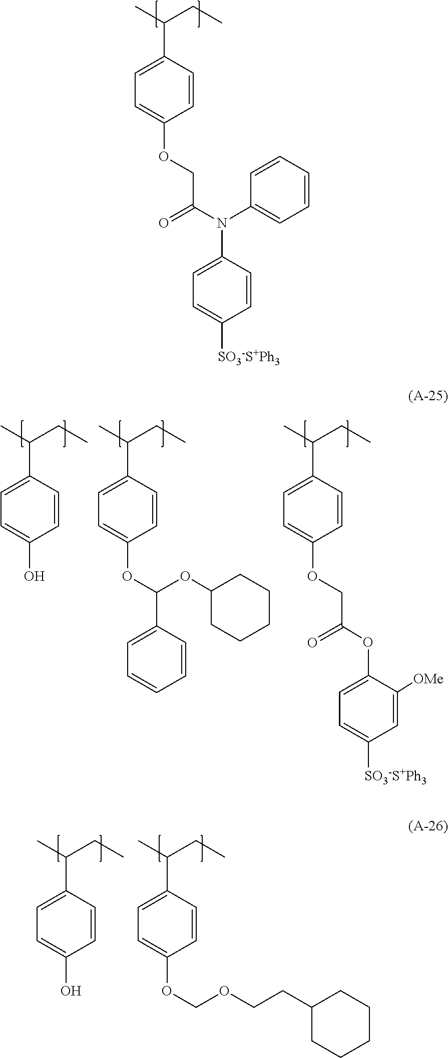

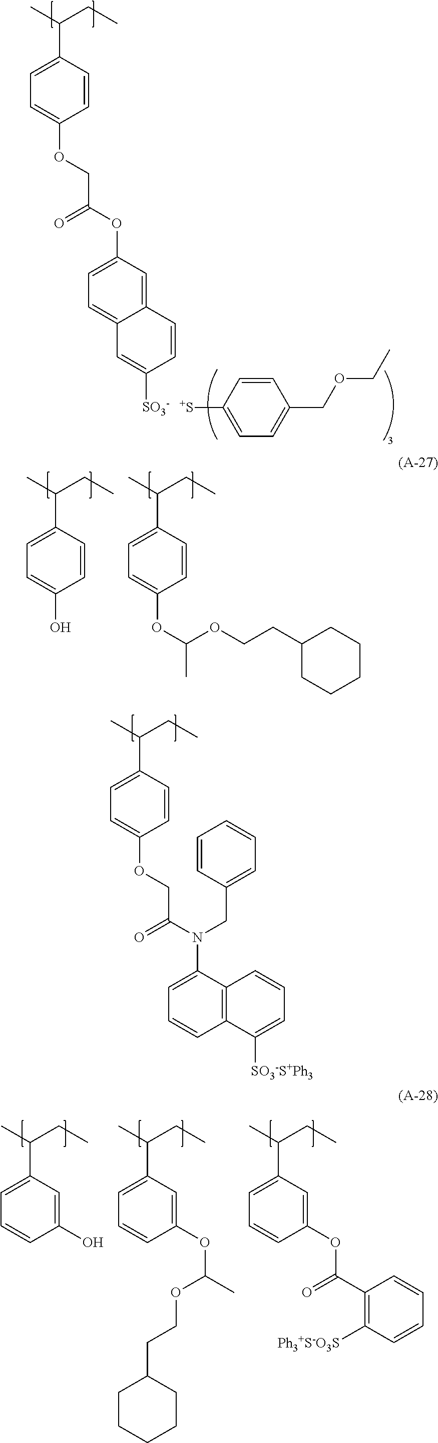

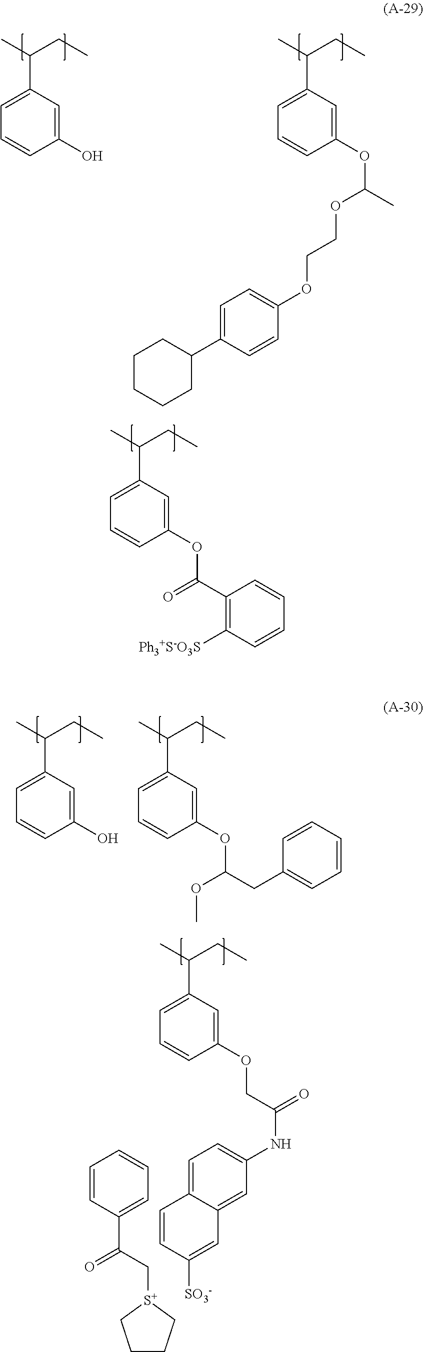

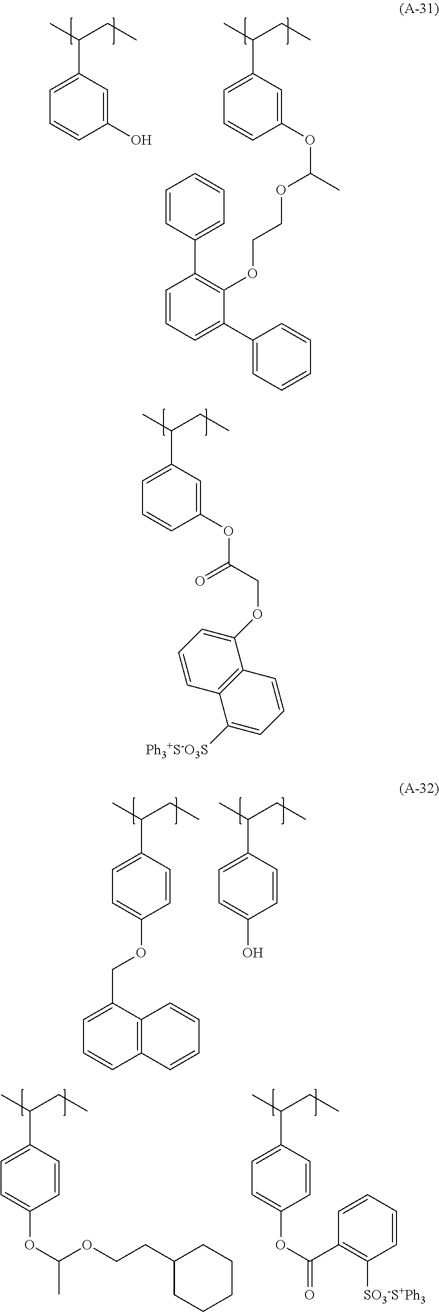

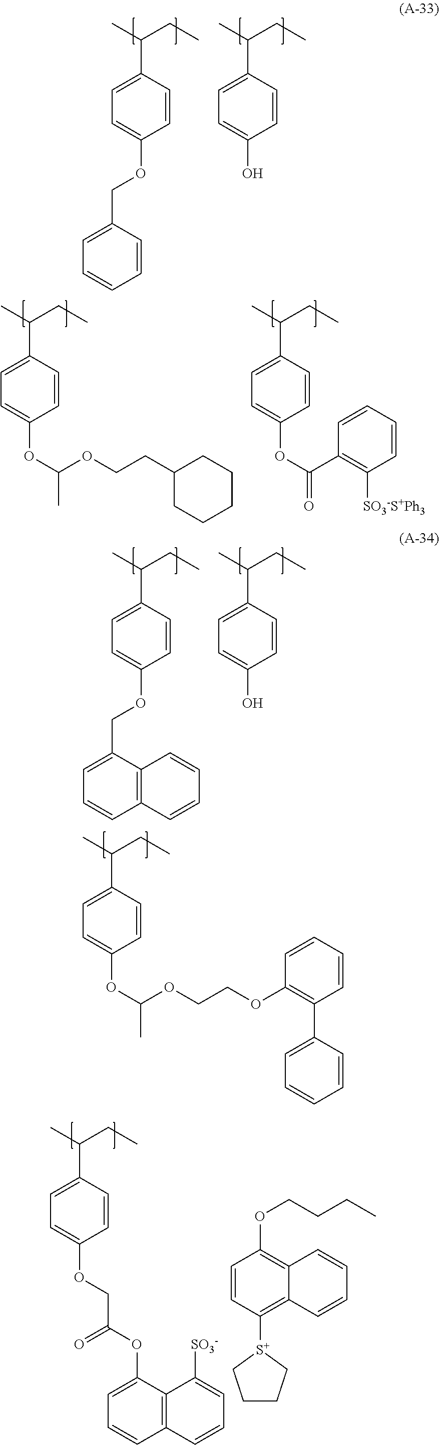

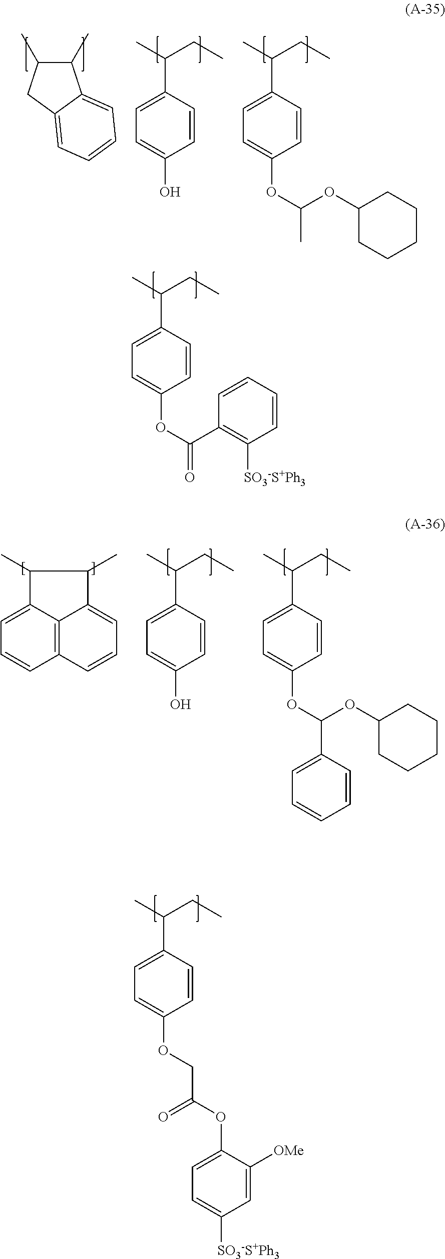

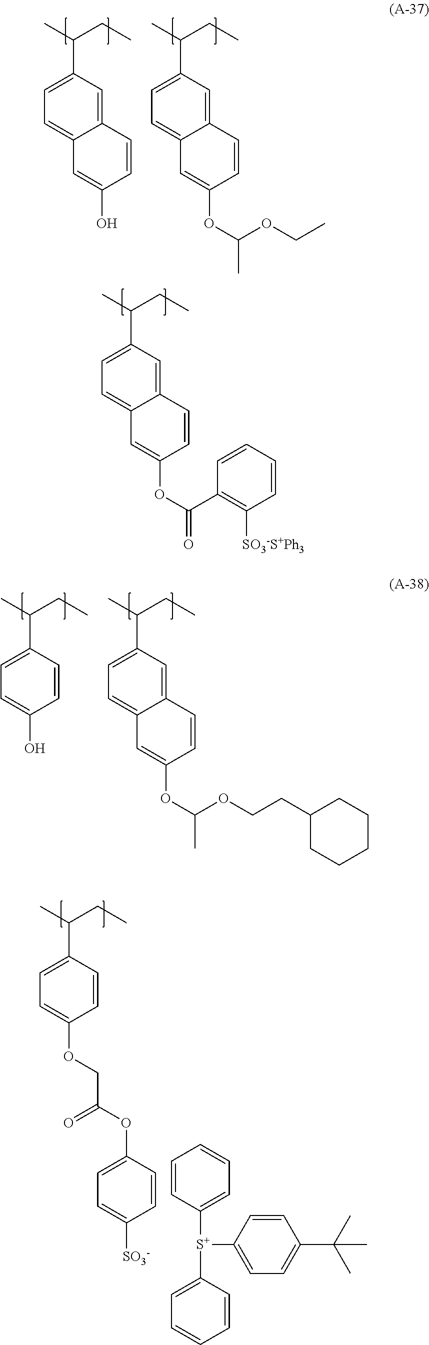

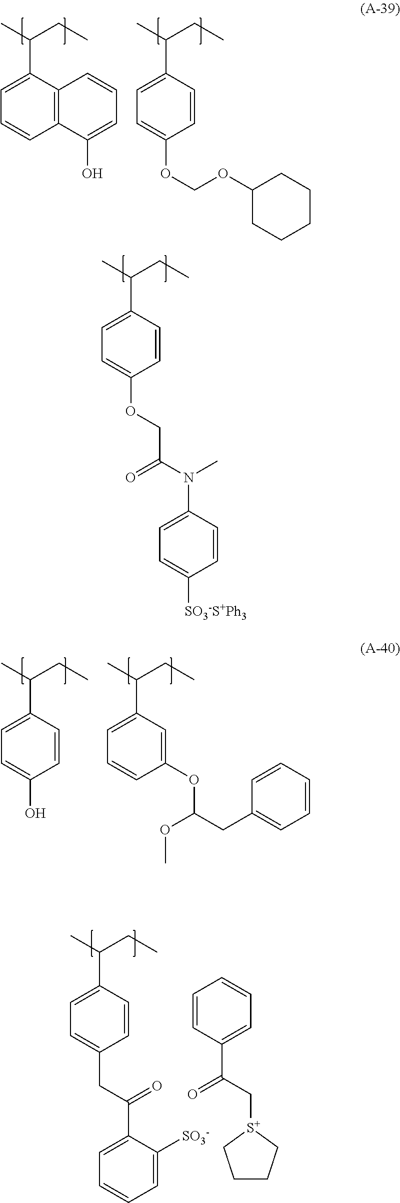

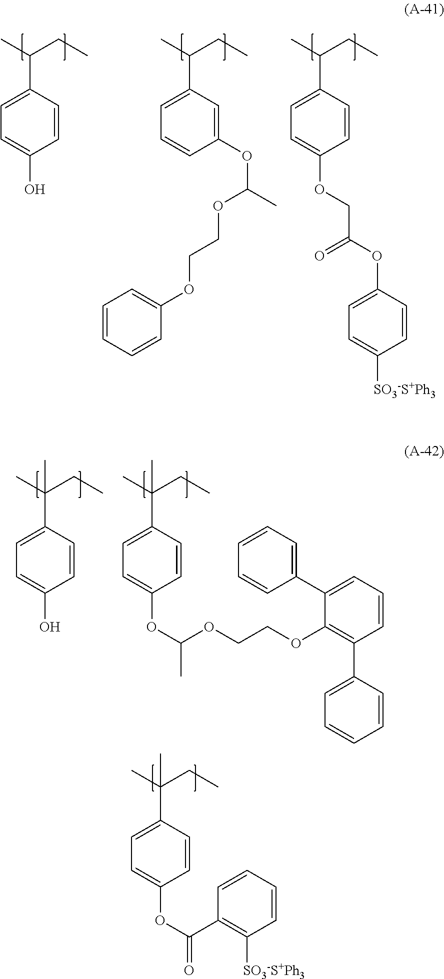

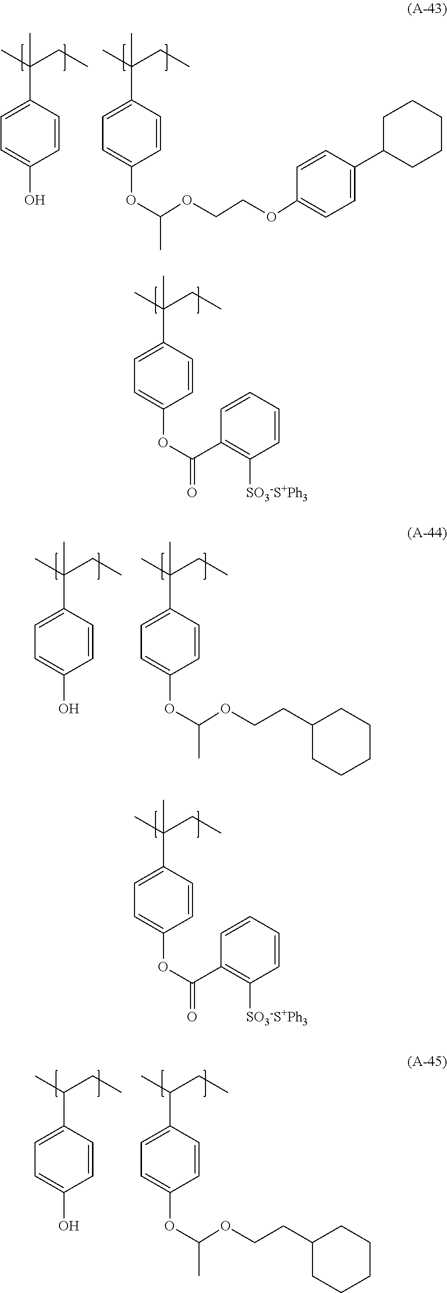

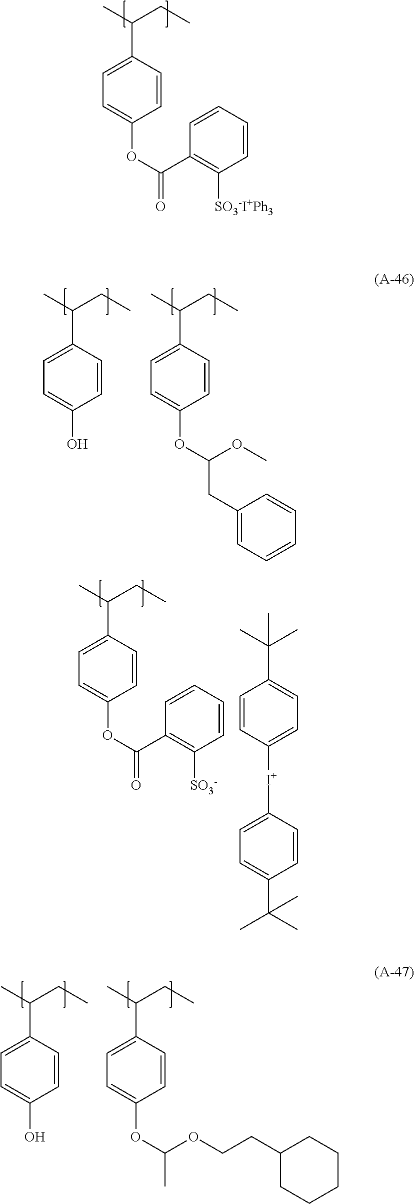

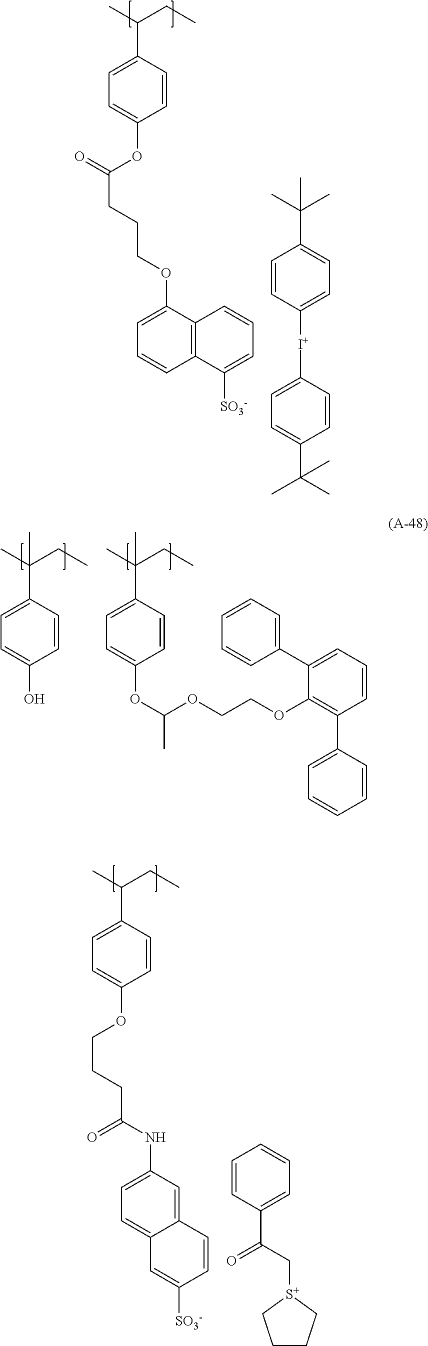

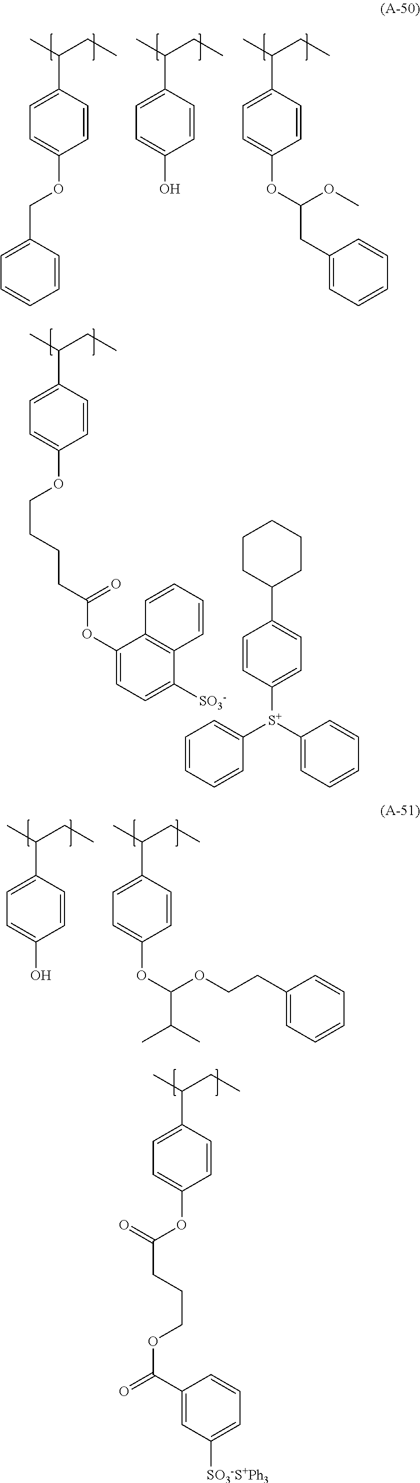

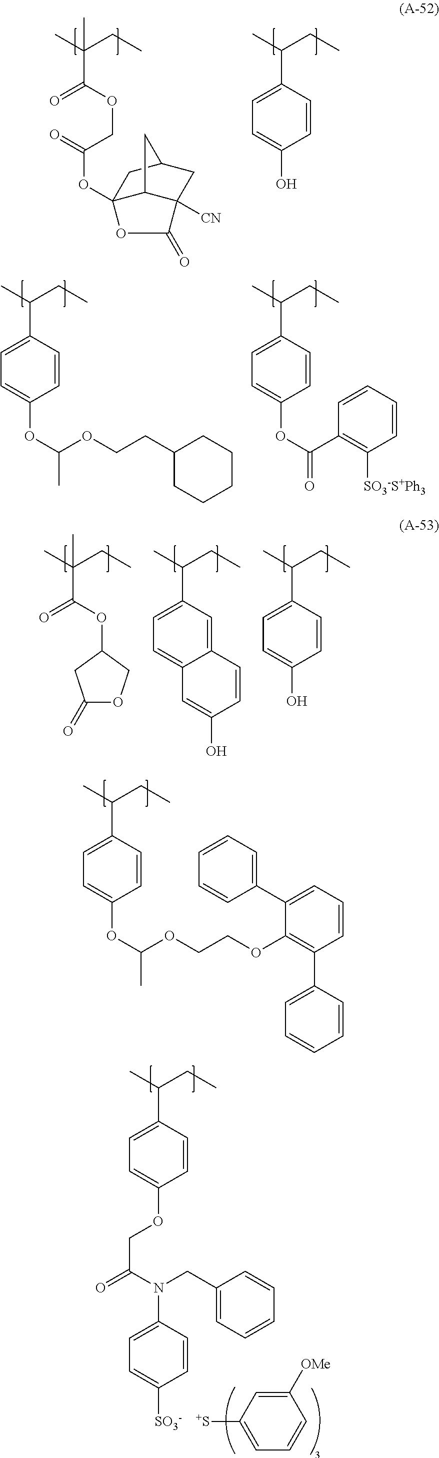

In addition, two or more of these high molecular compounds can be used in a combination.

The additive amount of the high molecular compound (A) used in the present invention is preferably 30 to 100% by mass, more preferably 50 to 99.7% by mass, and particularly preferably 70 to 99.5% by mass, based on total solid content of the composition.

[2] (B) A Low Molecular Compound Generating an Acid Upon Irradiation with Actinic Rays or Radiation.

The chemical amplification type positive resist composition of the present invention may further contain, a low molecular compound (B) generating an acid upon irradiation with actinic rays or radiation (hereinafter, as appropriate, these compounds are abbreviated to an “acid generator (B)”).

Herein, the term low molecular compound (B) means a compound other than a compound in which a site generating an acid upon irradiation with the actinic rays or radiation has been introduced into the main chain or the side chain of a high molecular compound, and is typically a compound in which the site has been introduced into a single molecular compound. The molecular weight of the low molecular compound (B) is generally 4000 or less, preferably 2000 or less, and more preferably 1000 or less. In addition, the molecular weight of the low molecular compound (B) is generally 100 or more, and preferably 200 or more.

The preferable forms of the acid generator (B) can include onium compounds. The examples of such an acid generator (B) can include sulfonium salts, iodonium salts and phosphonium salts, and the like.

In addition, another preferable forms of the acid generator (B) can include, upon irradiation with the actinic rays or radiation, a compound generating sulfonic acids, imide acids or methide acids. The examples of the acid generator (B) in this form can include sulfonium salts, iodonium salts, phosphonium salts, oxime sulfonates and imidosulfonates, and the like.

It is preferable that the acid generator (B) be a compound generating an acid upon irradiation with an electron beam.

The chemical amplification type positive resist composition of the present invention may or may not contain the acid generator (B), but in a case of containing the generator, the content of the acid generator in the composition is preferably 0.1 to 20% by mass, more preferably 0.5 to 10% by mass, and still more preferably 1 to 7% by mass, based on total solid content in the resist composition.

The acid generator can be used alone or two or more kinds thereof can be used in a combination.

(3) A Basic Compound

It is preferable that the chemical amplification type positive resist composition of the present invention contains a basic compound as an acid scavenger, in addition to the aforementioned components. By using the basic compound, the performance change with time from exposure to post-exposure baking can be decreased. As such basic compound, an organic basic compound is preferred, and more specific examples thereof include aliphatic amines, aromatic amines, heterocyclic amines, nitrogen-containing compounds having a carboxyl group, nitrogen-containing compounds having a sulfonyl group, nitrogen-containing compounds having a hydroxyl group, nitrogen-containing compounds having a hydroxylphenyl group, alcoholic nitrogen-containing compounds, amide derivatives and imide derivatives, and the like. Amine oxide compounds (disclosed in JP2008-102383A), and ammonium salts (preferred is hydroxide or carboxylate. More specifically, tetraalkyl ammonium hydroxides represented by tetrabutyl ammonium hydroxide are preferable in view of LER.) can also be suitably used.

Further, compounds of which the basicity increase by the action of an acid can also be used as one kind of basic compound.

Specific examples of the amines include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline, triethanolamine, N,N-dihydroxyethylaniline, tris(methoxyethoxyethyl)amine, and compounds illustrated in U.S. Pat. No. 6,040,112A, column 3, line 60 et seq., 2-[2-{2-(2,2-dimethoxy-phenoxyethoxy)ethyl}-bis-(2-methoxyethyl)]-amine, and Compounds (C1-1) to (C3-3) illustrated in paragraph [0066] of US2007/0224539A1, and the like. The examples of compounds having a nitrogen-containing heterocyclic structure include 2-phenylbenzimidazole, 2,4,5,-triphenylimidazole, N-hydroxyethylpiperidine, bis(1,2,2,6,6-pentamethyl-4-piperidyl) sebacate, 4-dimethylaminopyridine, antipyrine, hydroxyantipyrine, 1,5-diazabicyclo [4.3.0]non-5-ene and 1,8-diazabicyclo [5.4.0]-undec-7-ene, and the like. As an ammonium salt, tetrabutylammonium hydroxide is preferable.

Among these basic compounds, inter alia, ammonium salts are preferable in view of the improvement of resolution.

The chemical amplification type positive resist composition of the present invention may or may not contain the basic compound, but in a case of containing the compound, the content of the basis compound used in the present invention is preferably 0.01 to 10% by mass, more preferably 0.03 to 5% by mass, and particularly preferably 0.05 to 3% by mass, based on the total solid content in the resist composition.

[4] Surfactant

The chemical amplification type positive resist composition of the present invention may further contain a surfactant for improving coating properties. The examples of the surfactant are not particularly limited thereto, but include nonionic surfactants such as polyoxyethylene alkyl ethers and polyoxyethylene alkylaryl ethers, polyoxyethylene polyoxypropylene block copolymers, sorbitan fatty acid esters and polyoxyethylene sorbitan fatty acid esters, fluorine-based surfactants such as Florad FC 430 (available from Sumitomo 3M Limited) or Surfynol E 1004 (available from ASAHI GLASS CO., LTD.), PF656 and PF6320 available from OMNOVA Solutions Inc, and organosiloxane polymers.

The chemical amplification type positive resist composition of the present invention may or may not contain the surfactant, but in a case where the resist composition contains the surfactant, the amount of the surfactant used is preferably from 0.0001 to 2% by mass, and more preferably from 0.0005 to 1% by mass, based on the total amount of the resist composition (except for the solvent).

The chemical amplification type positive resist composition of the present invention can further contain, as necessary, dyes, plasticizers, photodecomposable basic compounds, photobase generators, and the like. With regard to all of these compounds, respective compounds disclosed in JP2002-6500A can be mentioned. In addition, needless to say, the sum of the contents of the high molecular compound (A), the optional component (the low molecular compound (B), the basic compound, and in addition to the surfactant, the dyes, and the like), which are included in the resist composition of the present invention does not exceed 100% by mass, based on the total amount of the resist composition (except for the solvent).

In addition, the preferable examples of the solvent which is used in the positive resist composition of the present invention include ethylene glycol monoethyl ether acetate, cyclohexanone, 2-heptanone, propylene glycol monomethyl ether (PGME, also called 1-methoxy-2-propanol), propylene glycol monomethyl ether acetate (PGMEA, also called 1-methoxy-2-acetoxypropane), propylene glycol monomethyl ether propionate, propylene glycol monoethyl ether acetate, methyl 3-methoxypropionate, ethyl 3-ethoxypropionate, methyl β-methoxy isobutyrate, ethyl butyrate, propyl butyrate, methyl isobutyl ketone, ethyl acetate, isoamyl acetate, ethyl lactate, toluene, xylene, cyclohexyl acetate, diacetone alcohol, N-methylpyrrolidone, N,N-dimethyl formamide, γ-butyrolactone, N,N-dimethyl acetamide, propylene carbonate, ethylene carbonate, and the like. These solvents may be used alone, or two or more thereof may be used in combination.

The solid content of the resist composition is dissolved in the above-described solvent and the solid content concentrations become from 1 to 40% by mass, more preferably from 1 to 30% by mass, and still more preferably is 3 to 20% by mass.

The present invention also includes a resist film which is formed by using the chemical amplification type positive resist composition of the present invention. Such a resist film is, for example, formed by applying the resist composition of the present invention to a support such a substrate. The chemical amplification type positive resist composition of the present invention is applied to the substrate by an appropriate coating method such as spin coating, roller coating, flow coating, dip coating, spray coating, doctor coating, and is pre-baked at 60 to 150° C., for 1 to 20 minutes, preferably at 80 to 130° C., for 1 to 10 minutes to form a thin film. The thickness of this coated film is preferably 30 to 200 nm.

The substrate suitable for the present invention is silicon substrate, a substrate provided with a metal-vapor deposited film or a metal-containing film, more suitably a substrate provided with a vapor-deposited film by Cr, MoSi, TaSi, or the oxide or the nitride thereof on the surface.

In addition, the present invention includes resist coated mask blanks having the resist film obtained as described above. In order to obtain such resist coated mask blanks, in a case where a resist pattern is formed on the photomask blanks for the production of the photomask, the examples of the transparent substrate used can include transparent substrates such as quartz and calcium fluoride, and the like. Generally, on the substrate, the intended one from the functional films called a light-shielding film, an antireflection film, further a phase shift film, additionally an etching stopper film or an etching mask film is laminated. As the functional film, a film containing transition metals such as silicon, chromium, molybdenum, zirconium, tantalum, tungsten, titanium, niobium is laminated thereon. In addition, the examples of the material used for an outermost layer include a material which has, as a main constituent material, a material containing silicon or silicon and oxygen and/or nitrogen; a silicon compound material which has, as a main constituent material, a material further containing transition metals in addition thereto; and a transition metal compound material which has, as a main constituent material, transition metals, in particular, at least one selected from chromium, molybdenum, zirconium, tantalum, tungsten, titanium and niobium, and the like, or a material further containing at least one element selected from oxygen, nitrogen and carbon in addition thereto.

While the light-shielding film may be monolayer, a multilayer structure including the laminated plural materials is more preferable. In a case of the multilayer structure, while the film thickness per layer is not particularly limited, the thickness of 5 nm to 100 nm is preferable, and 10 nm to 80 nm is more preferable. While the thickness of the entire light-shielding film is not particularly limited, the thickness of 5 nm to 200 nm is preferable, and 10 nm to 150 nm is more preferable.

Among these materials, in general, in a case where a pattern forming is performed on the photomask blanks which have a material containing oxygen or nitrogen together with chromium on the outermost layer thereof, by using a chemical amplification resist composition, the skirt shape pattern is formed near the substrate, a so-called tapered shape is likely to be produced, whereas in a case where the present invention is used, as compared with those of the prior art, it is more difficult to become a tapered pattern.

Then, the actinic rays or radiation (an electron beam, and the like) is irradiated to this resist film, and preferably the baking (usually 80 to 150° C., more preferably 90 to 130° C.) is performed and thereafter is developed. By this, a good pattern can be obtained. Additionally, using this pattern as a mask, an appropriate etching treatment and an ion implantation and the like are performed to construct semiconductor micro-circuits and a mold structure for imprint, and the like.

In addition, with regard to the process of a case of producing the mold for imprint by using the composition of the present invention, it is disclosed in for example JP4109085B, JP 2008-162101A and, “The Basis and the Technological Development and the Deployment of Application of Nanoimprint—the Fundamental Technology and the Latest Deployment of Technology of Nanoimprint—Editor: Yoshihiko HIRAI, Publisher: Frontier”.

The usage types of the chemical amplification type positive resist composition and a method of forming a resist pattern according to the present invention are then described.

The present invention also embraces a method of forming a resist pattern which includes exposing the resist film or the resist coated mask blanks, and developing the exposed resist film or the resist coated mask blanks In the present invention, it is preferable that the exposing be performed by using an electron beam.

In the production of the precision integrated circuit element, and the like, as for the exposure onto the resist film (a process of forming a pattern), first, it is preferable that the irradiation with an electron beam be performed in a pattern profile onto the resist film of the present invention. The irradiation amount (the exposure amount) is, approximately 0.1 to 60 μC/cm², preferably approximately 3 to 50 μC/cm². Then, on hot plates, at 60 to 150° C. for 1 to 20 minutes, preferably 80 to 120° C. for 1 to 10 minutes, the heating after the exposure (post exposure baking) is performed, and subsequently, developing, rinsing and drying are performed to form a resist pattern. A developer is preferably 0.1 to 5% by mass, more preferably 2 to 3% by mass an alkaline aqueous solution of, such as tetramethyl ammonium hydroxide (TMAH), and preferably for 0.1 to 3 minutes, more preferably for 0.5 to 2 minutes, the developing is performed by a conventional method such as dip method, puddle method, and spray method. Thus, the exposed portions thereof are dissolved in the developer, and the unexposed portions thereof are insoluble in the developer, thereby forming the desired pattern on the substrate.

### EXAMPLES

Next, the present invention is described in detail by referring to Examples, but the present invention should not be construed as being limited thereto.

### 1. Synthesis Example of High Molecular Compound (A)

The synthesis of examples of the high molecular compounds (A) which are used in the examples will be described below.

[The high molecular compound (A) of the present invention containing the repeating units represented by the general formulae (1) to (3)

### Synthesis Example 1

### Synthesis of High Molecular Compound (P-1)

First, 30 g of poly(p-hydroxystyrene) (VP-2500, available from Nippon Soda K.K.) as a polyhydroxystyrene compound was dissolved in 120 g of propylene glycol monomethyl ether acetate (PGMEA). To this solution, 15.80 g of 2,6-diphenylphenyloxyethyl vinyl ether (hereinafter, sometimes referred to as “VE-1”) as a vinyl ether compound, and 1.45 g of 2% by mass of camphorsulfonic acid (PGMEA solution) were added, and the mixture was stirred at room temperature for 2 hours. Second, 1.05 g of 10% by mass of triethylamine (PGMEA solution) was added thereto, and after stirring for a while, the reaction solution was transferred to a reparatory funnel containing 165 mL of ethyl acetate. This organic layer was washed with 200 mL of distilled water 3 times, and then the organic layer was dried to solid under reduced pressure.

The resulting polymer was dissolved in 120 g of N,N-dimethylformamide (DMF), and 19.75 g of pyridine, 2.76 g of 2-sulfobenzoic acid anhydride (hereinafter, sometimes referred to as “SN-1”) as a sulfonating agent, and 366 mg of N,N-dimethylaminopyridine were added thereto, and the mixture was stirred at room temperature for 5 hours. The reaction solution was transferred to a separatory funnel containing 300 mL of ethyl acetate, the organic layer was washed with 300 mL of saturated saline solution 5 times, the organic layer was concentrated on an evaporator and ethyl acetate was removed.

The resulting polymer was dissolved in 90 mL of tetrahydrofuran (THF) and 30 mL of methanol, and 5.14 g of triphenylsulfonium bromide (hereinafter, sometimes referred to as “PG-1”) as a PAG precursor was added thereto, and the mixture was stirred at room temperature for 3 hours. The reaction solution was concentrated on an evaporator, and thereafter the concentrate was dissolved again in 300 mL of ethyl acetate, and the organic layer was washed with 300 mL of distilled water 5 times. The organic layer was concentrated, and the concentrate was dissolved in 150 mL of acetone, and thereafter the solution was added dropwise into 2 L of a mixed solution of distilled water:methanol=15:1 (volume ratio). The supernatant was removed and the resulting solid was dissolved in 150 mL of ethyl acetate, and the solution was added dropwise to 2 L of hexane. The supernatant was removed and the resulting precipitate was dissolved in 95 g of PGMEA. The low boiling point solvent was removed from the resulting solution on an evaporator to obtain 136.2 g of a PGMEA solution (26.7% by mass) of High Molecular Compound (P-1).

With regard to the obtained High Molecular Compound (P-1), the compositional ratio (molar ratio) of the High Molecular Compound (P-1) was determined by ¹H-NMR measurement. In addition, the weight-average molecular weight (Mw: in terms of polystyrene), the number-average molecular weight (Mn: in terms of polystyrene) and the dispersity (Mw/Mn, hereinafter, also referred to as “PDI”) of the High Molecular Compound (P-1) were determined by GPC (solvent: N-methyl-2-pyrrolidone) measurement. These results are shown in the following chemical formula.

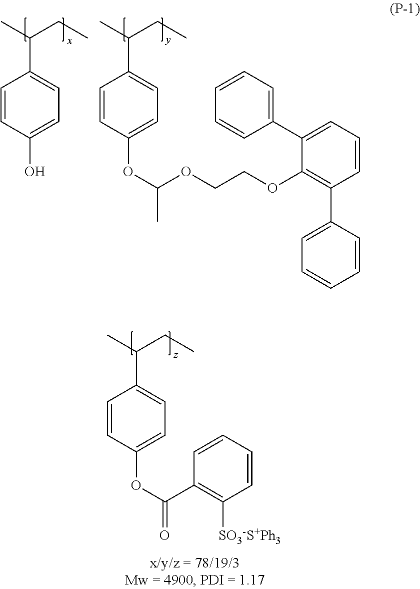

### Synthesis Examples 2 to 14 and Comparative Examples 1 and 2

### Synthesis of High Molecular Compounds (P-2) to (P-14) and (R-1) and (R-2)

High Molecular Compounds (P-2) to (P-14) and (R-1) and (R-2) were synthesized in the same manner as in Synthesis Example 1. The used reaction reagents, the charged amounts thereof (mol % relative to polyhydroxystyrene unit), and the concentrations (% by mass) and the amounts (g) of the resulting high molecular compound solutions are shown in Table 1.

TABLE 1

| | | | Charged | | | | Charged | High | High |
|---|---|---|---|---|---|---|---|---|---|
| | | | amount of | | Charged | | amount of | Molecular | Molecular |
| High | | | vinyl ether | | amount of | | PAG | Compound | Compound |
| Molecular | Polyhydroxystyrene | Vinyl ether | compound | Sulfonating | Sulfonating | PAG | precursor | Concentration | Solution |
| Compound | compound | compound | (mol %) | agent | agent (mol %) | precursor | (mol %) | (% by mass) | Amount (g) |
| P-2 | VP-2500 | VE-1 | 22 | SN-1 | 9 | PG-1 | 9 | 27.7 | 136.0 |
| P-3 | VP-8000 | VE-1 | 17 | SN-1 | 5 | PG-1 | 5 | 28.1 | 133.7 |
| P-4 | VP-2500 | VE-2 | 25 | SN-1 | 6 | PG-1 | 6 | 27.5 | 134.5 |
| P-5 | VP-2500 | VE-3 | 31 | SN-1 | 6 | PG-1 | 6 | 27.8 | 135.2 |
| P-6 | VP-2500 | VE-1 | 20 | SN-1 | 6 | PG-2 | 6 | 28.0 | 135.2 |
| P-7 | VP-8000 | VE-3 | 30 | SN-2 | 5 | PG-1 | 5 | 28.3 | 134.4 |
| P-8 | VP-2500 | VE-3 | 32 | SN-3 | 4 | PG-1 | 4 | 27.3 | 136.2 |
| P-9 | VP-8000 | VE-1 | 17 | SN-4 | 5 | PG-1 | 5 | 28.1 | 133.2 |
| P-10 | VP-8000 | VE-1 | 20 | SN-5 | 4 | PG-1 | 4 | 27.5 | 135.2 |
| P-11 | MHS | VE-3 | 29 | SN-1 | 4 | PG-1 | 4 | 27.9 | 134.8 |
| P-12 | VP-2500 | VE-4 | 32 | SN-6 | 3 | PG-1 | 3 | 28.3 | 133.3 |
| P-13 | Nf-PHS | VE-3 | 25 | SN-1 | 8 | PG-1 | 8 | 28.7 | 132.2 |
| P-14 | Bn-MHS | VE-3 | 29 | SN-1 | 8 | PG-1 | 8 | 28.2 | 135.1 |
| R-1 | VP-8000 | VE-1 | 16 | — | — | — | — | 27.2 | 133.4 |
| R-2 | VP-2500 | VE-3 | 32 | — | — | — | — | 28.2 | 132.8 |

The reaction reagents used in the synthesis of the High Molecular Compounds (P-2) to (P-14) and (R-1) and (R-2) are shown below.

VP-8000: poly(p-hydroxystyrene) (available from Nippon Soda K.K.)

MHS: poly(m-hydroxystyrene) (Mw=4200, PDI=1.2)

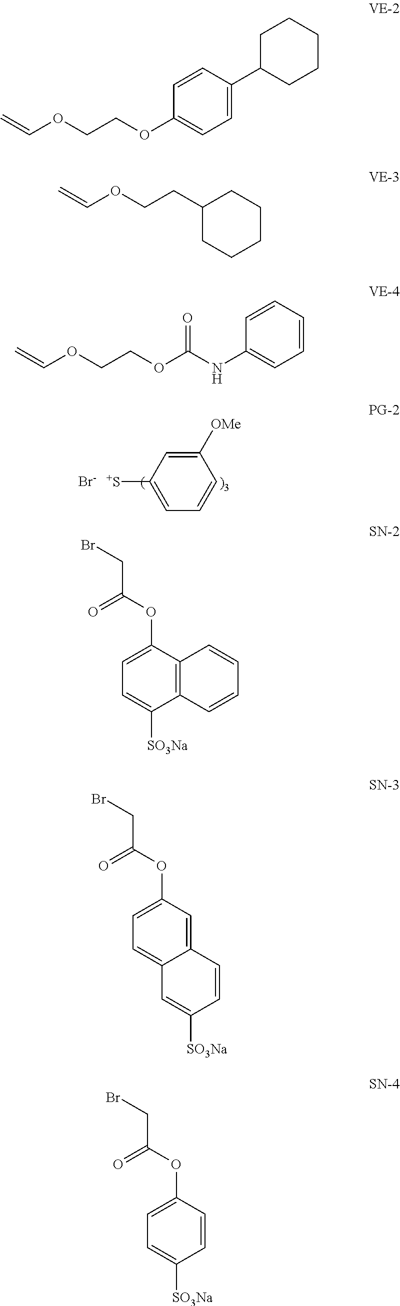

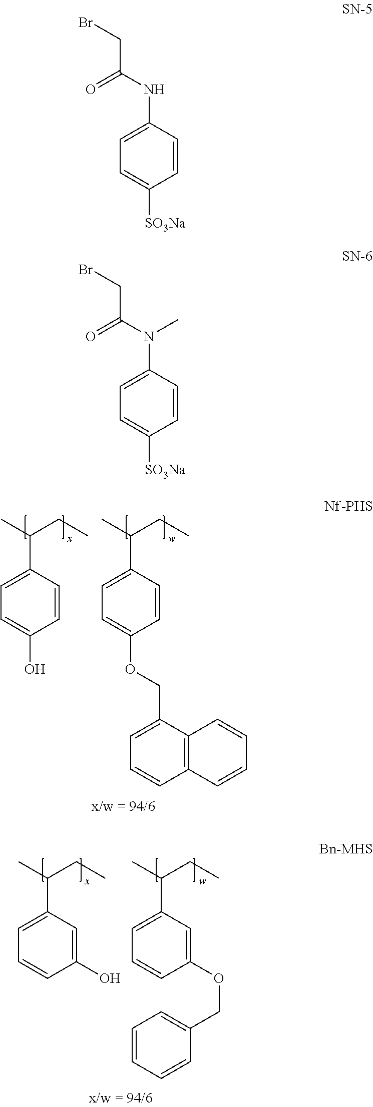

### Reference Example 1

### Synthesis of Nf-PHS

First, 30 g of VP-2500 was dissolved in 120 mL of acetone, 4.35 g of potassium carbonate, 1.18 g of sodium iodide and 2.78 g of 1-choloromethyl naphthalene were added thereto, and the mixture was refluxed for 4 hours. The reaction solution was left standing at room temperature, approximately 60 g of acetone was removed on an evaporator, and thereafter the reaction solution was transferred to a separatory funnel containing 200 mL of ethyl acetate. The organic layer was washed with 200 mL of 1N aqueous hydrochloric acid solution twice and with 200 mL of distilled water twice, and thereafter the organic layer was concentrated to dryness to obtain Nf-PHS.

### Reference Example 2

### Synthesis of Bn-MHS

Bn-MHS was obtain in the same manner as in the Reference Example 1, except that VP-2500 was replaced with the MHS and that 2.78 g of 1-choloromethyl naphthalene was replaced with 2.69 g of benzyl bromide.

### Synthesis Example 15

### Synthesis of High Molecular Compound (P-15)

First, 10.86 g of acetyl chloride was added to 20.0 g of phenylacetaldehyde dimethyl acetal, and the mixture was stirred at 45° C. for 4 hours. The low boiling point component was removed on an evaporator to quantitatively obtain 1-choloro-2-phenylethyl methyl ether (hereinafter, sometimes referred to as “C1-1”), as a chloroalkyl ether compound.

Second, 30 g of VP-2500 was dissolved in 120 g of THF, 26.52 g of triethylamine was added thereto and the mixture was cooled in an ice bath to obtain a reaction solution. Third, 21.3 g of C1-1 was added dropwise to the reaction solution, and the solution was left standing at room temperature, and thereafter stirred for 3 hours. Then, 100 mL of distilled water was added thereto, and THF was removed on an evaporator, and thereafter this was transferred to a separatory funnel containing 300 mL of ethyl acetate, and was washed with 300 mL of distilled water 5 times. The organic layer was concentrated to dryness on an evaporator.

The resulting polymer was dissolved in 120 g of N,N-dimethylformamide (DMF), and 19.75 g of pyridine, 2.76 g of 2-sulfobenzoic acid anhydride as a sulfonating agent, and 366 mg of N,N-dimethylaminopyridine were added thereto, and the mixture was stirred at room temperature for 5 hours. The resulting reaction solution was transferred to a separatory funnel containing 300 mL of ethyl acetate, the organic layer was washed with 300 mL of saturated saline solution 5 times, the organic layer was concentrated on an evaporator and ethyl acetate was removed.

The resulting polymer was dissolved in 90 mL of tetrahydrofuran (THF) and 30 mL of methanol, and 5.14 g of triphenylsulfonium bromide as a PAG precursor was added thereto, and the mixture was stirred at room temperature for 3 hours. The resulting reaction solution was concentrated on an evaporator, and thereafter, was dissolved again in 300 mL of ethyl acetate, and the organic layer was washed with 300 mL of distilled water 5 times. The organic layer was concentrated, and the concentrate was dissolved in 150 mL of acetone, and thereafter the solution was dropped into in 2 L of a mixed solution of distilled water:methanol=15:1 (volume ratio). The supernatant was removed and the resulting solid was dissolved in 150 mL of ethyl acetate, and the solution was dropped into 2 L of hexane. The supernatant was removed and the resulting precipitate was dissolved in 95 g of PGMEA. The low boiling point solvent was removed from the resulting solution on an evaporator to obtain 135.3 g of a PGMEA solution (27.1% by mass) of High Molecular Compound (P-15).

### Synthesis Examples 16 to 19

### Synthesis of High Molecular Compounds (P-16) to (P-19)

High Molecular Compounds (P-16) to (P-19) were synthesized in the same manner as in Synthesis Example 15. The used reaction reagents, the charged amounts thereof (mol % relative to polyhydroxystyrene unit), and the concentrations (% by mass) and the amounts (g) of the resulting high molecular compound solutions are shown in the following Table 2.

TABLE 2

| | | | Charged | | | | Charged | High | High |
|---|---|---|---|---|---|---|---|---|---|
| | | | amount of | | Charged | | amount of | Molecular | Molecular |
| High | | | vinyl ether | | amount of | | PAG | Compound | Compound |
| Molecular | Polyhydroxystyrene | Vinyl ether | compound | Sulfonating | Sulfonating | PAG | precursor | Concentration | Solution |
| Compound | compound | compound | (mol %) | agent | agent (mol %) | precursor | (mol %) | (% by mass) | Amount (g) |
| P-16 | VP-8000 | Cl-2 | 40 | SN-7 | 3 | PG-3 | 3 | 27.3 | 134.4 |
| P-17 | VP-2500 | Cl-3 | 33 | SN-8 | 4 | PG-1 | 4 | 28.7 | 132.7 |
| P-18 | VP-8000 | Cl-4 | 32 | SN-9 | 4 | PG-1 | 4 | 29.2 | 131.2 |
| P-19 | VP-2500 | Cl-1 | 52 | SN-1 | 5 | PG-4 | 6 | 29.8 | 133.4 |

The reaction reagents used in the synthesis of the High Molecular Compounds (P-16) to (P-19) are shown below.

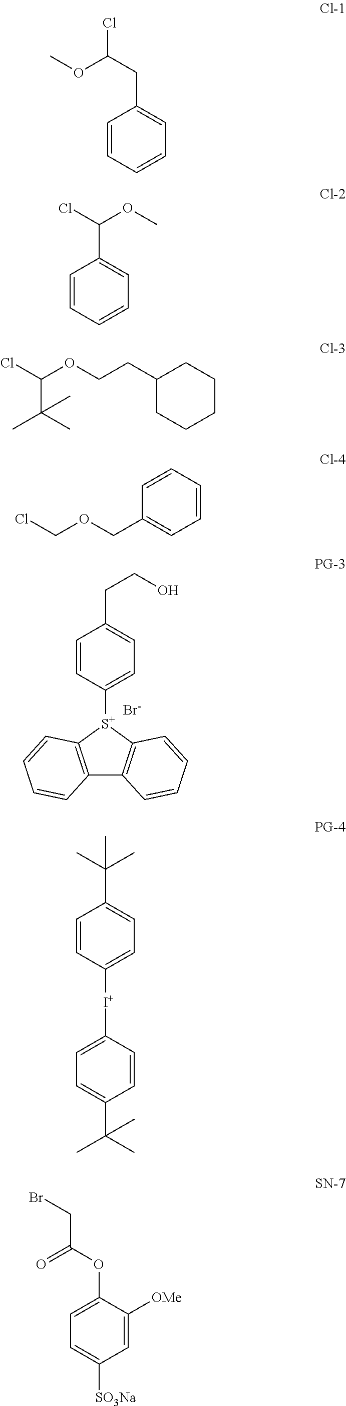

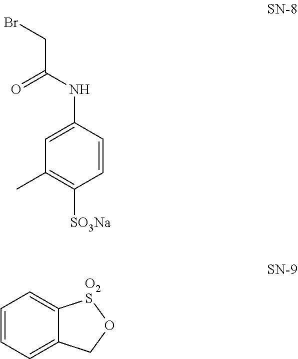

### Synthesis Example 20

### Synthesis of High Molecular Compound (P-20)

First, 7.84 g of 1-methoxy-2-propanol was heated to 70° C. under nitrogen atmosphere. While stirring this solution, a mixed solution of 10.0 g of Monomer (M-1), 5.13 g of Monomer (M-2), and 1.66 g of Monomer (M-3), which are shown below, 31.34 g of 1-methoxy-2-propanol, and 1.13 g of dimethyl 2,2′-azobisisobutyrate (V-601, available from Wako Pure Chemical Industries, Ltd.) were added dropwise thereto over 2 hours. After the completion of adding dropwise, the mixture was stirred at 70° C. for further 4 hours. The reaction solution was allowed to cool, and thereafter reprecipitation was performed in a large amount of hexane/ethyl acetate, and the vacuum drying was performed to obtain 10.04 g of the High Molecular Compound (P-20) of the present invention.

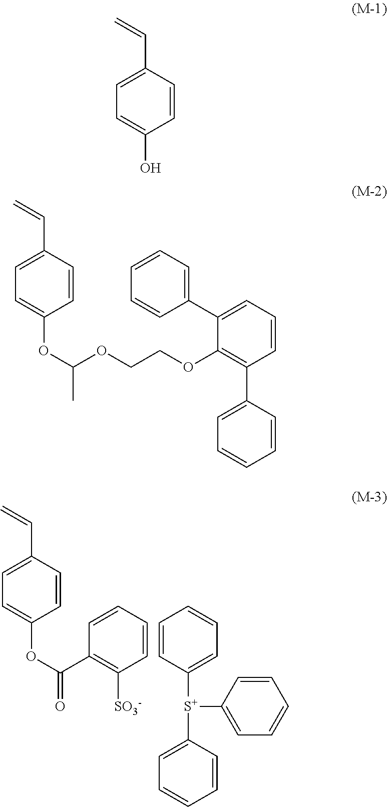

### Synthesis Examples 21 to 24 and Synthesis Comparative Examples 3 to 5

### Synthesis of High Molecular Compounds (P-21) to (P-24) and (R-3) to (R-5)

Compounds (P-21) to (P-24) and (R-3) to (R-5) were synthesized in the same manner as in Synthesis Example 20. The used monomers, the charged amounts thereof (g), the charged amounts of the polymerization initiator (g), and the amounts of the resulting high molecular compound (g) are shown in the following Table 3.

TABLE 3

| | | | | | | | | | Charged | Amounts of |
|---|---|---|---|---|---|---|---|---|---|---|
| | | | | | | | | | amount | High |
| High | | | | | | | | | of | Molecular |
| Molecular | Charged amount of monomers (g) | | | | | | | | V-601 | Compounds |
| Compound | Monomer-1 | | Monomer-2 | | Monomer-3 | | Monomer-4 | | (g) | (g) |
| P-21 | M-4 | 10.00 | M-2 | 4.69 | M-5 | 1.39 | — | — | 1.65 | 9.40 |
| P-22 | M-1 | 10.00 | M-2 | 6.13 | M-6 | 2.03 | — | — | 2.77 | 12.35 |
| P-23 | M-1 | 10.00 | M-2 | 4.54 | M-7 | 1.95 | M-8 | 1.11 | 2.87 | 12.69 |
| P-24 | M-1 | 10.00 | M-2 | 6.65 | M-8 | 1.88 | — | — | 2.80 | 11.73 |
| R-3 | M-1 | 10.00 | M-2 | 5.62 | M-10 | 1.33 | — | — | 1.14 | 11.04 |
| R-4 | M-1 | 10.00 | M-2 | 5.13 | M-11 | 1.96 | — | — | 1.35 | 9.96 |
| R-5 | M-1 | 10.00 | M-2 | 5.62 | M-12 | 1.64 | — | — | 1.14 | 10.68 |

The monomers used in the synthesis of the High Molecular Compounds (P-21) to (P-24) and (R-3) to (R-5) are shown below.

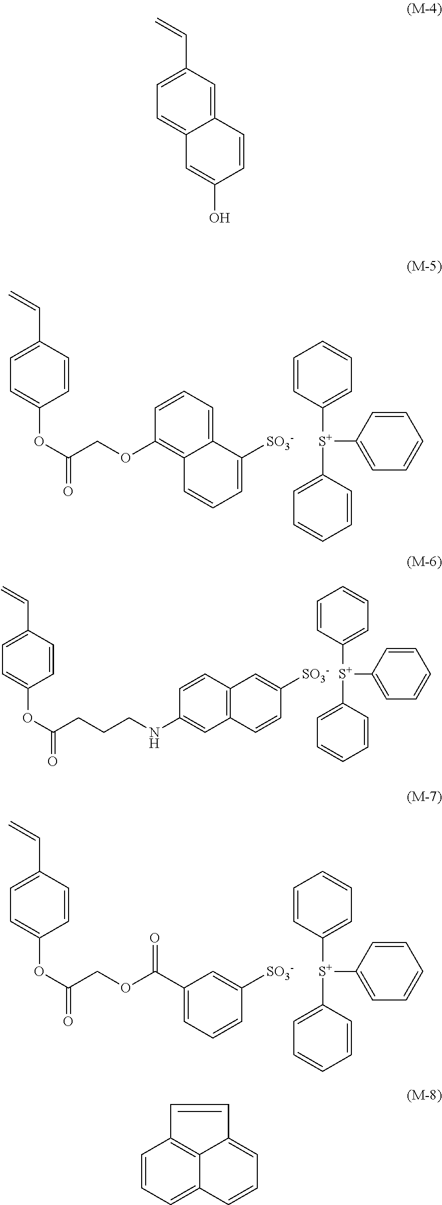

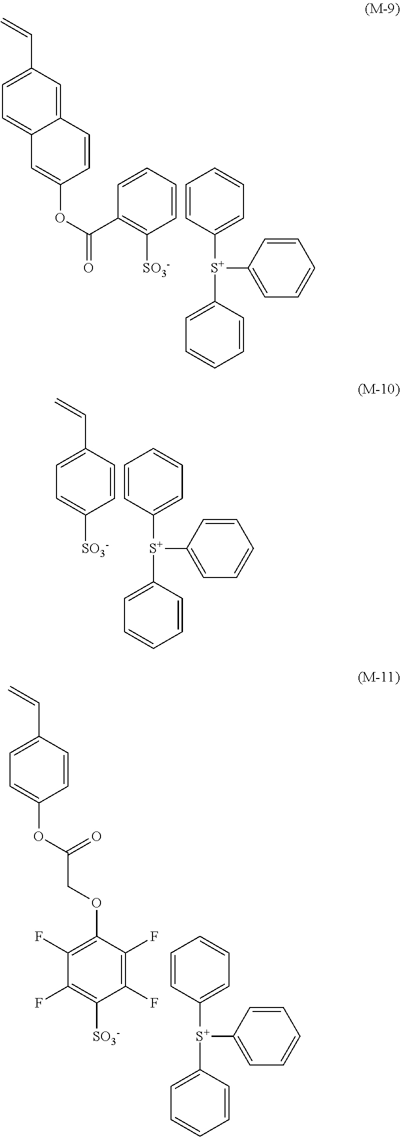

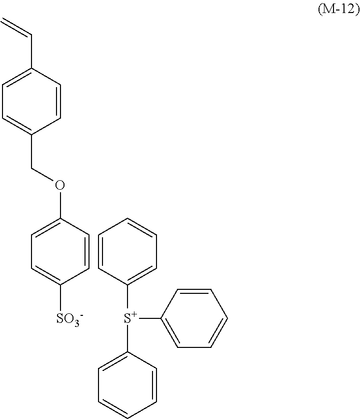

With regard to each of the High Molecular Compound (P-1) to (P-24) and (R-1) to (R-5), the structure, the compositional ratio, the weight-average molecular weight and the dispersity are shown below.

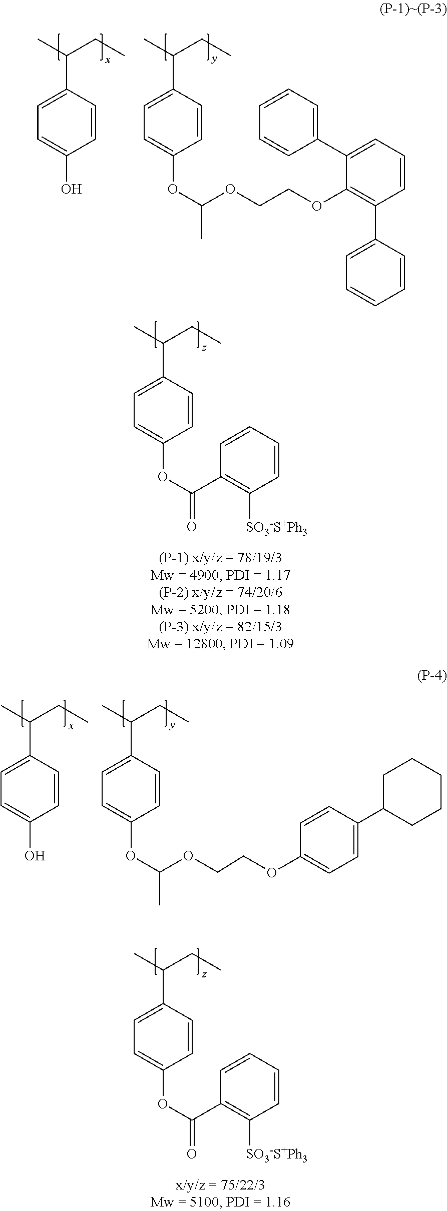

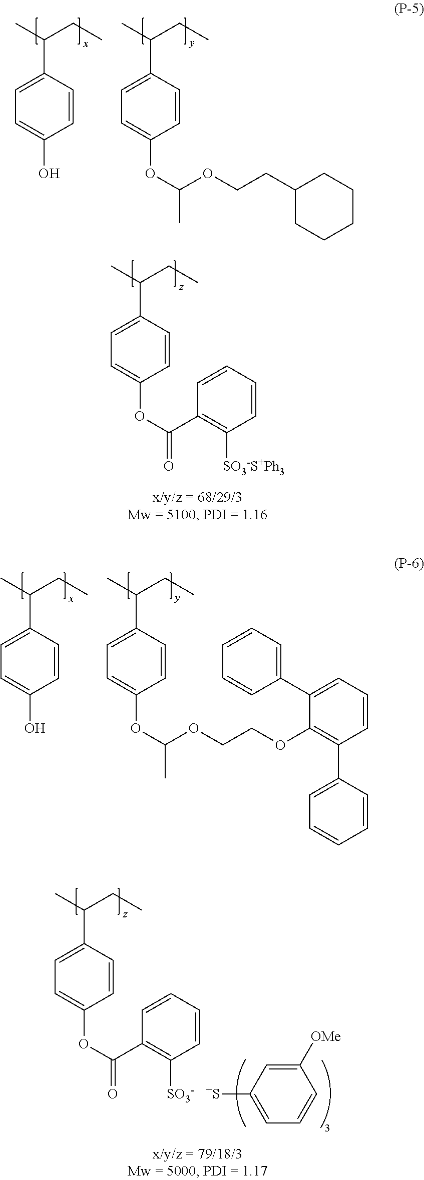

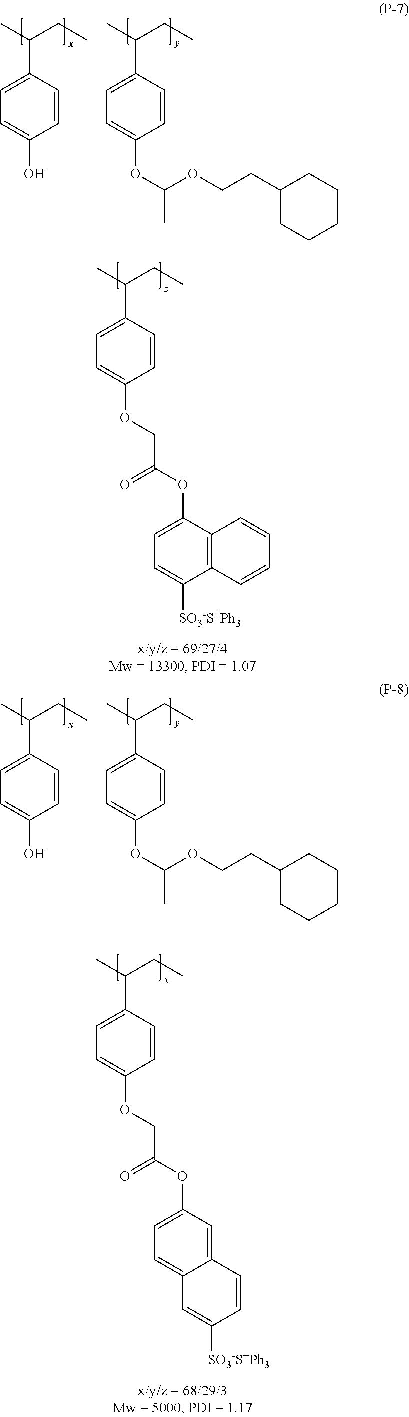

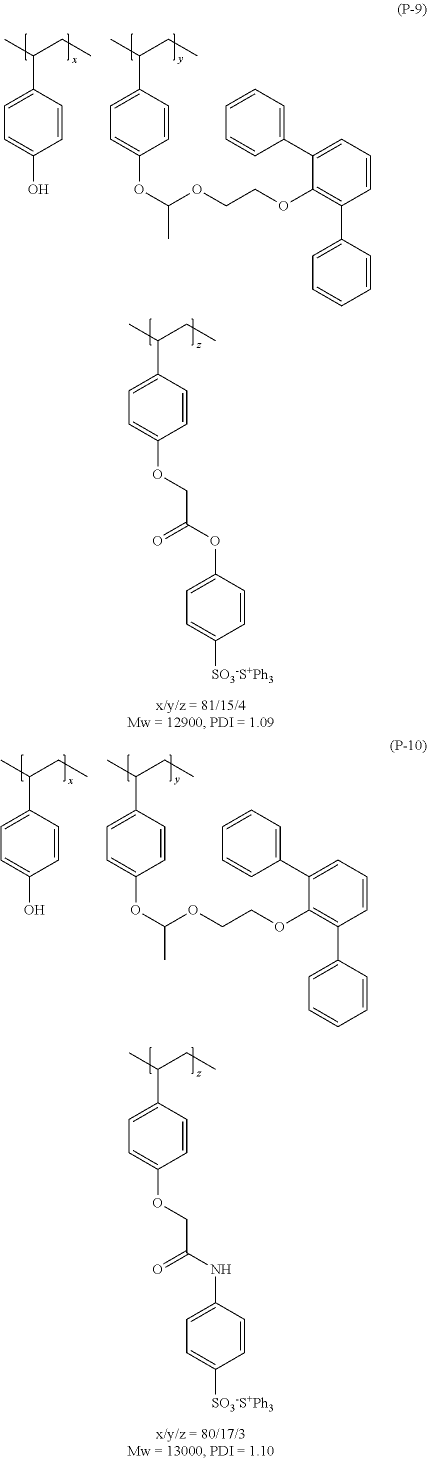

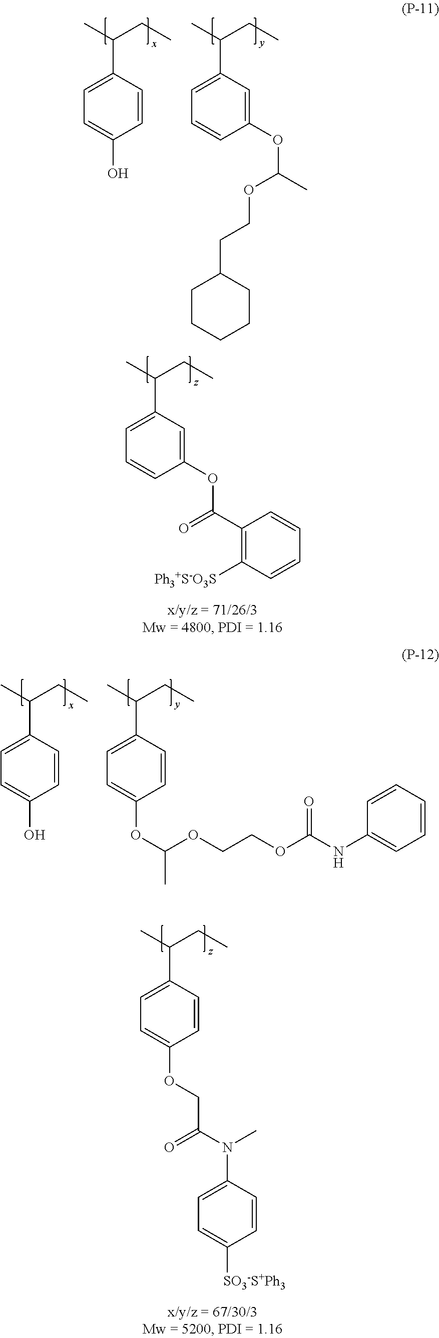

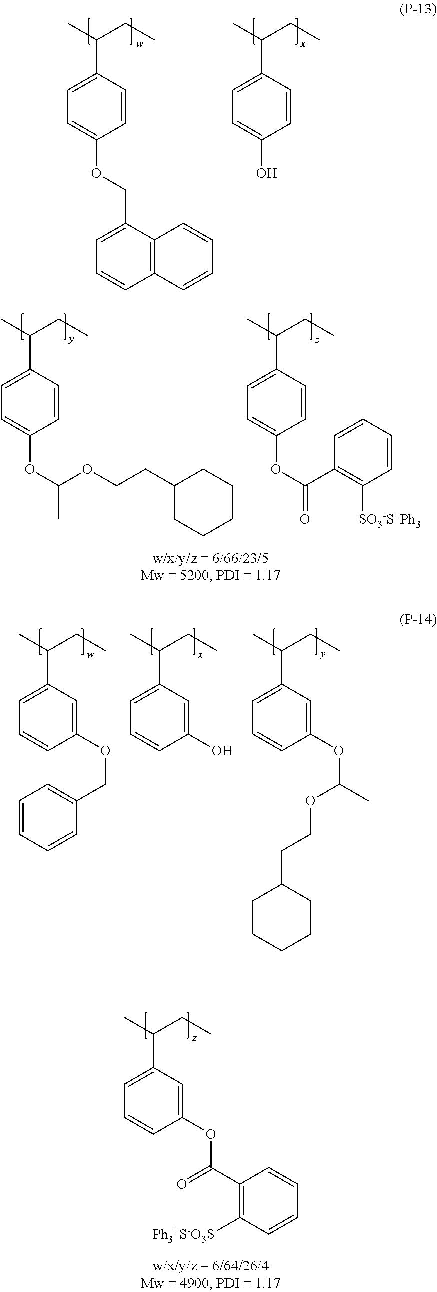

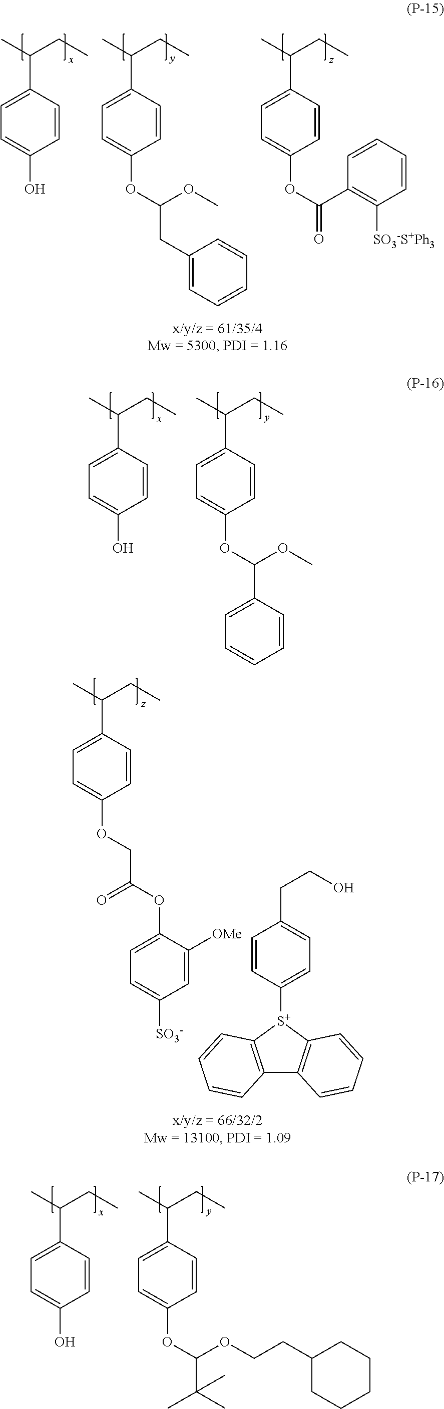

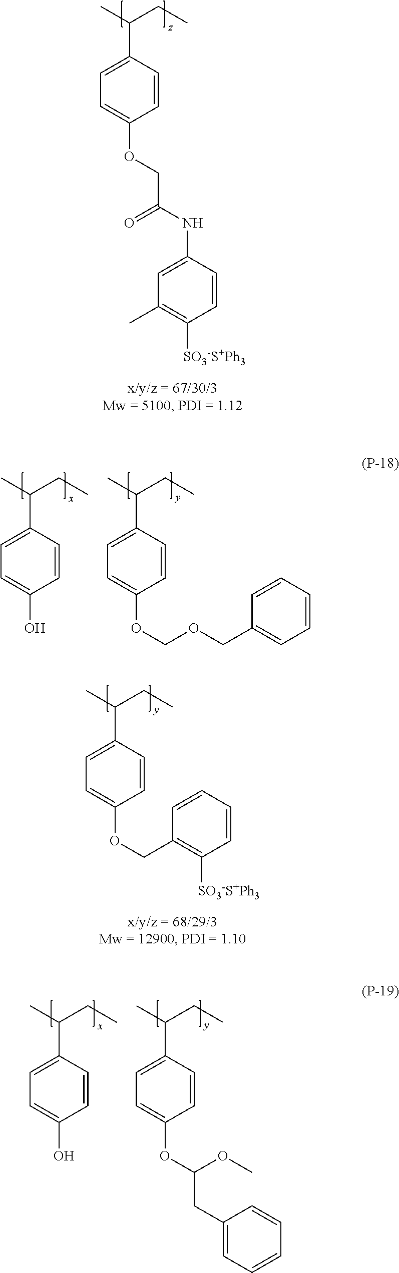

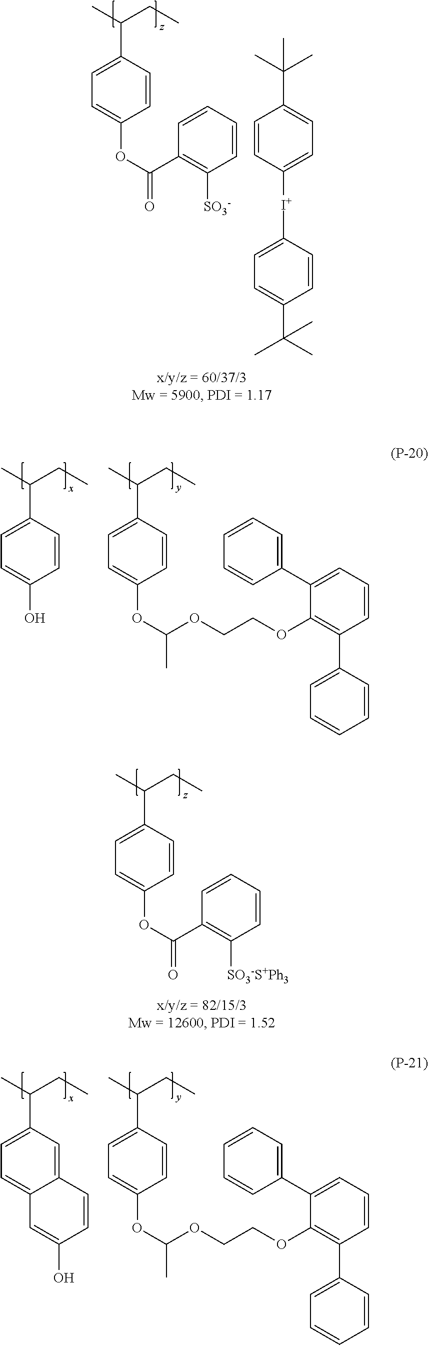

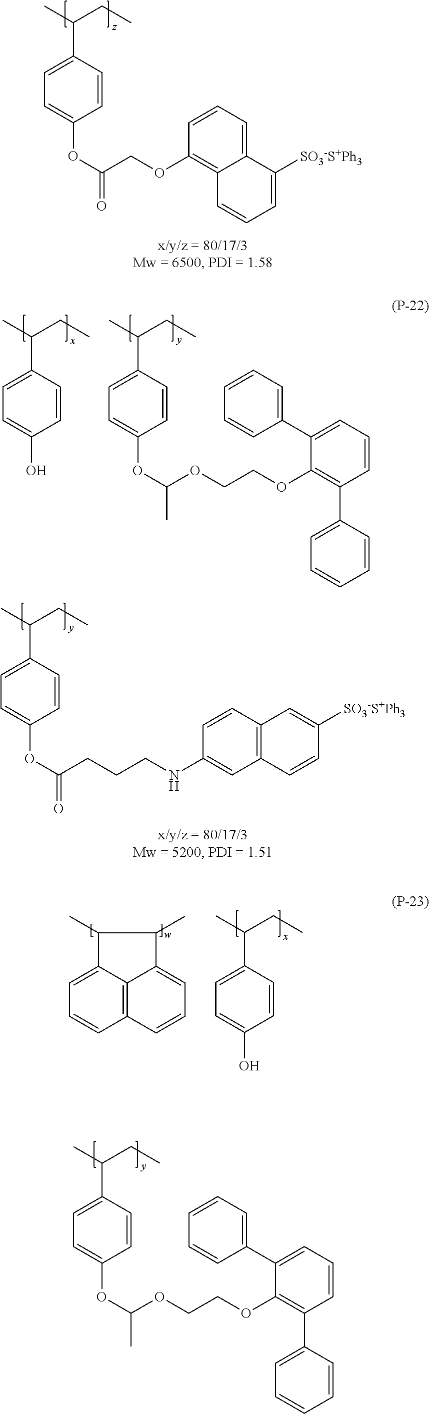

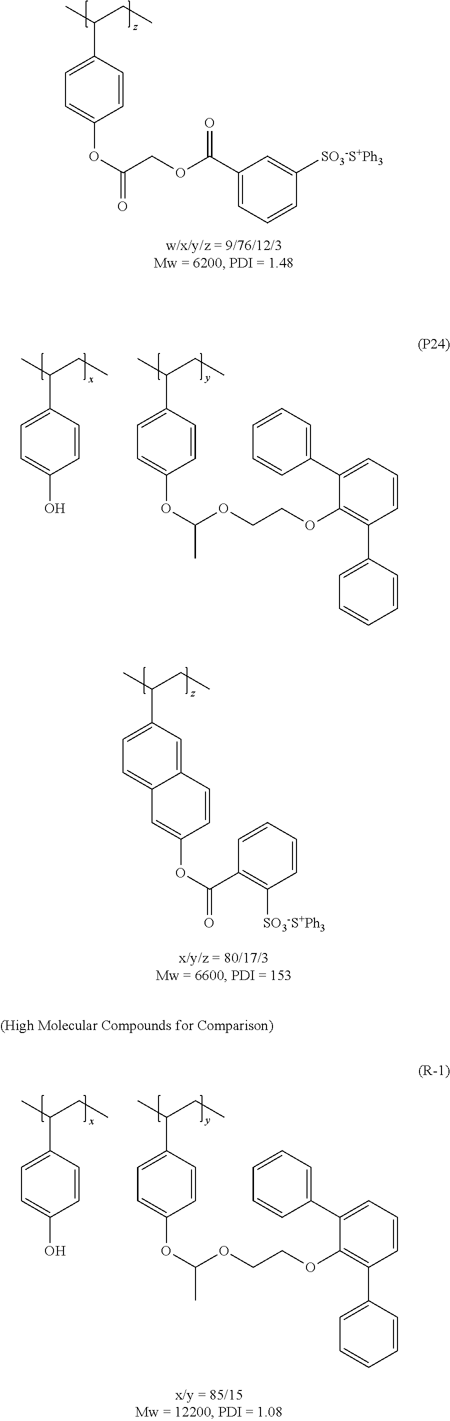

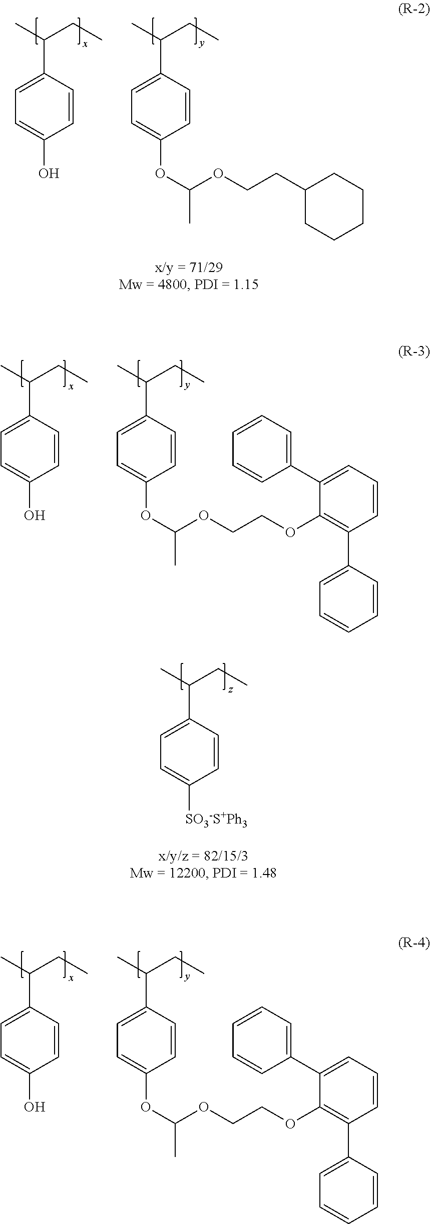

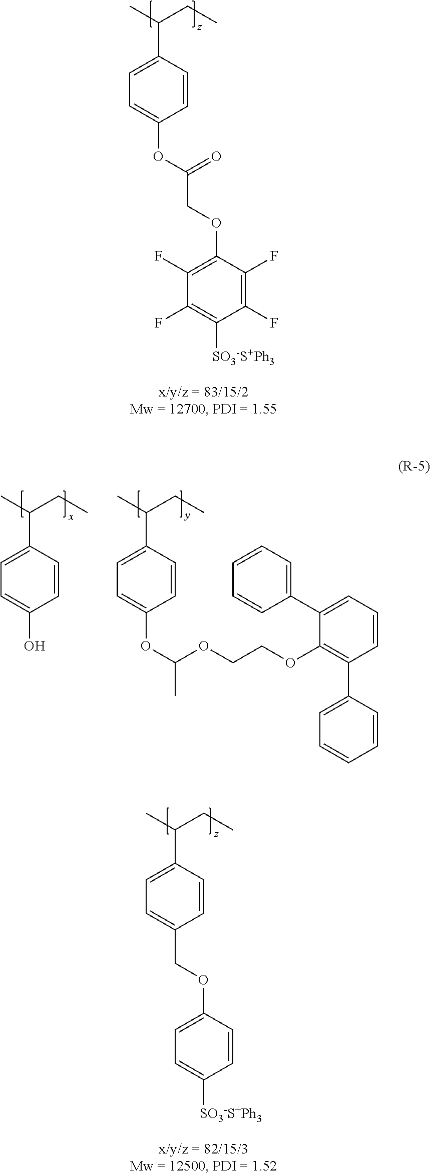

### 2. Example

### Example 1

The solution resulted from dissolving, in the mixed solvent of propylene glycol monomethyl ether acetate (PGMEA)/propylene glycol monomethyl ether (PGME)=80/20 (mass ratio), a proportion of the High Molecular Compound (P-3)/Tetrabutylammonium hydroxide (a basic compound)/Surfactant PF6320 (available from OMNOVA Solutions Limited)=99.35/0.6/0.05 (mass ratio) so as to have 4% by mass of solid concentration, was filtrated by using a polytetrafluoroethylene filter having a pore size of 0.1 μm to prepare a positive resist coating solution.

This coating solution was uniformly coated on a glass substrate on which a chromium oxide film (a light-shielding film) having a thickness of 100 nm had been provided by chemical vapor deposition, by using a spin coater. Then, the heating and drying was performed by using a hot plate at 130° C. over 60 seconds to form a resist film having a film thickness of 100 nm.

This resist film was irradiated with an electron beam by using an electron beam irradiation apparatus (HL750, available from Hitachi Ltd., accelerating voltage: 50 KeV). Immediately after the irradiation, the resist film was heated on a hot plate at 120° C. for 600 seconds.

Thereafter, the film was developed at 23° C. for 60 seconds by using 2.38% by mass of an aqueous solution of tetramethylammonium hydroxide (TMAH), was rinsed with pure water for 30 seconds, and then dried. Thus, the line and space pattern (line:space=1:1) was formed. In addition, hereinafter, the line and space pattern is sometimes abbreviated to L&S.

[Sensitivity]

The cross-sectional profile of each obtained pattern was observed using a scanning electron microscope (S-4800, available from Hitachi Ltd.). With regard to L&S pattern, the minimum irradiation energy in a case of resolving a line having a 100-nm line width was defined as the sensitivity (μC/cm²).

[Resolving Power]

The limiting resolving power (the minimum line width when the line and the space were separated and resolved) in the irradiation amount showing the aforementioned sensitivity was defined as a resolving power (nm).

[Line Edge Roughness (LER)]

With respect to the region of 50 μm in the longitudinal direction of the line pattern having a 100-nm line width in the irradiation amount showing the aforementioned sensitivity, the distance from a reference line where the edge should be present was measured at arbitrary 30 points by a scanning electron microscope (S-4800, available from Hitachi, Ltd.), and the standard deviation was determined, and 36 was computed. It is shown that the smaller the value is, the better the line edge roughness is.

[Exposure Latitude (EL)]

In an irradiation amount showing the aforementioned sensitivity (hereinafter, also referred to “optimal irradiation amount”), in a case of varying the irradiation amount, the width of the irradiation amount where a pattern size accepts 100 nm±10% was determined, and this value was divided by the optimal irradiation amount to put the exposure latitude on a percentage basis. The bigger this value is, the better the exposure latitude is.

The evaluation results are shown in Table 5.

### Example 2 to 24, and Comparative Examples 1 to 5

Except that the components listed in the following Table 4 are used, in the same manner as in Example 1, the preparation of the resist solutions, the formation of positive patterns, and the evaluation thereof were performed. The evaluation results are shown in Table 5 to Table 7.

TABLE 4

| | High | | | | | Concentration |
|---|---|---|---|---|---|---|
| | Molecular | Photoacid | Basic | | | of Total |
| | Compound | Generator (% | Compound | Solvent | Surfactant (% | Solids (% by |
| Example | (% by mass) | by mass) | (% by mass) | (mass ratio) | by mass) | mass) |
| Example 1 | P-3 | — | BASE-1 | S1/S2 | W-1 | 4 |
| | (99.35) | | (0.6) | (80/20) | (0.05) | |
| Example 2 | P-20 | — | BASE-1 | S1/S2 | W-1 | 4 |
| | (99.35) | | (0.6) | (80/20) | (0.05) | |
| Example 3 | P-9 | — | BASE-1 | S1/S2 | W-1 | 4 |
| | (99.35) | | (0.6) | (80/20) | (0.05) | |
| Example 4 | P-10 | — | BASE-1 | S1/S2 | W-1 | 4 |
| | (99.35) | | (0.6) | (80/20) | (0.05) | |
| Example 5 | P-5 | — | BASE-1 | S1/S2 | W-1 | 4 |
| | (99.35) | | (0.6) | (80/20) | (0.05) | |
| Example 6 | P-8 | — | BASE-1 | S1/S2 | W-1 | 4 |
| | (99.35) | | (0.6) | (80/20) | (0.05) | |
| Example 7 | P-13 | — | BASE-1 | S1/S2 | W-1 | 4 |
| | (99.35) | | (0.6) | (70/30) | (0.05) | |
| Example 8 | P-1 | — | BASE-1 | S1/S2 | W-1 | 4 |
| | (99.35) | | (0.6) | (80/20) | (0.05) | |
| Example 9 | P-2 | — | BASE-1 | S1/S2 | W-1 | 4 |
| | (99.25) | | (0.7) | (60/40) | (0.05) | |
| Example 10 | P-4 | — | BASE-1 | S1/S2 | W-1 | 4 |
| | (99.35) | | (0.6) | (80/20) | (0.05) | |
| Example 11 | P-6 | — | BASE-1 | S1/S2 | W-1 | 4 |
| | (99.35) | | (0.6) | (80/20) | (0.05) | |
| Example 12 | P-7 | — | BASE-1 | S1/S2 | W-1 | 4 |
| | (99.35) | | (0.6) | (80/20) | (0.05) | |
| Example 13 | P-11 | — | BASE-1 | S1/S2 | W-1 | 4 |
| | (99.35) | | (0.6) | (80/20) | (0.05) | |
| Example 14 | P-12 | — | BASE-1 | S1/S2 | W-1 | 4 |
| | (99.35) | | (0.6) | (80/20) | (0.05) | |
| Example 15 | P-14 | — | BASE-1 | S1/S2 | W-1 | 4 |
| | (99.35) | | (0.6) | (80/20) | (0.05) | |
| Example 16 | P-15 | — | BASE-1 | S1/S2 | W-1 | 4 |
| | (99.35) | | (0.6) | (80/20) | (0.05) | |
| Example 17 | P-16 | — | BASE-1 | S1/S2 | W-1 | 4 |
| | (99.35) | | (0.6) | (80/20) | (0.05) | |
| Example 18 | P-17 | — | BASE-1 | S1/S2 | W-1 | 4 |
| | (99.35) | | (0.6) | (80/20) | (0.05) | |
| Example 19 | P-18 | — | BASE-1 | S1/S2 | W-1 | 4 |
| | (99.35) | | (0.6) | (80/20) | (0.05) | |
| Example 20 | P-19 | — | BASE-1 | S1/S2 | W-1 | 4 |
| | (99.35) | | (0.6) | (80/20) | (0.05) | |
| Example 21 | P-21 | — | BASE-1 | S1/S2 | W-1 | 4 |
| | (99.35) | | (0.6) | (80/20) | (0.05) | |
| Example 22 | P-22 | — | BASE-1 | S1/S2 | W-1 | 4 |
| | (99.35) | | (0.6) | (80/20) | (0.05) | |
| Example 23 | P-23 | — | BASE-1 | S1/S2 | W-1 | 4 |
| | (99.35) | | (0.6) | (80/20) | (0.05) | |
| Example 24 | P-24 | — | BASE-1 | S1/S2 | W-1 | 4 |
| | (99.35) | | (0.6) | (80/20) | (0.05) | |
| Comparative | R-1 | PAG-1 | BASE-1 | S1/S2 | W-1 | 4 |
| Example 1 | (99.85) | (5.5) | (0.6) | (80/20) | (0.05) | |
| Comparative | R-3 | — | BASE-1 | S1/S2 | W-1 | 4 |
| Example 2 | (99.35) | | (0.6) | (80/20) | (0.05) | |
| Comparative | R-4 | — | BASE-1 | S1/S2 | W-1 | 4 |
| Example 3 | (99.35) | | (0.6) | (80/20) | (0.05) | |
| Comparative | R-5 | — | BASE-1 | S1/S2 | W-1 | 4 |
| Example 4 | (99.35) | | (0.6) | (80/20) | (0.05) | |
| Comparative | R-2 | PAG-1 | BASE-1 | S1/S2 | W-1 | 4 |
| Example 5 | (99.85) | (5.5) | (0.6) | (80/20) | (0.05) | |

In addition, the concentration of each component shown in Table 4 is the mass concentration based on the mass of the total solids.

The details of the compounds other than the aforementioned compounds used in the examples and the comparative examples are described below.

[Photoacid Generator (B)]

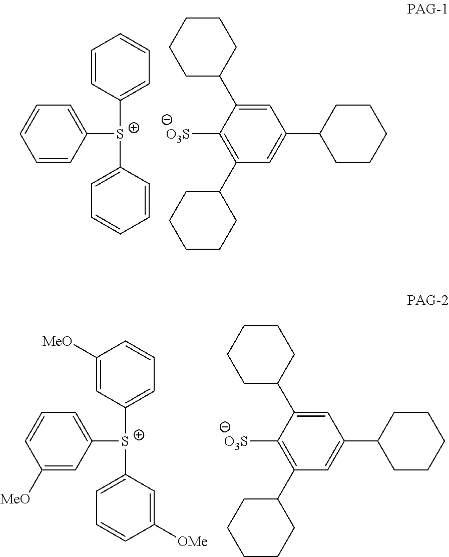

[Basic Compound]

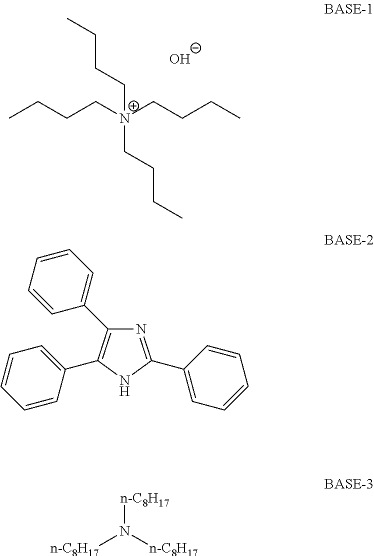

[Surfactant]

W-1: PF6320 (available from OMNOVA Solutions Inc; fluorine series)

[Solvent]

S1: Propylene glycol monomethyl ether acetate (PGMEA)
S2: Propylene glycol monomethyl ether (PGME)

TABLE 5

| | L&S Sensitivity | L&S Resolving | | |
|---|---|---|---|---|
| Examples | (μC/cm²) | Power (nm) | LER (nm) | EL (%) |
| Example 1 | 25.8 | 37.5 | 3.7 | 32.0 |
| Example 2 | 25.0 | 37.5 | 4.1 | 30.2 |
| Example 3 | 25.4 | 37.5 | 3.6 | 31.8 |
| Example 4 | 26.0 | 37.5 | 3.8 | 33.4 |
| Comparative | 25.4 | 50 | 5.2 | 21.2 |
| Example 1 | | | | |
| Comparative | 26.2 | 50 | 4.6 | 24.4 |
| Example 2 | | | | |
| Comparative | 24.8 | 62.5 | 4.8 | 23.3 |
| Example 3 | | | | |
| Comparative | 26.2 | 37.5 | 4.8 | 29.2 |
| Example 4 | | | | |

Comparing the resist compositions with one another, which used the high molecular compounds having the same type of an acetal group, as shown in Table 5, the compositions according to Examples 1 to 4 could satisfy at the same time all of high sensitivity, high resolving power, good line edge roughness (LER) and good exposure latitude (EL). On the other hand, the compositions according to Comparative Examples 1 to 4 which used the High Molecular Compounds (R-1) and (R-3) to (R-5) for comparison do not have any good effect of sensitivity, resolving power, line edge roughness (LER) and exposure latitude (EL), and could not satisfy at the same time all of high sensitivity, high resolving power, good line edge roughness (LER) and good exposure latitude (EL).

In addition, comparing Example 1 with Example 2, in Example 1 where the dispersity of the high molecular compound is low, LER and EL are better.

TABLE 6

| | L&S Sensitivity | L&S Resolving | | |
|---|---|---|---|---|
| Examples | (μC/cm²) | Power (nm) | LER (nm) | EL (%) |
| Example 5 | 25.4 | 37.5 | 4.2 | 38.8 |
| Example 6 | 26.4 | 37.5 | 4.8 | 37.2 |
| Example 7 | 26.3 | 37.5 | 4.3 | 41.2 |
| Comparative | 25.1 | 50 | 6.8 | 30.4 |
| Example 5 | | | | |

Comparing the resist compositions with one another, which used the high molecular compounds having the same type of an acetal group, as shown in Table 6, the compositions according to Examples 5 to 7 could satisfy at the same time all of high sensitivity, high resolving power, good line edge roughness (LER) and good exposure latitude (EL). On the other hand, the composition according to Comparative Example 5 which used the High Molecular Compounds (R-2) for comparison does not have any good effect of sensitivity, resolving power, line edge roughness (LER) and exposure latitude (EL), and could not satisfy at the same time all of high sensitivity, high resolving power, good line edge roughness (LER) and good exposure latitude (EL).

TABLE 7

| | L&S Sensitivity | L&S Resolving | | |
|---|---|---|---|---|
| Examples | (μC/cm²) | Power (nm) | LER (nm) | EL (%) |
| Example 8 | 25.7 | 37.5 | 3.8 | 32.7 |
| Example 9 | 23.8 | 37.5 | 4.1 | 31.2 |
| Example 10 | 25.8 | 37.5 | 4.6 | 34.0 |
| Example 11 | 26.3 | 37.5 | 4.2 | 33.5 |
| Example 12 | 26.7 | 37.5 | 4.6 | 38.4 |
| Example 13 | 25.4 | 37.5 | 4.1 | 36.6 |
| Example 14 | 26.2 | 37.5 | 4.2 | 38.8 |
| Example 15 | 26.6 | 25 | 4.8 | 37.1 |
| Example 16 | 25.2 | 37.5 | 4.8 | 41.6 |
| Example 17 | 24.9 | 37.5 | 5.2 | 39.9 |
| Example 18 | 26.3 | 37.5 | 4.9 | 38.8 |
| Example 19 | 27.0 | 37.5 | 4.6 | 39.2 |
| Example 20 | 25.9 | 37.5 | 4.8 | 37.7 |
| Example 21 | 26.8 | 37.5 | 3.8 | 32.2 |
| Example 22 | 26.3 | 37.5 | 4.1 | 31.2 |
| Example 23 | 26.8 | 37.5 | 4.0 | 32.2 |
| Example 24 | 25.1 | 37.5 | 3.8 | 32.3 |

### Examples 25 to 34 and Comparative Example 6

The positive resist solution which was prepared in the same manner in Example 1 except that the components listed in the following Table 8 was used, was uniformly coated on a hexamethyldisilazane-treated silicon substrate by using a spin coater. Then, the heating and drying was performed by using a hot plate at 130° C. over 90 seconds. Thus, a resist film having a film thickness of 100 nm was formed. This resist film was irradiated with an electron beam by using an electron beam irradiation apparatus (HL750, available from Hitachi Ltd., accelerating voltage: 50 KeV). Immediately after the irradiation, the resist film was heated on a hot plate at 120° C. for 90 seconds. Thereafter, the film was developed at 23° C. for 60 seconds by using 2.38% by mass of an aqueous solution of tetramethylammonium hydroxide, was rinsed with pure water for 30 seconds, and then dried. Thus, the line and space pattern (line:space=1:1) was formed. With regard to this line and space pattern, the evaluation was performed in the same manner in Example 1. The results are shown in Table 8.

TABLE 8

| | High | | | | | | | | | |
|---|---|---|---|---|---|---|---|---|---|---|
| | Molecular | Photoacid | Basic | | | Concentration | L&S | L&S | | |
| | Compound | Generator (% | Compound | Solvent | Surfactant (% | of Total Solids | Sensitivity | Resolving | LER | EL |
| Example | (% by mass) | by mass) | (% by mass) | (mass ratio) | by mass) | (% by mass) | (μC/cm²) | Power (nm) | (nm) | (%) |
| Example 25 | P-1 | — | BASE-1 | S1/S2 | W-1 | 4 | 25.4 | 37.5 | 3.6 | 34.2 |
| | (99.35) | | (0.6) | (80/20) | (0.05) | | | | | |
| Example 26 | P-1 | — | BASE-1 | S1/S2 | — | 4 | 25.2 | 37.5 | 3.7 | 33.9 |
| | (99.4) | | (0.6) | (80/20) | | | | | | |
| Example 27 | P-1 (60) | — | BASE-1 | S1/S2 | — | 4 | 24.4 | 37.5 | 3.8 | 34.7 |
| | P-2 (39.4) | | (0.6) | (60/40) | | | | | | |
| Example 28 | P-1 | PAG-2 | BASE-1 | S1/S2 | W-1 | 4 | 26.1 | 37.5 | 4.1 | 33.1 |
| | (99.15) | (0.1) | (0.7) | (80/20) | (0.05) | | | | | |
| Example 29 | P-1 | — | BASE-2 | S1/S2 | W-1 | 4 | 25.9 | 37.5 | 3.9 | 32.8 |
| | (98.95) | | (1.0) | (80/20) | (0.05) | | | | | |
| Example 30 | P-1 | — | BASE-3 | S1/S2 | W-1 | 4 | 26.3 | 37.5 | 3.9 | 32.5 |
| | (98.90) | | (1.05) | (80/20) | (0.05) | | | | | |
| Example 31 | P-1 | — | BASE-1 | S1/S2 | W-1 | 4 | 24.3 | 37.5 | 4.3 | 30.2 |
| | (99.65) | | (0.3) | (80/20) | (0.05) | | | | | |
| Example 32 | P-6 | — | BASE-1 | S1/S2 | W-1 | 4 | 26.0 | 37.5 | 3.7 | 34.0 |
| | (99.35) | | (0.6) | (80/20) | (0.05) | | | | | |
| Example 33 | P-10 | — | BASE-1 | S1/S2 | W-1 | 4 | 25.9 | 37.5 | 3.8 | 33.4 |
| | (99.35) | | (0.6) | (80/20) | (0.05) | | | | | |
| Example 34 | P-21 | — | BASE-1 | S1/S2 | W-1 | 4 | 26.3 | 37.5 | 3.8 | 32.5 |
| | (99.35) | | (0.6) | (80/20) | (0.05) | | | | | |
| Comparative | R-1 | PAG-2 | BASE-1 | S1/S2 | W-1 | 4 | 25.4 | 50 | 4.8 | 24.3 |
| Example 6 | (93.10) | (6.25) | (0.6) | (80/20) | (0.05) | | | | | |

As shown in Table 8, the compositions according to Examples 25 to 34 could satisfy at the same time all of high sensitivity, high resolving power, good line edge roughness (LER) and good exposure latitude (EL). On the other hand, the composition according to Comparative Example 6 which used the High Molecular Compounds (R-1) for comparison does not have any good effect of sensitivity, resolving power, line edge roughness (LER) and exposure latitude (EL), and could not satisfy at the same time all of high sensitivity, high resolving power, good line edge roughness (LER) and good exposure latitude (EL).

What is claimed is:

1. A chemical amplification type positive resist composition comprising:
a high molecular compound (A) having a repeating unit represented by the following general formula (1), a repeating unit represented by the following general formula (2), and a repeating unit represented by the following general formula (3), 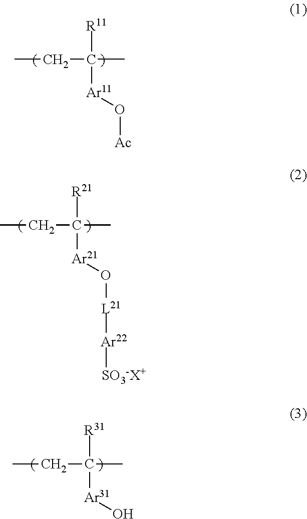
wherein, each of R¹¹, R²¹, and R³¹ represents independently a hydrogen atom or a methyl group,
each of Ar¹¹, Ar²¹, and Ar³¹ represents independently an arylene group,
Ac is a group leaving by the action of an acid, and —OAc is an acetal group which decomposes by the action of an acid to generate an alkali-soluble group,
L²¹ represents a divalent organic group,
Ar²² represents an unsubstituted aromatic ring, or an aromatic ring which is substituted with an alkyl group or an alkoxy group, and
X⁺ represents an onium cation.

2. The chemical amplification type positive resist composition according to claim 1, wherein the Ar¹¹, Ar²¹, and Ar³¹ represent a phenylene group.

3. The chemical amplification type positive resist composition according to claim 1, wherein the L²¹ represents a carbonyl group, a methylene group, —CO—(CH₂)ₙ—O—, —CO—(CH₂)ₙ—O—CO—, —(CH₂)ₙ—COO—, —(CH₂)ₙ—CONR¹—, or —CO—(CH₂)ₙ—NR¹— (wherein, the R¹ represents a hydrogen atom, an alkyl group, an aryl group or an aralkyl group, and the n is an integer of 1 to 10).

4. The chemical amplification type positive resist composition according to claim 3, wherein the L²¹ represents a carbonyl group, —CH₂—COO—, —CO—CH₂—O—, —CO—CH₂—O—CO—, —CH₂—CONR¹—, or —CO—CH₂—NR¹— (the R¹ represents a hydrogen atom, an alkyl group, an aryl group or an aralkyl group).

5. The chemical amplification type positive resist composition according to claim 1, wherein the X⁺ represents a sulfonium cation.

6. The chemical amplification type positive resist composition according to claim 1, wherein the dispersity of the high molecular compound (A) is from 1.0 to 1.3.

7. A resist film formed by the chemical amplification type positive resist composition according to claim 1.

8. Resist coated mask blanks having the resist film according to claim 7.

9. A method of forming a resist pattern comprising:
exposing the resist film according to claim 7; and
developing the exposed film.

10. A method of forming a resist pattern comprising:
exposing the resist coated mask blanks according to claim 8; and
developing the exposed mask blanks.

11. The method of forming a resist pattern according to claim 9, wherein the exposing is performed by using an electron beam.

12. The chemical amplification type positive resist composition according to claim 2, wherein the L²¹ represents a carbonyl group, a methylene group, —CO—(CH₂)ₙ—O—, —CO—(CH₂)ₙ—O—CO—, —(CH₂)ₙ—COO—, —(CH₂)ₙ—CONR¹—, or —CO—(CH₂)ₙ—NR¹— (wherein, the R¹ represents a hydrogen atom, an alkyl group, an aryl group or an aralkyl group, and the n is an integer of 1 to 10).

13. The chemical amplification type positive resist composition according to claim 2, wherein the X⁺ represents a sulfonium cation.

14. The chemical amplification type positive resist composition according to claim 3, wherein the X⁺ represents a sulfonium cation.

15. The chemical amplification type positive resist composition according to claim 12, wherein the X⁺ represents a sulfonium cation.

16. The chemical amplification type positive resist composition according to claim 2, wherein the dispersity of the high molecular compound (A) is from 1.0 to 1.3.

17. The chemical amplification type positive resist composition according to claim 3, wherein the dispersity of the high molecular compound (A) is from 1.0 to 1.3.

18. The chemical amplification type positive resist composition according to claim 12, wherein the dispersity of the high molecular compound (A) is from 1.0 to 1.3.

19. The chemical amplification type positive resist composition according to claim 15, wherein the dispersity of the high molecular compound (A) is from 1.0 to 1.3.

20. The method of forming a resist pattern according to claim 10, wherein the exposing is performed by using an electron beam.
